(19) United States
(12) Patent Application Publication
(10) Pub. No.: US 2026/0150497 A1
(43) Pub. Date: May 28, 2026

(54) LIGHT EMITTING ELEMENT, AND DISPLAY DEVICE AND ELECTRONIC DEVICE EACH INCLUDING THE SAME

(71) Applicant: Samsung Display Co., Ltd., Yongin-si, Gyeonggi-do (KR)

(72) Inventors: WONJONG KIM, Yongin-si (KR); HYUNBIN PARK, Yongin-si (KR); BYEONGWOOK YOO, Yongin-si (KR); YEONHWA LEE, Yongin-si (KR); MORAN HA, Yongin-si (KR); JAEHEUNG HA, Yongin-si (KR)

(21) Appl. No.: 19/177,959

(22) Filed: Apr. 14, 2025

(30) Foreign Application Priority Data
Jul. 23, 2024 (KR) 10-2024-0097186

(51) Int. Cl. H10K 50/84; H10K 50/16; H10K 50/82; H10K 102/00

(52) U.S. Cl. CPC H10K 50/84; H10K 50/16; H10K 50/82; H10K 2102/351

(57) ABSTRACT

A light emitting element includes a first electrode, a hole transport region on the first electrode, an emission layer on the hole transport region, an electron transport region on the emission layer, a second electrode on the electron transport region, and a capping layer on the second electrode. The second electrode includes a silver-magnesium alloy having a higher silver content (e.g., amount) than a magnesium content (e.g., amount). A thickness of the second electrode is about 30 Å to about 105 Å, the capping layer has a refractive index of about 2.2 to about 2.5, and a thickness of the capping layer is about 200 Å to about 500 Å.

### CROSS-REFERENCE TO RELATED APPLICATIONS

The present application claims priority to and the benefit of Korean Patent Application No. 10-2024-0097186, filed on Jul. 23, 2024, in the Korean Intellectual Property Office, the entire content of which is incorporated herein by reference.

### BACKGROUND

### 1. Field

One or more embodiments of the present disclosure herein relate to a light emitting element, and a display device and an electronic device each including the light emitting element.

### 2. Description of the Related Art

Recently, significant research and development efforts on organic electroluminescence displays as image display devices have been conducted. The organic electroluminescence display is different from a liquid crystal display device and is a self-luminescent display device in which holes and electrons injected separately from a first electrode and a second electrode recombine in an emission layer. This recombination causes a light emitting material containing an organic compound in the emission layer to emit light, thereby achieving display (e.g., display of images).

In the application of a light emitting element to an electronic device, increasing the emission efficiency and lifespan of the light emitting element is highly desired or required. Therefore, the development of materials and structures for the light emitting element, which stably achieves these requirement, has been continuously required, desired, and pursued.

### SUMMARY

One or more aspects of embodiments of the present disclosure are directed toward a light emitting element having excellent or suitable emission efficiency and preventing or reducing a decrease in luminance reduction according to a viewing angle.

One or more aspects of embodiments of the present disclosure are directed toward a display device with improved display characteristics in a side viewing angle range

One or more aspects of embodiments of the present disclosure are directed toward an electronic device with improved display characteristics in a side viewing angle range.

Additional aspects will be set forth in part in the description which follows and, in part, will be apparent from the description, or may be learned by practice of the presented embodiments.

According to one or more embodiments of the present disclosure, a light emitting element includes a first electrode, a hole transport region on (e.g., arranged on) the first electrode, an emission layer on (e.g., arranged on) the hole transport region, an electron transport region on (e.g., arranged on) the emission layer, a second electrode on (e.g., arranged on) the electron transport region, and a capping layer on (e.g., arranged on) the second electrode. The second electrode includes a silver (Ag)-magnesium (Mg) alloy (i.e., a silver-magnesium alloy) having a higher silver content (e.g., amount) than a magnesium content (e.g., amount). A thickness of the second electrode is in a range of about 30 Angstroms (Å) to about 105 Å, the capping layer has a refractive index of about 2.2 to about 2.5, and a thickness of the capping layer is in a range of about 200 Å to about 500 Å.

In one or more embodiments, the magnesium content (e.g., amount) may be about 5 vol % to about 15 vol % on the basis of a total content (e.g., amount) of 100 vol % of the silver-magnesium alloy.

In one or more embodiments, the electron transport region may include an auxiliary layer that is adjacent to the second electrode and includes ytterbium (Yb).

In one or more embodiments, the second electrode may be directly on (e.g., arranged directly on) the auxiliary layer.

In one or more embodiments, the capping layer may have a light transmittance of greater than about 65% to about 90% in a wavelength range of about 450 nm to about 750 nm.

In one or more embodiments, the capping layer may have a light reflectance of about 1% to less than about 30% in a wavelength range of about 450 nm to about 750 nm.

In one or more embodiments, the capping layer may be directly on (e.g., arranged directly on) the second electrode.

In one or more embodiments, the hole transport region may include a hole injection layer on (e.g., arranged on) the first electrode, and a hole transport layer on (e.g., arranged on) the hole injection layer.

In one or more embodiments, the second electrode may be a cathode.

In one or more embodiments, the first electrode may include at least one selected from among at least one metal selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), indium (In), tin (Sn), and zinc (Zn), a compound of two or more selected from among the metals, lithium fluoride (LiF), indium tin oxide (ITO), indium zinc oxide (IZO), zinc oxide (ZnO), and indium tin zinc oxide (ITZO).

In one or more embodiments, based on a top of the capping layer, luminance at a side viewing angle of about 60 degrees may be about 20% or more relative to luminance at a front viewing angle.

In one or more embodiments, if (e.g., when) the thickness of the second electrode is defined as a first thickness, and the thickness of the capping layer is defined as a second thickness, then the first thickness may be about 0.15 to about 0.4 of the second thickness. In other words, the thickness of the second electrode is about 0.15 to about 0.4 of the thickness of the capping layer.

In one or more embodiments, the capping layer may include a compound represented by Formula 1.

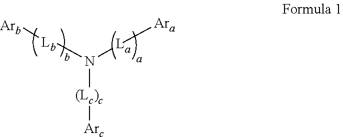

In Formula 1, Arₐ to Ar_{c} may each independently be a substituted or unsubstituted aryl group of 6 to 30 ring-forming carbon atoms or a substituted or unsubstituted heteroaryl group of 2 to 30 ring-forming carbon atoms, Lₐ to L_{c} may each independently be a direct linkage, a substituted or unsubstituted arylene group of 6 to 30 ring-forming carbon atoms, or a substituted or unsubstituted heteroarylene group of 2 to 30 ring-forming carbon atoms, and “a” to “c” may each independently be an integer of 0 to 3, where if (e.g., when) “a” to “c” are each an integer of 2 or greater, multiple Lₐ(s) to L_{c}(s) may each independently be a substituted or unsubstituted arylene group of 6 to 30 ring-forming carbon atoms or a substituted or unsubstituted heteroarylene group of 2 to 30 ring-forming carbon atoms.

In one or more embodiments, the capping layer may include at least one selected from among compounds in Compound Group 1.

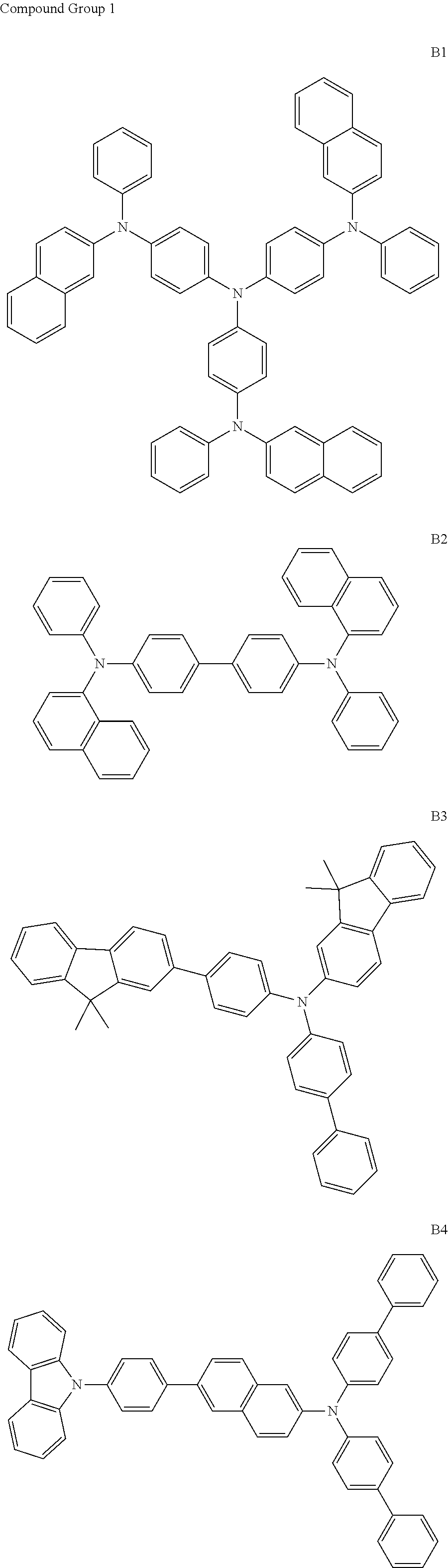 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; CC1(C)c2ccccc2-c2ccc(-c3ccc(N(c4ccc(-c5ccccc5)cc4)c4ccc5c(c4)C(C)(C)c4ccccc4-5)cc3)cc21 ; c1ccc(-c2ccc(N(c3ccc(-c4ccccc4)cc3)c3ccc4cc(-c5ccc(-n6c7ccccc7c7ccccc76)cc5)ccc4c3)cc2)cc1]

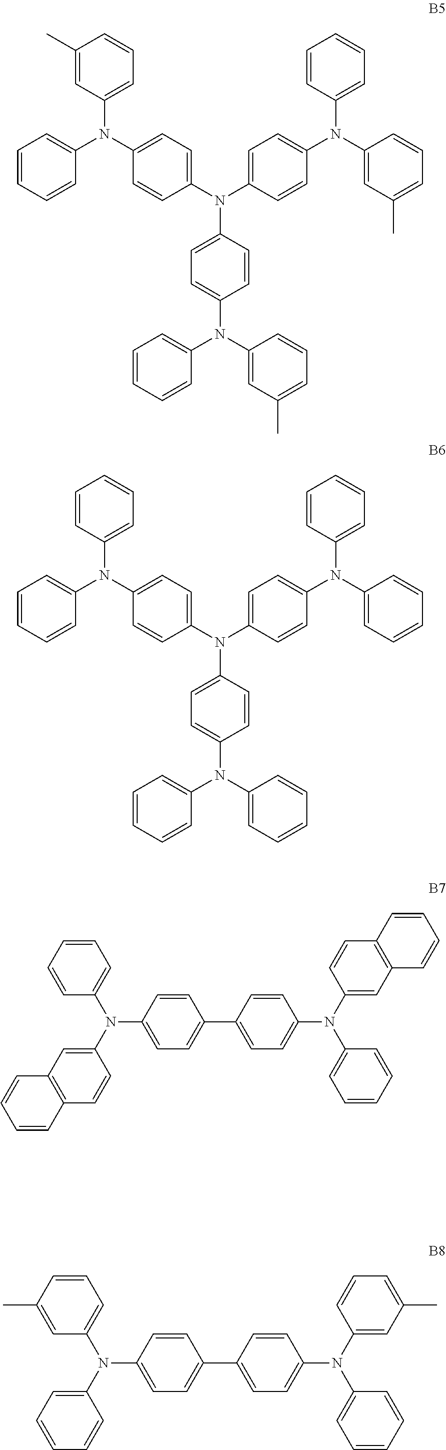

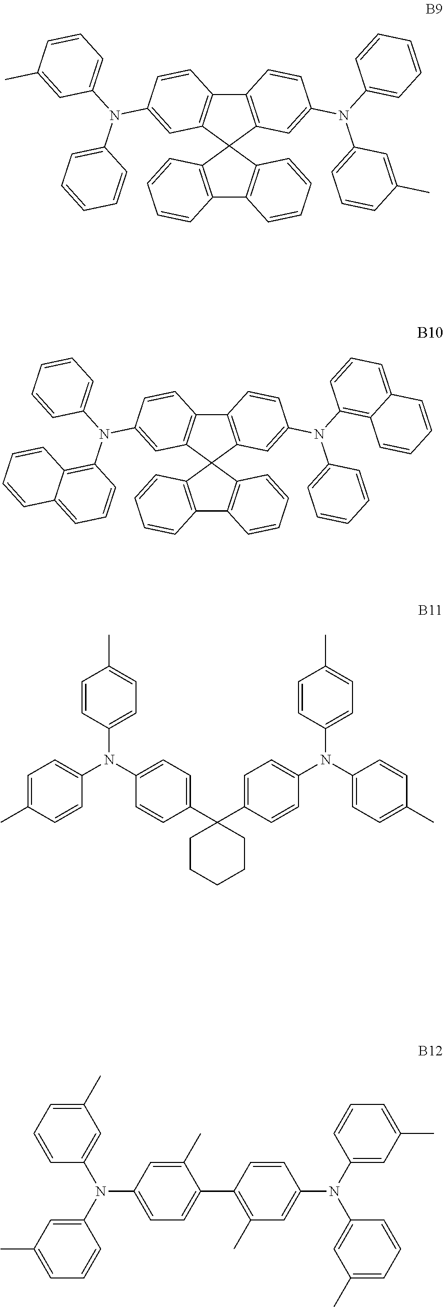

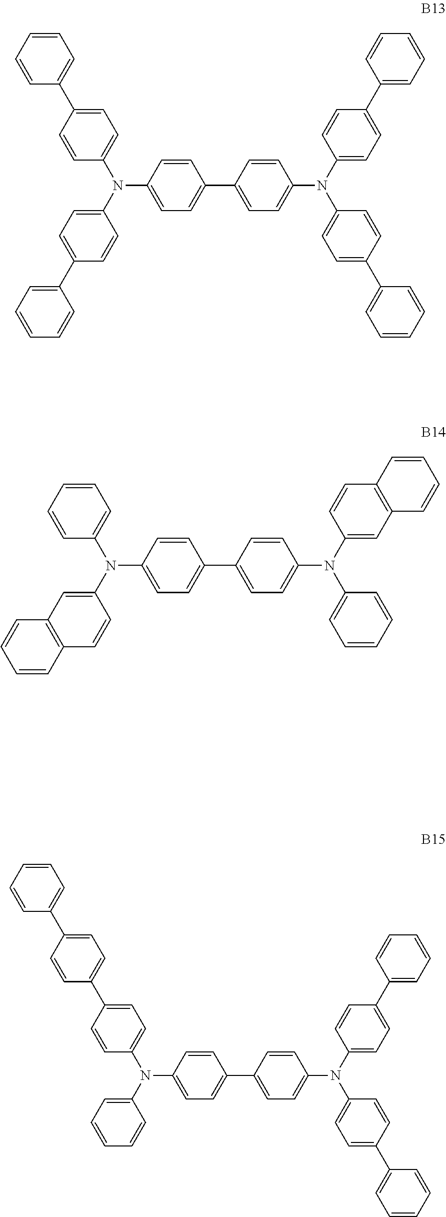 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

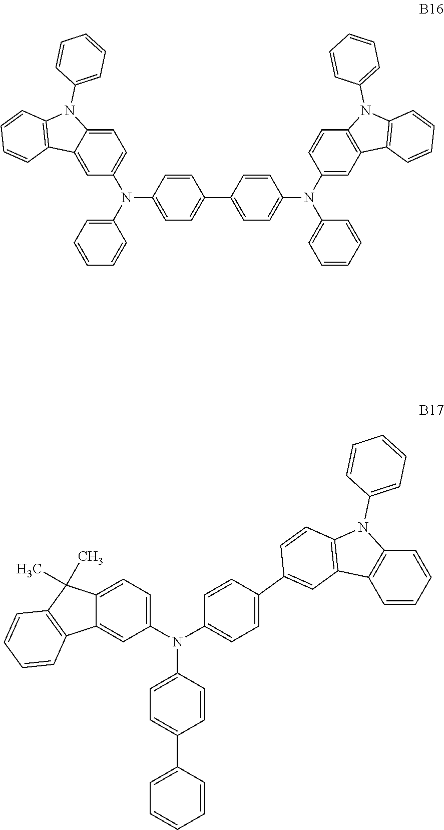 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

According to one or more embodiments of the disclosure, a light emitting element includes a first electrode, a hole transport region on (e.g., arranged on) the first electrode, an emission layer on (e.g., arranged on) the hole transport region, an electron transport region on (e.g., arranged on) the emission layer, a second electrode on (e.g., arranged on) the electron transport region, and a capping layer on (e.g., arranged on) the second electrode. The second electrode includes a silver (Ag)-magnesium (Mg) alloy (i.e., a silver-magnesium alloy) having a higher silver content (e.g., amount) than a magnesium content (e.g., amount). The capping layer has a refractive index of about 2.2 to about 2.5. If (e.g., when) a thickness of the second electrode is defined as a first thickness, and a thickness of the capping layer is defined as a second thickness, the first thickness is about 0.15 to about 0.4 of the second thickness. In other words, the thickness (i.e., the first thickness) of the second electrode is about 0.15 to about 0.4 of the thickness (i.e., the second thickness) of the capping layer. Based on a top of the capping layer, the capping layer has luminance at a side viewing angle of about 60 degrees of about 20% or more relative to luminance at a front viewing angle.

According to one or more embodiments of the disclosure, a display device includes a base layer including multiple light emitting areas and a non-light emitting area adjacent to the multiple light emitting areas, a circuit layer on (e.g., arranged on) the base layer, and a display element layer on (e.g., arranged on) the circuit layer and including multiple light emitting elements respectively corresponding to the multiple light emitting areas. At least a portion of the multiple light emitting elements includes a first electrode on (e.g. arranged on) the circuit layer, a hole transport region on (e.g., arranged on) the first electrode, an emission layer on (e.g., arranged on) the hole transport region, an electron transport region on (e.g., arranged on) the emission layer, a second electrode on (e.g., arranged on) the electron transport region, and a capping layer on (e.g., arranged on) the second electrode. The second electrode includes a silver (Ag)-magnesium (Mg) alloy (i.e., a silver-magnesium alloy) having a higher silver content (e.g., amount) than a magnesium content (e.g., amount). A thickness of the second electrode is in a range of about 30 Å to about 105 Å, the capping layer has a refractive index of about 2.2 to about 2.5, and a thickness of the capping layer is in a range of about 200 Å to about 500 Å.

In one or more embodiments, the display device may further include an encapsulating layer on (e.g., arranged on) the display element layer and including a first encapsulating inorganic layer, and the first encapsulating inorganic layer may be directly on (e.g., arranged directly on) the capping layer.

In one or more embodiments, the display device may further include a color filter layer on (e.g., arranged on) the display element layer and including multiple color filters.

In one or more embodiments, the magnesium content (e.g., amount) may be about 5 vol % to about 15 vol % on the basis of a total content (e.g., amount) of 100 vol % of the silver-magnesium alloy.

In one or more embodiments, the capping layer may be directly on (e.g., arranged directly on) the second electrode.

### BRIEF DESCRIPTION OF DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a perspective view of a display device according to one or more embodiments of the present disclosure;

FIG. 2 is a cross-sectional view of a display device according to one or more embodiments of the present disclosure;

FIG. 3 is a plan view of a display panel according to one or more embodiments of the present disclosure;

FIG. 4 is an enlarged plan view of a portion of a display panel according to one or more embodiments of the present disclosure;

FIG. 5 is a cross-sectional view of a display device according to one or more embodiments of the present disclosure;

FIG. 6 is a cross-sectional view of a display device according to one or more embodiments of the present disclosure;

FIGS. 7-9 are each a cross-sectional view schematically showing a light emitting element according to one or more embodiments of the present disclosure;

FIGS. 10-13 are each a cross-sectional view schematically showing a display devices according to one or more embodiments of the present disclosure;

FIG. 14A is a graph showing relative luminance according to a viewing angle for each of the Examples and the Comparative Example of the present disclosure; and

FIG. 14B is a graph showing relative luminance according to a viewing angle for each of the Examples of the present disclosure.

### DETAILED DESCRIPTION

The disclosure may have one or more suitable modifications and may be embodied in different forms, and example embodiments will be explained in more detail with reference to the accompany drawings. The disclosure may, however, be embodied in different forms and should not be construed as limited to the example embodiments set forth herein. Rather, all modifications, equivalents, and substituents which are included in the spirit and technical scope of the present disclosure should be included in the disclosure.

Like reference numerals refer to like elements throughout the disclosure, and duplicative descriptions thereof may not be provided for conciseness. In the drawings, the dimensions of structures may be exaggerated for clarity of illustration. It will be understood that, although the terms “first,” “second,” and/or the like may be used herein to describe one or more suitable elements, these elements should not be limited by these terms. These terms are only used to distinguish one element from another element. Thus, a first element could be termed a second element without departing from the teachings of the present disclosure. Similarly, a second element could be termed a first element. As used herein, the singular forms are intended to include the plural forms as well, unless the context clearly indicates otherwise. For example, the singular forms “a,” “an,” “one,” and “the” are intended to include the plural forms as well, unless the context clearly indicates otherwise. Expressions such as “at least one of,” “one of,” and “selected from,” when preceding a list of elements, modify the entire list of elements and do not modify the individual elements of the list. For example, “at least one of a, b, or c,” “at least one selected from a, b, and c,” “at least one selected from among a to c,” and/or the like, may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation. As used herein, the term “and/or” or “or” may include any and all combinations of one or more of the associated listed items. Further, the use of “may” when describing embodiments of the present disclosure refers to “one or more embodiments of the present disclosure.”

In the disclosure, it will be further understood that the terms “comprise(s)/comprising” and/or “include(s)/including,” and/or “have/has/having,” if (e.g., when) used in this disclosure, specify the presence of stated features, numerals, steps, operations, elements, parts, or any combination thereof, but do not preclude the presence or addition of one or more other features, numerals, steps, operations, elements, parts, or any combination thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the disclosure, if (e.g., when) a layer, a film, a region, a plate, and/or the like is referred to as being “on” or “above” another part, it may be “directly on” the other part, or one or more intervening layers may be present therebetween. In contrast, “directly on” refers to there being no additional layers, films, regions, plates, or similar elements between the specified layer, film, region, plate, or similar element and the other part (i.e., “directly on” means there are no additional layers, films, regions, plates, or similar elements between the specified layer, film, region, plate, or similar element and the other part). For example, “directly on” refers to two layers or two members are arranged without utilizing an additional member such as an adhesive member therebetween. In addition, if (e.g., when) a layer, a film, a region, a plate, and/or the like is referred to as being “under” or “below” another part, it may be “directly under” the other part, or one or more intervening layers may be present therebetween. Also, if (e.g., when) an element is referred to as being arranged “on” another element, it may be arranged under the other element.

In the disclosure, the term “substituted or unsubstituted” may refer to substituted or unsubstituted with at least one substituent selected from the group consisting of deuterium, a halogen, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, a heterocyclic group, an aryl group, and a heteroaryl group. In addition, each of the exampled substituents may be substituted or unsubstituted. For example, a biphenyl group may be interpreted as an aryl group or a phenyl group substituted with a phenyl group.

In the present disclosure, the term “forming a ring via the combination with an adjacent group” may refer to forming a substituted or unsubstituted hydrocarbon ring or a substituted or unsubstituted heterocycle via the combination with an adjacent group. The hydrocarbon ring includes an aliphatic hydrocarbon ring and/or an aromatic hydrocarbon ring. The heterocycle includes an aliphatic heterocycle and/or an aromatic heterocycle. The hydrocarbon ring and the heterocycle may each be monocycles or polycycles. In addition, the ring formed via the combination with an adjacent group may be combined with another ring to form a spiro structure.

In the present disclosure, the term “adjacent group” may refer to a substituent substituted for an atom which is directly bonded to an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In addition, in 4,5-dimethylphenanthrene, two methyl groups may be interpreted as “adjacent groups” to each other.

In the present disclosure, a halogen may be fluorine, chlorine, bromine, or iodine.

In the present disclosure, an alkyl group may be a linear or branched type (kind). The number of carbons in the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, n-nonyl, n-decyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, and/or the like, without limitation.

In the present disclosure, a cycloalkyl group may refer to a ring-type (kind) alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, without limitation.

In the present disclosure, an alkenyl group refers to a hydrocarbon group including one or more carbon-carbon double bonds in the middle or at the terminal of an alkyl group having 2 or more carbons. The alkenyl group may be a linear chain or a branched chain. The number of carbons in the alkenyl group is not specifically limited, for example, may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styrylvinyl group, and/or the like, without limitation.

In the present disclosure, an alkynyl group refers to a hydrocarbon group including one or more carbon-carbon triple bonds in the middle or at the terminal of an alkyl group having 2 or more carbons. The alkynyl group may be a linear chain or a branched chain. The number of carbons in the alkynyl group is not specifically limited, for example, may be 2 to 30, 2 to 20, or 2 to 10. Examples of the alkynyl group may include an ethynyl group, a propynyl group, and/or the like, without limitation.

In the present disclosure, a hydrocarbon ring group refers to any functional group or substituent derived from an aliphatic hydrocarbon ring. The hydrocarbon ring group may be a saturated hydrocarbon ring group of 5 to 20 ring-forming carbon atoms.

In the present disclosure, an aryl group refers to any functional group or substituent derived from an aromatic hydrocarbon ring. The aryl group may be a monocyclic aryl group or a polycyclic aryl group. The number for ring-forming carbons in the aryl group may be 6 to 30, 6 to 20, or 6 to 15. Examples of the aryl group may include phenyl, naphthyl, fluorenyl, anthracenyl, phenanthryl, biphenylyl, terphenylyl, quaterphenylyl, quinquephenylyl, sexiphenylyl, triphenylenyl, pyrenyl, benzofluoranthenyl, chrysenyl, and/or the like, without limitation.

In the present disclosure, a fluorenyl group may be substituted, and two substituents may be combined with each other to form a spiro structure. Examples of a substituted fluorenyl group are as follows, but embodiments of the present disclosure are not limited thereto.

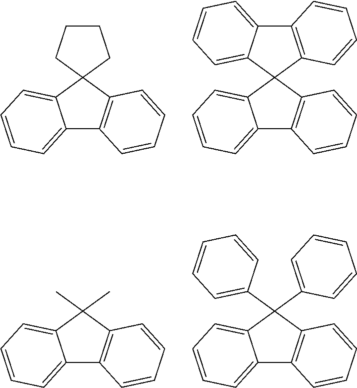

In the present disclosure, a heterocyclic group refers to any functional group or substituent derived from a ring including one or more selected from among B, O, N, P, Si, S, and Se as heteroatoms. The heterocyclic group may include an aliphatic heterocyclic group and/or an aromatic heterocyclic group. The aromatic heterocyclic group may be a heteroaryl group. The aliphatic heterocyclic group and the aromatic heterocyclic group may each be a monocycle or a polycycle.

In the present disclosure, a heterocyclic group may include one or more selected from among B, O, N, P, Si, S, and Se as heteroatoms. If (e.g., when) the heterocyclic group includes two or more heteroatoms, the two or more heteroatoms may be the same or different. The heterocyclic group may be a monocyclic heterocyclic group or a polycyclic heterocyclic group, and has the concept including a heteroaryl group. The number of ring-forming carbons in the heterocyclic group may be 2 to 30, 2 to 20, or 2 to 10.

In the present disclosure, an aliphatic heterocyclic group may include one or more selected from among B, O, N, P, Si, S, and Se as heteroatoms. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, without limitation.

In the present disclosure, a heteroaryl group may include one or more selected from among B, O, N, P, Si, S, and Se as heteroatoms. If (e.g., when) the heteroaryl group includes two or more heteroatoms, the two or more heteroatoms may be the same or different. The heteroaryl group may be a monocyclic heterocyclic group or polycyclic heterocyclic group. The number for ring-forming carbon s in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, without limitation.

In the present disclosure, the same explanation on the above-described aryl group may be applied to an arylene group except that the arylene group is a divalent group. The same explanation on the above-described heteroaryl group may be applied to a heteroarylene group except that the heteroarylene group is a divalent group.

In the present disclosure, a silyl group includes an alkyl silyl group and/or an aryl silyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, without limitation.

In the present disclosure, the number of carbons in a carbonyl group is not specifically limited, for example, may be 1 to 40, 1 to 30, or 1 to 20. For example, the carbonyl group may have the following structures, but embodiments of the present disclosure are not limited thereto.

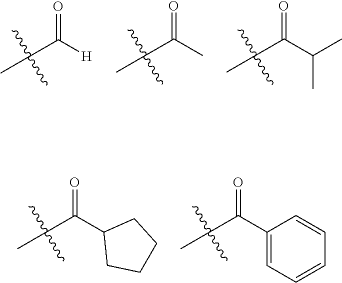

In the present disclosure, the number of carbons in a sulfinyl group or a sulfonyl group is not specifically limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkyl thio group and/or an aryl thio group. The thio group may refer to the above-defined alkyl group or aryl group bonded to a sulfur atom. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and/or the like, without limitation.

In the present disclosure, an oxy group may refer to the above-defined alkyl group or aryl group which is bonded to an oxygen atom. The oxy group may include an alkoxy group and/or an aryl oxy group. The alkoxy group may be a linear chain, a branched chain, or a cyclic ring. The number of carbons in the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like. However, embodiments of the present disclosure are not limited thereto.

In the present disclosure, a boron group may refer to the above-defined alkyl group or aryl group, bonded to a boron atom. The boron group includes an alkyl boron group and/or an aryl boron group. Examples of the boron group may include a dimethylboron group, a diethylboron group, a t-butylmethylboron group, a diphenylboron group, a phenylboron group, and/or the like, without limitation.

In the present disclosure, the number of carbons in an amine group is not specifically limited, for example, may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, and/or the like, without limitation.

In the present disclosure, alkyl groups in an alkylthio group, an alkylsulfoxy group, an alkylaryl group, an alkylboron group, an alkyl silyl group, and an alkyl amine group may be the same as the examples of the above-described alkyl group.

In the present disclosure, aryl groups in an aryloxy group, an arylthio group, an arylsulfoxy group, an arylboron group, an aryl silyl group, and an aryl amine group may be the same as the examples of the above-described aryl group.

In the present disclosure, a direct linkage may refer to a single bond.

In one or more embodiments,

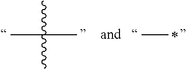

may each refer to a position to be connected.

Hereinafter, embodiments of the disclosure will be explained referring to the drawings.

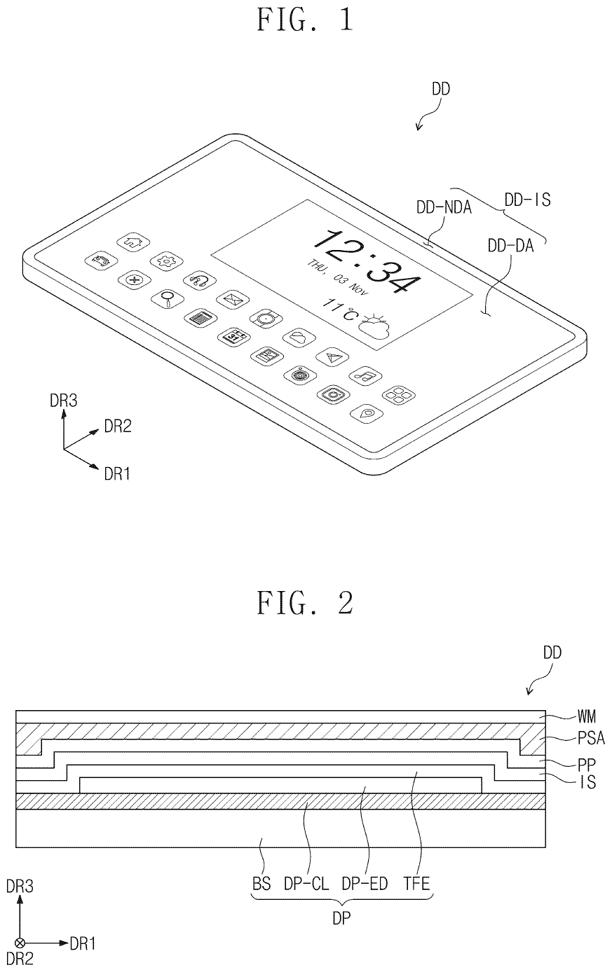

FIG. 1 is a perspective view of an electronic device DD according to one or more embodiments of the present disclosure. As shown in FIG. 1, the electronic device DD may display images through a display surface DD-IS. In one or more embodiments, the display surface DD-IS may have a rectangular shape having long sides extending in a first direction DR1 on a plane and short sides extending in a second direction DR2 intersecting the first direction DR1. However, embodiments of the present disclosure are not limited thereto, for example, in one or more embodiments, the display surface DD-IS may have one or more suitable shapes such as a circle or a polygon.

In one or more embodiments, a third direction DR3 may be defined as a direction substantially normal (e.g., perpendicular) to a plane defined by the first direction DR1 and the second direction DR2. A front surface (or top) and a back surface (or bottom) of each member constituting the electronic device DD may be opposed to each other in the third direction DR3, and the normal direction of each of the front and back surfaces of each member may be substantially parallel to the third direction DR3. A separation distance between the front and back surfaces defined along the third direction DR3 may correspond to a thickness of the member.

In the present disclosure, “on a plane” or “in a plan view” may be defined as a state viewed from the third direction DR3. For example, “on a plane” may be explained based on a plane defined by the first direction DR1 and the second direction DR2. In the disclosure, “on a cross-section” may be defined as a state viewed from the first direction DR1 or the second direction DR2. In one or more embodiments, the directions indicated by the first to third directions DR1, DR2 and DR3 are relative concepts and may be converted to other directions.

In one or more embodiments of the present disclosure, the electronic device DD having a flat display surface is illustrated, but embodiments of the present disclosure are not limited thereto. In one or more embodiments, the electronic device DD may include a curved display surface or a three-dimensional display surface. The three-dimensional display surface includes multiple display regions pointing in (e.g., pointing toward) different directions, and may include, for example, a bent display surface. The electronic device DD according to one or more embodiments may be a flexible display device DD. In one or more embodiments, the flexible display device DD may be a foldable display device.

In one or more embodiments, the electronic device DD may be applied to a tablet terminal. Electronic modules, a camera module, a power module and/or the like, mounted on a main board may be arranged in a bracket/case together with the electronic device DD to constitute a tablet terminal. The electronic device DD according to the disclosure may be applied to large-sized electronic devices such as a television and/or a monitor as well as small and medium-sized electronic devices such as a mobile phone, a car navigation system, a game console, and/or a smart watch.

The electronic device DD of one or more embodiments may be a transparent display device. The transparent display device may display information in a state where an object placed on the back of the electronic device DD is transparently reflected on the front of the electronic device DD. Accordingly, a user may recognize the object placed on the back of the electronic device DD from the front of the electronic device DD.

As shown in FIG. 1, the display surface DD-IS includes an image area DD-DA where an image is displayed and a bezel area DD-NDA adjacent to the image area DD-DA. The bezel area DD-NDA is an area where an image is not displayed. Icon images are shown as an example of images in FIG. 1.

As shown in FIG. 1, in one or more embodiments, the image area DD-DA may be substantially rectangular. The term “substantially rectangular” includes not only a rectangular shape in the mathematical sense, but also a rectangular shape in which a vertex is not defined in a vertex area (or a corner area) and a boundary of a curve is defined. In one or more embodiments, different from the drawing, the image area DD-DA may have one or more suitable shapes other than a rectangular shape. For example, in one or more embodiments, the image area DD-DA may have a circular shape or an elliptical shape. In one or more embodiments, the image area DD-DA may have a polygonal shape other than a rectangular shape.

The bezel area DD-NDA may be around (e.g., surround) the image area DD-DA. However, embodiments of the disclosure are not limited thereto, and a shape of the bezel area DD-NDA may be modified. For example, in one or more embodiments, the bezel area DD-NDA may be arranged on only one side of the image area DD-DA.

FIG. 2 is a cross-sectional view of an electronic device DD according to one or more embodiments of the present disclosure.

The electronic device DD may include a display module and a window WM arranged on the display module. The display module DM and the window WM may be combined by an adhesive layer PSA. According to one or more embodiments of the disclosure, the window WM may be formed by a coating method, and the window WM may be in contact with the display module, and in these embodiments, the adhesive layer PSA may not be provided.

The display module may include a display panel DP, an input sensor IS, and an optical layer PP. The display panel DP may include a base layer BS, a circuit layer DP-CL, a display element layer DP-ED, and an encapsulating layer TFE.

The circuit layer DP-CL may be on (e.g., arranged on) the top of the base layer BS. In one or more embodiments, the base layer BS may be a flexible substrate capable of bending, folding, rolling and/or the like. In one or more embodiments, the base layer BS may be a glass substrate, a metal substrate, a polymer substrate and/or the like. However, embodiments of the present disclosure are not limited thereto, and the base layer BS may be an inorganic layer, an organic layer, or a composite material layer. The base layer BS has substantially the same shape as the display panel DP.

In one or more embodiments, the base layer BS may have a multilayer structure. For example, the base layer BS may include a first synthetic resin layer, a second synthetic resin layer, and inorganic layers arranged therebetween. Each of the first and second synthetic resin layers may include a polyimide-based resin, but embodiments of the present disclosure are not particularly limited.

The circuit layer DP-CL may be on (e.g., arranged on) the base layer BS. The circuit layer DP-CL may include multiple insulating layers, multiple semiconductor patterns, multiple conductive patterns, signal lines, and/or the like. The circuit layer DP-CL may include a driving circuit of a pixel.

The display element layer DP-ED may be on (e.g., arranged on) the circuit layer DP-CL. The display element layer DP-ED may include a light emitting element. For example, in one or more embodiments, the light emitting element may include an organic light emitting material, an inorganic light emitting material, an organic-inorganic light emitting material, a quantum dot, a quantum rod, a micro LED, or a nano LED.

The encapsulating layer TFE may be on (e.g., arranged on) the display element layer DP-ED. The encapsulating layer TFE may protect the display element layer DP-ED, i.e., the light emitting element, from foreign substances such as moisture, oxygen, and/or dust particles. In one or more embodiments, the encapsulating layer TFE may include at least one encapsulating inorganic layer. In one or more embodiments, the encapsulating layer TFE may include a stacked structure of first encapsulating inorganic layer/encapsulating organic layer/second encapsulating inorganic layer.

The input sensor IS may be directly on (e.g., arranged directly on) the display panel DP. The input sensor IS may detect a user's input by, for example, an electromagnetic induction method and/or a capacitive method. The display panel DP and the input sensor IS may be formed through a continuous process. Here, “directly on” and “arranged directly on” may refer to that no third component is arranged between the input sensor IS and the display panel DP. For example, a separate adhesive layer may not be arranged between the input sensor IS and the display panel DP. In one or more embodiments, the input sensor IS may not be provided in the electronic device DD.

The optical layer PP reduces the reflectance of external light incident from an upper side of the window WM. The optical layer PP according to one or more embodiments of the present disclosure may include a phase retarder and a polarizer. The phase retarder may be a film type (kind) or a liquid crystal coating type (kind), and may include a λ/2 phase retarder and/or a λ/4 phase retarder. The polarizer may also be a film type (kind) or a liquid crystal coating type (kind). The film type (kind) may include a stretchable synthetic resin film, and the liquid crystal coating type (kind) may include liquid crystals arranged in a set or predetermined array. The phase retarder and the polarizer may each further include a protective film. The phase retarder and the polarizer themselves or the protective film may be defined as a base layer of the optical layer PP.

The optical layer PP according to one or more embodiments of the present disclosure may include color filters. The color filters have a set or predetermined arrangement. The arrangement of the color filters may be determined by considering the emission colors of pixels included in the display panel DP. In one or more embodiments, the optical layer PP may further include a black matrix adjacent to the color filters.

The window WM according to one or more embodiments of the present disclosure may include a base layer and a light-shielding pattern. The base layer may include a glass substrate and/or a synthetic resin film. The light-shielding pattern partially overlaps the base layer. The light-shielding pattern is arranged on a back surface of the base layer, and the light-shielding pattern may substantially define the bezel area DD-NDA (FIG. 1) of the display device DD. An area where the light-shielding pattern is not arranged may define the image area DD-DA (FIG. 1) of the display device DD.

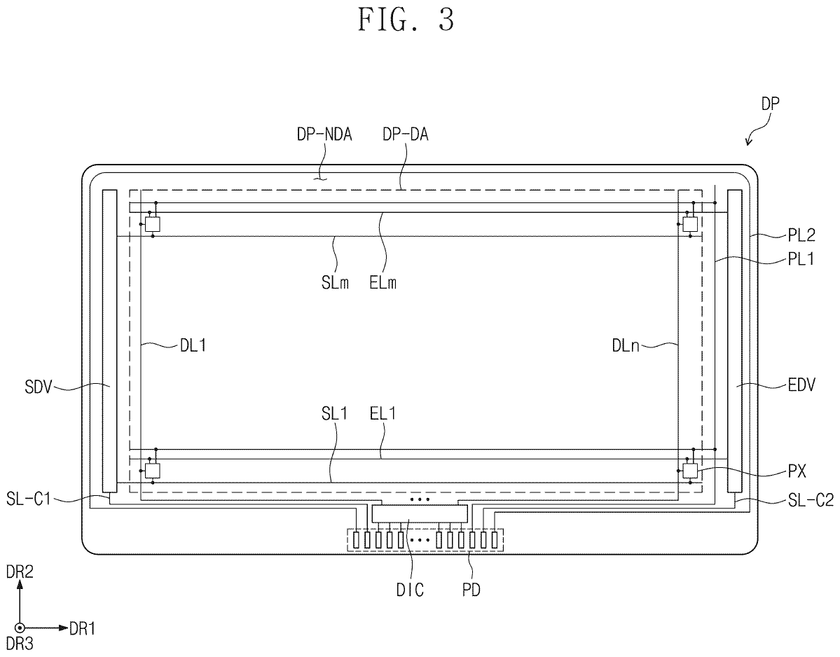

FIG. 3 is a plan view of a display panel DP according to one or more embodiments of the present disclosure.

Referring to FIG. 3, the display panel DP may include multiple pixels PX, a scan driving circuit SDV, an emission driving circuit EDV, multiple signal lines, and multiple pads PD. The multiple pixels PX are arranged in a display area DP-DA. A driving chip DIC mounted in a non-display area DP-NDA may include a data driving circuit. The display area DP-DA may correspond to the image area DD-DA in FIG. 1, and the non-display area DP-NDA may correspond to the bezel area DD-NDA. In the description, the phrase “areas or portions correspond to areas or portions” refers to overlapping, and is not necessarily limited to two different areas or portions having the same area. In one or more embodiments of the disclosure, the data driving circuit may also be stacked on the display panel DP like the scan driving circuit SDV and the emission driving circuit EDV.

The multiple signal lines may include multiple scan lines SL1 to SLm, multiple data lines DL1 to DLn, multiple emission lines EL1 to ELm, first and second control lines SL-C1 and SL-C2, and first and second power lines PL1 and PL2. “m” and “n” are each a natural number of 2 or more.

The scan lines SL1 to SLm may extend in a first direction DR1 and be electrically connected with the pixels PX and the scan driving circuit SDV. The data lines DL1 to DLn may extend in a second direction DR2 and be electrically connected with the pixels PX and the driving chip DIC. The emission lines EL1 to ELm may extend in the first direction DR1 and be electrically connected with the pixels PX and the emission driving circuit EDV.

The first power line PL1 receives a first power voltage, and the second power line PL2 receives a second power voltage at a lower level than the first power voltage. In one or more embodiments, a second electrode (for example, cathode) of a light emitting element included in the pixel PX is connected with the second power line PL2.

The first control line SL-C1 is connected with the scan driving circuit SDV and may extend toward a bottom of the display panel DP. The second control line SL-C2 is connected with the emission driving circuit EDV and may extend toward the bottom of the display panel DP. Pads PD are arranged in the non-display area DP-NDA adjacent to the bottom of the display panel DP and may be closer to the bottom of the display panel DP than the driving chip DIC. The pads PD may be connected with the driving chip DIC and some signal lines.

The scan driving circuit SDV generates multiple scan signals, and the scan signals may be applied to the pixels PX through scan lines SL1 to SLm. The driving chip DIC generates multiple data voltages, and the data voltages may be applied to the pixels PX through data lines DL1 to DLn. The emission driving circuit EDV generates multiple emission signals, and the emission signals may be applied to the pixels PX through emission lines EL1 to ELm. The pixels PX may receive the data voltages in response to the scan signals. The pixels PX may display images by emitting light with a luminance corresponding to the data voltages in response to the emission signals.

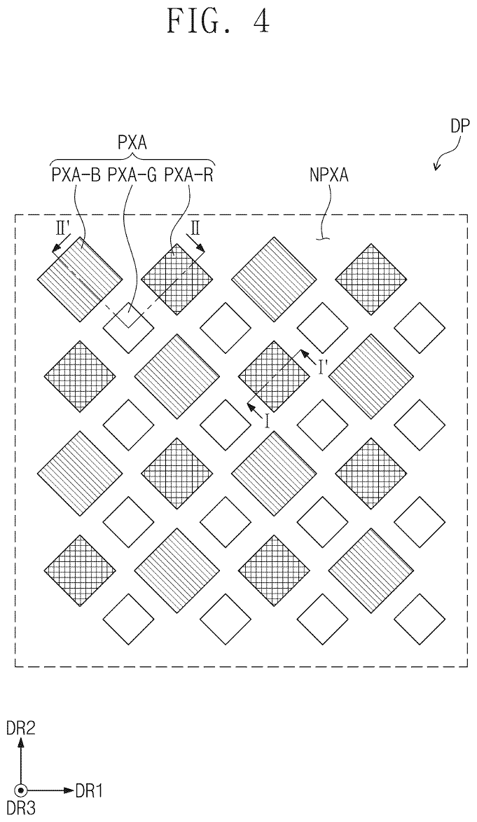

FIG. 4 is a plan view showing a display panel DP according to one or more embodiments of the present disclosure. Hereinafter, the explanation of the display panel DP included in the electronic device DD shown in FIG. 1 and FIG. 2 may be equally applied to the display panel DP of FIG. 4.

Referring to FIG. 4, the display panel DP may include a light emitting area PXA and a non-light emitting area NPXA. The non-light emitting area NPXA may be around (e.g., surround) the light emitting area PXA. The light emitting areas PXA may be provided in multiple numbers. In one or more embodiments, the light emitting area PXA may include a red light emitting area PXA-R, a green light emitting area PXA-G, and a blue light emitting area PXA-B. Each of the red light emitting area PXA-R, the green light emitting area PXA-G, and the blue light emitting area PXA-B may be to emit light of different wavelength ranges. The red light emitting area PXA-R may be to emit red light, the green light emitting area PXA-G may be to emit green light, and the blue light emitting area PXA-B may be to emit blue light.

In one or more embodiments, among the light emitting areas PXA-R, PXA-G, and PXA-B, the area of the blue light emitting area PXA-B may be the largest, and the area of the green light emitting area PXA-G may be the smallest. However, this is merely an example, and the areas of the light emitting areas PXA-R, PXA-G, and PXA-B are not limited thereto. In FIG. 4, the red light emitting area PXA-R and the blue light emitting area PXA-B are arranged alternately in one row, and the green light emitting area PXA-G is arranged in another row spaced and/or apart (e.g., spaced apart or separated) from the red light emitting area PXA-R and the blue light emitting area PXA-B. However, this is merely an example, and the arrangement of the light emitting areas PXA-R, PXA-G and PXA-B is not limited thereto. For example, in one or more embodiments, the light emitting areas PXA-R, PXA-G, and PXA-B may be arranged in a stripe shape. In one or more embodiments, the arrangement of the light emitting areas PXA-R, PXA-G, and PXA-B may have a PENTILE® arrangement (for example, an RGBG matrix, an RGBG structure, or an RGBG matrix structure) or a Diamond Pixel™ arrangement (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In FIG. 4, each of the light emitting areas PXA-R, PXA-G, and PXA-B is illustrated as having a square shape with a different size on a plane (e.g., in a plan view), but embodiments of the present disclosure are not limited thereto, and the light emitting areas PXA-R, PXA-G, and PXA-B may have one or more suitable shapes. For example, in one or more embodiments, each of the light emitting areas PXA-R, PXA-G, and PXA-B may have a square shape with rounded corners on a plane (e.g., in a plan view). In one or more embodiments, each of the light emitting areas PXA-R, PXA-G, and PXA-B may have a circular or elliptical shape on a plane (e.g., in a plan view).

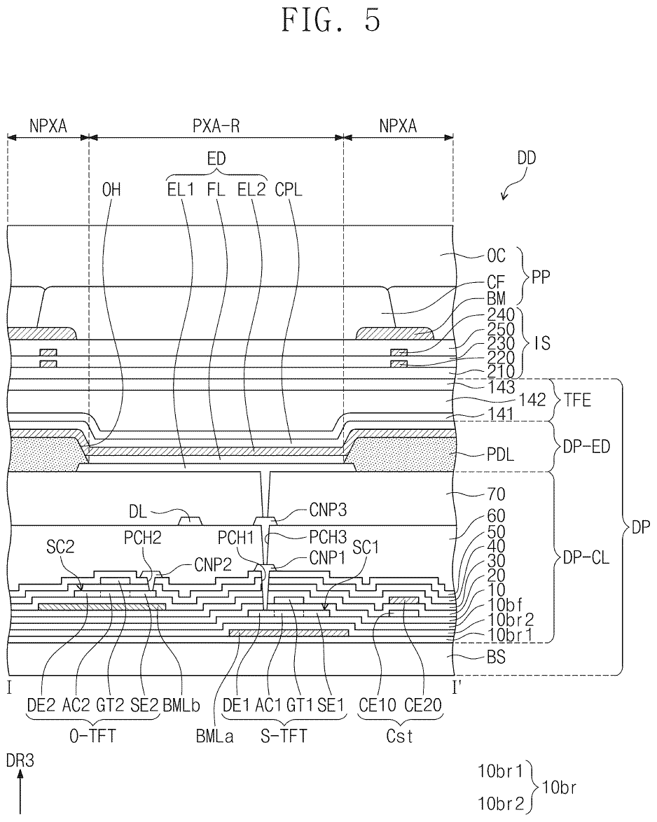

FIG. 5 is a cross-sectional view of an electronic device DD according to one or more embodiments of the present disclosure. FIG. 5 illustrates a cross-section of the electronic device DD corresponding to line I-I′ in FIG. 4. In FIG. 5, some components of the electronic device DD, for example, the adhesive layer PSA and the window WM shown in FIG. 2, are not illustrated for clarity.

A pixel driving circuit driving a light emitting element ED may include multiple pixel driving elements. The pixel driving circuit may include multiple transistors S-TFT and O-TFT and a capacitor Cst. In FIG. 5, a silicon transistor S-TFT and an oxide transistor O-TFT are illustrated as examples of the transistors. The pixel driving circuit in FIG. 5 is only an example embodiment, and the configuration of the pixel driving circuit is not necessarily limited thereto. In one or more embodiments, the pixel driving circuit may include only one type (kind) of transistor selected from among the silicon transistor S-TFT and the oxide transistor O-TFT.

Referring to FIG. 5, a base layer BS is illustrated as a single layer. The base layer BS may include a synthetic resin such as a polyimide. The base layer BS may be formed by coating a synthetic resin layer on a working substrate (or carrier substrate). If (e.g., when) the electronic device DD is completed by performing a subsequent process, then the working substrate may be removed. In one or more embodiments of the present disclosure, the base layer BS may have a multilayer structure including a first synthetic resin layer, at least one inorganic layer, and a second synthetic resin layer.

Referring to FIG. 5, a barrier layer 10br may be arranged on the base layer BS. The barrier layer 10br prevents foreign substances from entering from the outside. The barrier layer 10br may include at least one inorganic layer. In one or more embodiments, the barrier layer 10br may include a silicon oxide layer and a silicon nitride layer. Each may be provided in multiples, and the silicon oxide layers and the silicon nitride layers may be alternately stacked.

In one or more embodiments, the barrier layer 10br may include a lower barrier layer 10br1 and an upper barrier layer 10br2. A first shielding electrode BMLa may be arranged between the lower barrier layer 10br1 and the upper barrier layer 10br2. The first shielding electrode BMLa may be arranged to correspond to the silicon transistor S-TFT. The first shielding electrode BMLa may include a metal, for example, molybdenum.

The first shielding electrode BMLa may receive a bias voltage. The first shielding electrode BMLa may also receive a first power supply voltage. The first shielding electrode BMLa may block an electric potential from affecting the silicon transistor S-TFT due to a polarization phenomenon. The first shielding electrode BMLa may block external light from reaching the silicon transistor S-TFT. In one or more embodiments of the present disclosure, the first shielding electrode BMLa may be a floating electrode that is isolated from other electrodes or wirings.

A buffer layer 10bf may be arranged on the barrier layer 10br. The buffer layer 10bf may prevent or reduce metal atoms or impurities from diffusing from the base layer BS to a first semiconductor pattern SC1 on an upper side of the buffer layer 10bf. The buffer layer 10bf may include at least one inorganic layer. In one or more embodiments, the buffer layer 10bf may include a silicon oxide layer and a silicon nitride layer.

The first semiconductor pattern SC1 may be arranged on the buffer layer 10bf. In one or more embodiments, the first semiconductor pattern SC1 may include a silicon semiconductor. For example, the silicon semiconductor may include amorphous silicon, polycrystalline silicon, and/or the like. For example, in one or more embodiments, the first semiconductor pattern SC1 may include low-temperature polysilicon.

The first semiconductor pattern SC1 may have different electrical properties depending on whether it is doped. The first semiconductor pattern SC1 may include a first region having high conductivity (e.g., high electrical conductivity) and a second region having low conductivity (e.g., low electrical conductivity). The first region may be doped with an N-type (kind) dopant or a P-type (kind) dopant. The second region may be an undoped region or a region doped at a lower concentration than the first region. A source region SE1, a channel region AC1 (or active region), and a drain region DE1 of the silicon transistor S-TFT may be formed from the first semiconductor pattern SC1. The source region SE1 and the drain region DE1 may extend in opposite directions from the channel region AC1 in a cross-section.

A first insulating layer 10 may be arranged on the buffer layer 10bf. The first insulating layer 10 may cover the first semiconductor pattern SC1. The first insulating layer 10 may be an inorganic layer. In one or more embodiments, the first insulating layer 10 may be a single layer of a silicon oxide layer. However, embodiments of the present disclosure are not limited thereto.

A gate GT1 of the silicon transistor S-TFT is arranged on the first insulating layer 10. The gate GT1 may be a portion of a metal pattern. The gate GT1 overlaps the channel region AC1. In a process of doping the first semiconductor pattern SC1, the gate GT1 may be a mask. A first electrode CE10 of the capacitor Cst, which may be a storage capacitor, is arranged on the first insulating layer 10. Different from the drawing shown in FIG. 5, in one or more embodiments, the first electrode CE10 may have a shape that is integral with the gate GT1.

A second insulating layer 20 is arranged on the first insulating layer 10 and may cover the gate GT1. In one or more embodiments of the present disclosure, an upper electrode overlapping the gate GT1 may be further arranged on the second insulating layer 20. A second electrode CE20 overlapping the first electrode CE10 may be arranged on the second insulating layer 20. The upper electrode may have an integral shape with the second electrode CE20 on a plane.

A second shielding electrode BMLb is arranged on the second insulating layer 20. The second shielding electrode BMLb may be arranged to correspond to the oxide transistor O-TFT. In one or more embodiments of the present disclosure, the second shielding electrode BMLb may not be provided. According to one or more embodiments of the present disclosure, the first shielding electrode BMLa may extend to the bottom of the oxide transistor O-TFT and replace the second shielding electrode BMLb.

A third insulating layer 30 may be arranged on the second insulating layer 20. A second semiconductor pattern SC2 may be arranged on the third insulating layer 30. The second semiconductor pattern SC2 may include a channel region AC2 of the oxide transistor O-TFT. In one or more embodiments, the second semiconductor pattern SC2 may include a metal oxide semiconductor. The second semiconductor pattern SC2 may include a transparent conductive oxide (TCO) such as indium tin oxide (ITO), indium zinc oxide (IZO), indium gallium zinc oxide (IGZO), zinc oxide (ZnOₓ), or indium oxide (In₂O₃).

The metal oxide semiconductor may include multiple regions SE2, AC2, and DE2, that are distinguished depending on whether the transparent conductive oxide is reduced or not. A region where the transparent conductive oxide is reduced (hereinafter, reduced region) has greater conductivity (e.g., electrical conductivity) than a region where it is not reduced (hereinafter, non-reduced region). The reduced region substantially serves as a source/drain or signal line of a transistor. The non-reduced region substantially corresponds to the semiconductor region (or channel) of the transistor. A fourth insulating layer 40 may be arranged on the third insulating layer 30. As shown in FIG. 5, the fourth insulating layer 40 may cover the second semiconductor pattern SC2. In one or more embodiments of the present disclosure, the fourth insulating layer 40 may be an insulating pattern that overlaps a gate GT2 of the oxide transistor O-TFT and exposes a source region SE2 and a drain region DE2 of the oxide transistor O-TFT.

The gate GT2 of the oxide transistor O-TFT is arranged on the fourth insulating layer 40. The gate GT2 of the oxide transistor O-TFT may be a portion of a metal pattern. The gate GT2 of the oxide transistor O-TFT overlaps the channel region AC2. A fifth insulating layer 50 is arranged on the fourth insulating layer 40, and the fifth insulating layer 50 may cover the gate GT2. In one or more embodiments, each of the first insulating layer 10 to the fifth insulating layer 50 may be an inorganic layer.

A first connection pattern CNP1 and a second connection pattern CNP2 may each be arranged on the fifth insulating layer 50. Because the first connection pattern CNP1 and the second connection pattern CNP2 are formed through a same process, they may have a same material and a same stacked structure. The first connection pattern CNP1 may be connected with the drain region DE1 of the silicon transistor S-TFT through a first pixel contact hole PCH1 penetrating the first to fifth insulating layers 10, 20, 30, 40 and 50. The second connection pattern CNP2 may be connected with the source region SE2 of the oxide transistor O-TFT through a second pixel contact hole PCH2 penetrating the fourth and fifth insulating layers 40 and 50. The connection relationship between the first connection pattern CNP1 and the second connection pattern CNP2 for the silicon transistor S-TFT and the oxide transistor O-TFT, respectively, is not necessarily limited thereto.

A sixth insulating layer 60 may be arranged on the fifth insulating layer 50. A third connection pattern CNP3 may be arranged on the sixth insulating layer 60. The third connection pattern CNP3 may be connected with the first connection pattern CNP1 through a third pixel contact hole PCH3 penetrating the sixth insulating layer 60. A data line DL may be arranged on the sixth insulating layer 60. A seventh insulating layer 70 may be arranged on the sixth insulating layer 60 and may cover the third connection pattern CNP3 and the data line DL. Because the third connection pattern CNP3 and the data line DL are formed through a same process, they may have a same material and a same stacked structure. In one or more embodiments, each of the sixth insulating layer 60 and the seventh insulating layer 70 may be an organic layer.

A light emitting element ED includes a first electrode EL1, a functional layer FL, and a second electrode EL2. The first electrode EL1 of the light emitting element ED may be arranged on the seventh insulating layer 70. The first electrode EL1 may be a (semi) transparent electrode or a reflective electrode. In one or more embodiments, the first electrode EL1 may include a stacked structure of ITO/Ag/ITO that are sequentially stacked. The positions of the first electrode EL1 and the second electrode EL2 may be interchanged with each other.

A pixel defining layer PDL may be arranged on the seventh insulating layer 70. The pixel defining layer PDL may be an organic layer. The pixel defining layer PDL may have a property of absorbing light, and for example, in one or more embodiments, the pixel defining layer PDL may have a black color. The pixel defining layer PDL may include a black coloring agent. The black coloring agent may include a black dye or a black pigment. For example, the black coloring agent may include carbon black, a metal such as chromium, or an oxide thereof. The pixel defining layer PDL may correspond to a light-shielding pattern having light-shielding properties.

The pixel defining layer PDL may cover a portion of the first electrode EL1. For example, an opening OH exposing a portion of the first electrode EL1 may be defined in the pixel defining layer PDL. A light emitting area PXA-R may be defined to correspond to the opening OH. In FIG. 5, one light emitting area PXA-R corresponding to the red light emitting area PXA-R in FIG. 4 is illustrated. The cross-sections corresponding to the green light emitting area PXA-G and the blue light emitting area PXA-B in FIG. 4 may also be substantially the same as those illustrated in FIG. 5. However, a functional layer FL of a different material from the red light emitting area PXA-R may be respectively arranged in the green light emitting area PXA-G and the blue light emitting area PXA-B.

In one or more embodiments of the present disclosure, the functional layer FL may include at least an emission layer. In addition to the emission layer, the functional layer FL may further include a charge control layer, which may include a hole transport region and/or an electron transport region. This will be described in more detail later.

The light emitting element ED of one or more embodiments further includes a capping layer CPL. The capping layer CPL is arranged on the second electrode EL2 and may be used to improve the light extraction efficiency generated from the emission layer of the light emitting element ED.

An encapsulating layer TFE may cover the light emitting element ED. The encapsulating layer TFE may include a first encapsulating inorganic layer 141, an encapsulating organic layer 142, and a second encapsulating inorganic layer 143, that are sequentially stacked, but the layers constituting the encapsulating layer TFE are not necessarily limited thereto. In one or more embodiments, the encapsulating inorganic layers 141 and 143 may each independently include a silicon nitride layer, a silicon oxynitride layer, a silicon oxide layer, a titanium oxide layer, and/or an aluminum oxide layer. In one or more embodiments, each of the encapsulating inorganic layers 141 and 143 may have a multilayer structure. The encapsulating organic layer 142 may include an acrylic organic layer or an epoxy-based organic layer, but embodiments of the present disclosure are not limited thereto. In one or more embodiments, the encapsulating organic layer 142 may include a photopolymerizable organic material. The first encapsulating inorganic layer 141 may be arranged directly on the capping layer CPL of the light emitting element ED.

An input sensor IS includes multiple conductive patterns. The input sensor IS may include at least one conductive layer (or at least one sensor conductive layer) including multiple conductive patterns, and at least one insulating layer (or at least one sensor insulating layer). In one or more embodiments, the input sensor IS may include a first insulating layer 210 (or first sensor insulating layer), a first conductive layer 220 (or first sensor conductive layer), a second insulating layer 230 (or second sensor insulating layer), a second conductive layer 240 (or second sensor conductive layer), and a third insulating layer 250 (or third sensor insulating layer). FIG. 5 schematically illustrates multiple conductive patterns included in each of the first conductive layer 220 and the second conductive layer 240.

The first insulating layer 210 may be arranged directly on the display panel DP. The first insulating layer 210 may be an inorganic layer including at least one of silicon nitride, silicon oxynitride, or silicon oxide. Each of the first conductive layer 220 and the second conductive layer 240 may have a single layer structure or a multilayer structure stacked along the third direction DR3. The first conductive layer 220 and the second conductive layer 240 may each include conductive lines defining a mesh-shaped electrode. The conductive lines of the first conductive layer 220 and the conductive lines of the second conductive layer 240 may or may not be connected through a contact hole penetrating the second insulating layer 230 depending on positions.

The first conductive layer 220 and the second conductive layer 240 of the single layer structure may each include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnOₓ), or indium zinc tin oxide (IZTO). In one or more embodiments, the transparent conductive layer may include a conductive polymer such as poly(3,4-ethylenedioxythiophene) (PEDOT), a metal nanowire, graphene, and/or the like.

The first conductive layer 220 and the second conductive layer 240 of the multilayer structure may each include metal layers. In one or more embodiments, the metal layers may have a three-layer structure of, for example, titanium/aluminum/titanium. The conductive layer of the multilayer structure may include at least one metal layer and at least one transparent conductive layer. The second insulating layer 230 may be arranged between the first conductive layer 220 and the second conductive layer 240. The second insulating layer 230 arranged between the first conductive layer 220 and the second conductive layer 240 may be explained as a “sensing insulating layer” in the description. The third insulating layer 250 may cover the second conductive layer 240. In one or more embodiments of the present disclosure, the third insulating layer 250 may not be provided. The second insulating layer 230 and the third insulating layer 250 may each include an inorganic layer or an organic layer.

An optical layer PP may be positioned on the input sensor IS. The optical layer PP may include a light-shielding pattern BM, a color filter CF, and a planarization layer OC.

A material constituting the light-shielding pattern BM is not particularly limited as long as it is a material that absorbs light. The light-shielding pattern BM is a layer having a black color, and in one or more embodiments, the light-shielding pattern BM may include a black component (black coloring agent). The black component may include a black dye or a black pigment. The black component may include carbon black, a metal such as chromium, or an oxide thereof.

The light-shielding pattern BM may be overlapped with the first conductive layer 220 and the second conductive layer 240 on a plane (e.g., in a plan view). The light-shielding pattern BM may prevent or reduce external light reflection by the first conductive layer 220 and the second conductive layer 240. The light-shielding pattern BM may be overlapped with the non-light emitting area NPXA.

The color filter CF may overlap with at least the light emitting area PXA-R. A portion of the color filter CF may also overlap with the non-light emitting area NPXA. A portion of the color filter CF may be arranged on the light-shielding pattern BM. The color filter CF may be to transmit light generated by the light emitting element ED and block some wavelength bands of external light. The color filter CF may reduce external light reflection by the first electrode EL1 and the second electrode EL2.

The planarization layer OC may cover the light-shielding pattern BM and the color filter CF. The planarization layer OC may include an organic material, and the planarization layer OC may provide a flat top.

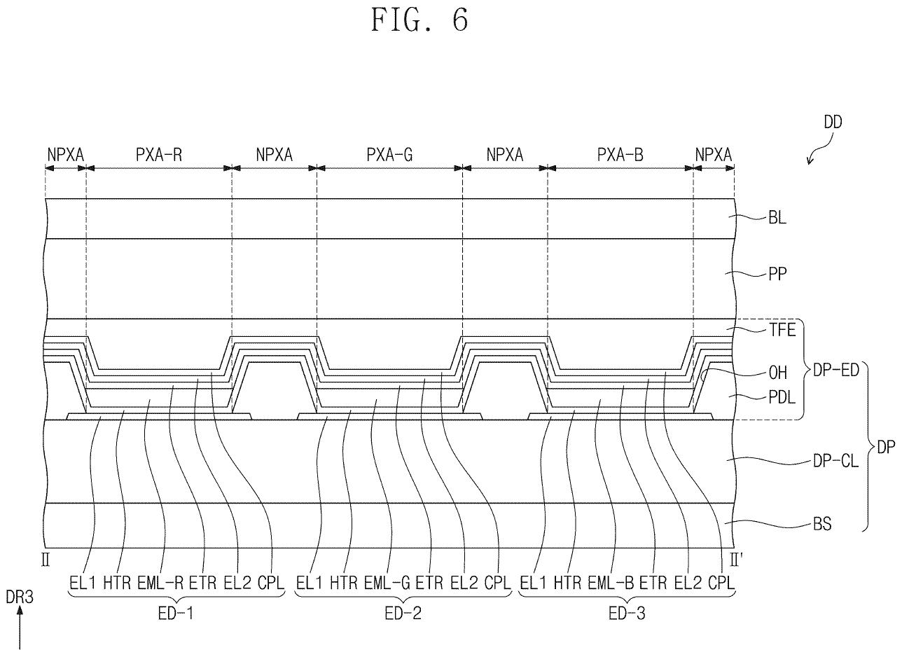

FIG. 6 is a cross-sectional view of an electronic device DD of one or more embodiments of the present disclosure. FIG. 6 is a cross-sectional view showing a portion corresponding to line II-II′ in FIG. 4. In FIG. 6, some parts of the electronic device DD, for example, the input sensor IS, adhesive layer PSA, and window WM shown in FIG. 2 are not shown for clarity.

According to one or more embodiments of the present disclosure, the electronic device DD may include a display panel DP and an optical layer PP arranged on the display panel DP. The display panel DP may include light emitting elements ED-1, ED-2, and ED-3. The electronic device DD may include multiple light emitting elements ED-1, ED-2, and ED-3. The optical layer PP may be arranged on the display panel DP and control reflected light at the display panel DP due to external light. The optical layer PP may include, for example, a polarization layer and/or a color filter layer. In one or more embodiments, the optical layer PP may not be provided in the electronic device DD.

On the optical layer PP, a base substrate BL may be arranged. The base substrate BL may be a member providing a base surface on which the optical layer PP is arranged. The base substrate BL may be a glass substrate, a metal substrate, a plastic substrate and/or the like. However, embodiments of the disclosure are not limited thereto, and the base substrate BL may be an inorganic layer, an organic layer, or a composite material layer. In one or more embodiments, the base substrate BL may not be provided.

The electronic device DD according to one or more embodiments may further include a plugging layer. The plugging layer may be arranged between a display device layer DP-ED and a base substrate BL. The plugging layer may be an organic material layer. The plugging layer may include at least one selected from among an acrylic-based resin, a silicon-based resin, and an epoxy-based resin.

The display panel DP may include a base layer BS, a circuit layer DP-CL provided on the base layer BS, and a display element layer DP-ED. The display element layer DP-ED may include a pixel defining layer PDL, light emitting elements ED-1, ED-2, and ED-3 arranged in the pixel defining layer PDL, and an encapsulating layer TFE arranged on the light emitting elements ED-1, ED-2, and ED-3.

The base layer BS may be a member providing a base surface on which the display element layer DP-ED is arranged. The base layer BS may be a glass substrate, a metal substrate, a plastic substrate, and/or the like. However, embodiments of the disclosure are not limited thereto, and the base layer BS may be an inorganic layer, an organic layer, or a composite material layer.

In one or more embodiments, the circuit layer DP-CL may be arranged on the base layer BS, and the circuit layer DP-CL may include multiple transistors. Each of the transistors may include a control electrode, an input electrode, and an output electrode. For example, in one or more embodiments, the circuit layer DP-CL may include switching transistors and driving transistors for driving the light emitting elements ED-1, ED-2, and ED-3 of the display element layer DP-ED.

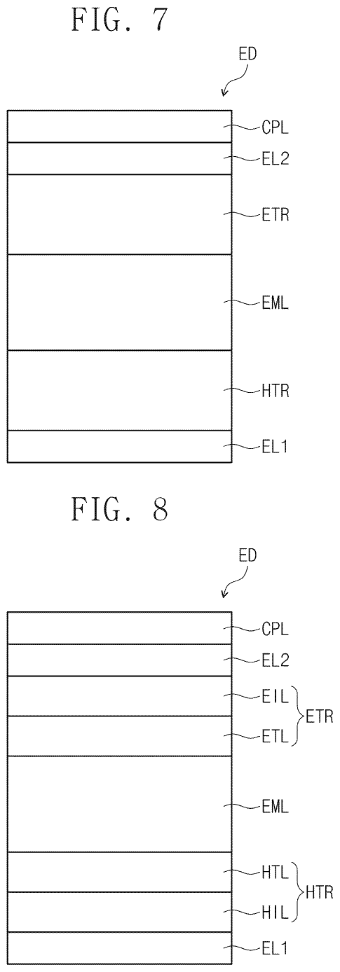

Each of the light emitting elements ED-1, ED-2, and ED-3 may have one of the structures of light emitting elements ED of embodiments according to FIG. 7 to FIG. 9, which will be explained later. Each of the light emitting elements ED-1, ED-2, and ED-3 may include a first electrode EL1, a hole transport region HTR, respective emission layers EML-R, EML-G, and EML-B, an electron transport region ETR, a second electrode EL2, and a capping layer CPL.

FIG. 6 illustrates one or more embodiments in which the respective emission layers EML-R, EML-G, and EML-B of the light emitting elements ED-1, ED-2 and ED-3 are each arranged in an opening OH defined in the pixel defining layer PDL, and the hole transport region HTR, the electron transport region ETR, and the second electrode EL2 are provided as common layers on the whole light emitting elements ED-1, ED-2, and ED-3. However, embodiments of the present disclosure are not limited thereto, for example, in one or more embodiments, the hole transport region HTR and the electron transport region ETR may each be patterned in the opening OH defined in the pixel defining layer PDL and provided. For example, in one or more embodiments, the hole transport region HTR, the respective emission layers EML-R, EML-G, and EML-B, and the electron transport region ETR of the light emitting elements ED-1, ED-2, and ED-3 may be patterned by an ink jet printing method and provided.

The encapsulating layer TFE may cover the light emitting elements ED-1, ED-2, and ED-3. The encapsulating layer TFE may encapsulate the display element layer DP-ED. The encapsulating layer TFE may be a thin film encapsulating layer. The encapsulating layer TFE may be one layer or a stack of multiple layers. The encapsulating layer TFE may include at least one insulating layer. In one or more embodiments, the encapsulating layer TFE may include a first encapsulating inorganic layer 141 (FIG. 5), an encapsulating organic layer 142 (FIG. 5), and a second encapsulating inorganic layer 143 (FIG. 5). The first encapsulating inorganic layer 141 (FIG. 5) may be arranged directly on the light emitting elements ED-1, ED-2, and ED-3.

The encapsulating layer TFE may be arranged on the second electrode EL2 and may be arranged while filling the opening OH.

Referring to FIG. 4 and FIG. 6, the electronic device DD may include a non-light emitting area NPXA and light emitting areas PXA-R, PXA-G, and PXA-B. The light emitting areas PXA-R, PXA-G, and PXA-B may be areas emitting light produced from the light emitting elements ED-1, ED-2, and ED-3, respectively. The light emitting areas PXA-R, PXA-G, and PXA-B may be separated from one another on a plane (e.g., in a plan view).

The light emitting areas PXA-R, PXA-G, and PXA-B may be areas separated by the pixel defining layer PDL. The non-light emitting area NPXA may be an area between neighboring light emitting areas PXA-R, PXA-G, and PXA-B and may be an area corresponding to the pixel defining layer PDL. In one or more embodiments, each of the light emitting areas PXA-R, PXA-G, and PXA-B may correspond to a pixel. The pixel defining layer PDL may divide the light emitting elements ED-1, ED-2, and ED-3. The respective emission layers EML-R, EML-G, and EML-B of the light emitting elements ED-1, ED-2, and ED-3 may be arranged and divided in the opening OH defined in the pixel defining layer PDL.

The light emitting areas PXA-R, PXA-G, and PXA-B may be divided into multiple groups according to the color of light produced from the light emitting elements ED-1, ED-2, and ED-3. In the electronic device DD of one or more embodiments, shown in FIG. 4 and FIG. 6, three light emitting areas PXA-R, PXA-G, and PXA-B respectively emitting red light, green light, and blue light are illustrated as an example. For example, the electronic device DD of one or more embodiments may include a red light emitting area PXA-R, a green light emitting area PXA-G, and a blue light emitting area PXA-B, which are separated from one another.

In the electronic device DD according to one or more embodiments, multiple light emitting elements ED-1, ED-2, and ED-3 may be to emit light having different wavelength ranges. For example, in one or more embodiments, the electronic device DD may include a first light emitting element ED-1 configured to emit red light, a second light emitting element ED-2 configured to emit green light, and a third light emitting element ED-3 configured to emit blue light. For example, the red light emitting area PXA-R, the green light emitting area PXA-G, and the blue light emitting area PXA-B of the electronic device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2 and ED-3 may be to emit light in substantially the same wavelength range, or at least one thereof may be to emit light in a different wavelength range. For example, in one or more embodiments, the first to third light emitting elements ED-1, ED-2 and ED-3 all may be to emit blue light.

FIGS. 7 to 9 are each a cross-sectional view schematically showing a light emitting element according to one or more embodiments of the present disclosure.

A light emitting element ED according to one or more embodiments may include a first electrode EL1, a second electrode EL2 oppositely arranged to the first electrode EL1, and at least one functional layer arranged between the first electrode EL1 and the second electrode EL2. The light emitting element ED further includes a capping layer CPL arranged on the second electrode EL2.

As shown in FIG. 7, in one or more embodiments, a light emitting element ED may include a hole transport region HTR, an emission layer EML, an electron transport region ETR, and/or the like, which are sequentially stacked, as the at least one functional layer. For example, the light emitting element ED of one or more embodiments may include a first electrode EL1, a hole transport region HTR, an emission layer EML, an electron transport region ETR, and a second electrode EL2, sequentially stacked. The light emitting element ED may further include a capping layer CPL arranged on the second electrode EL2.

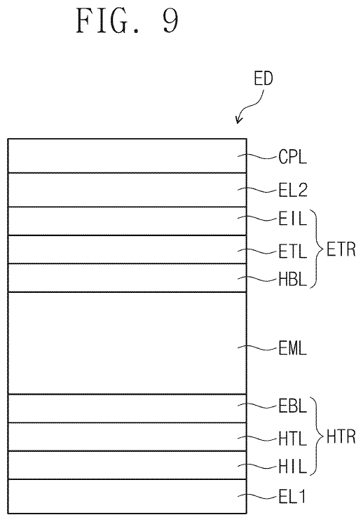

Compared to FIG. 7, FIG. 8 illustrates the cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. In addition, Compared to FIG. 7, FIG. 9 illustrates the cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer EBL.

The first electrode EL1 has conductivity (e.g., is a conductor). The first electrode EL1 may be formed of a metal material, a metal alloy, and/or a conductive compound. The first electrode EL1 may be an anode or a cathode. However, embodiments of the disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn and Zn, a compound of two or more selected therefrom, a mixture of two or more selected therefrom, or an oxide thereof.

If (e.g., when) the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). If (e.g., when) the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, and/or a (e.g., any suitable) mixture thereof (for example, a mixture of Ag and Mg). In one or more embodiments, the first electrode EL1 may have a structure of multiple layers including a reflective layer or a transflective layer formed of one or more of the above materials, and a transmissive conductive layer formed of ITO, IZO, ZnO, and/or ITZO. For example, in one or more embodiments, the first electrode EL1 may have a three-layer structure of ITO/Ag/ITO. However, embodiments of the disclosure are not limited thereto. The first electrode EL1 may include one of the above-described metal materials, a combination of two or more metal materials selected from among the above-described metal materials, or any oxide of the above-described metal materials. A thickness of the first electrode EL1 may be from about 700 Å to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one selected from among a hole injection layer HIL, a hole transport layer HTL, a buffer layer or an emission auxiliary layer, and an electron blocking layer EBL. A thickness of the hole transport region HTR may be, for example, about 50 Å to about 15,000 Å.

The hole transport region HTR may have a single layer formed of a single material, a single layer formed of multiple different materials, or a multilayer structure including multiple layers formed of multiple different materials.

For example, in one or more embodiments, the hole transport region HTR may have the structure of a single layer of a hole injection layer HIL or a hole transport layer HTL, or may have a structure of a single layer formed of a hole injection material and/or a hole transport material. In one or more embodiments, the hole transport region HTR may have a structure of a single layer formed of multiple different materials, or a structure stacked from the first electrode EL1 of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer EBL, but embodiments of the disclosure are not limited thereto.

The hole transport region HTR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the hole transport region HTR may include a compound represented by Formula H-1.

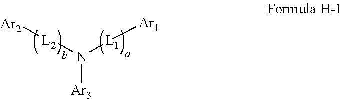

In Formula H-1, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. “a” and “b” may each independently be an integer of 0 to 10. In one or more embodiments, if (e.g., when) “a” or “b” is an integer of 2 or greater, multiple L₁(s) or multiple L₂(s) may each independently be a substituted or unsubstituted arylene group of 6 to 30 ring-forming carbon atoms or a substituted or unsubstituted heteroarylene group of 2 to 30 ring-forming carbon atoms.

In Formula H-1, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. In addition, in Formula H-1, Ar₃ may be a substituted or unsubstituted aryl group of 6 to 30 ring-forming carbon atoms or a substituted or unsubstituted heteroaryl group of 2 to 30 ring-forming carbon atoms.

In one or more embodiments, the compound represented by Formula H-1 may be a monoamine compound. In one or more embodiments, the compound represented by Formula H-1 may be a diamine compound in which at least one selected from among Ar₁ to Ar₃ includes an amine group as a substituent. In one or more embodiments, the compound represented by Formula H-1 may be a carbazole-based compound in which at least one selected from among Ar₁ and Ar₂ includes a substituted or unsubstituted carbazole group, or a fluorene-based compound in which at least one selected from among Ar₁ and Ar₂ includes a substituted or unsubstituted fluorene group.

The compound represented by Formula H-1 may be any one selected from among compounds in Compound Group H. However, the compounds shown in Compound Group H are mere examples, and the compound represented by Formula H-1 is not limited to the compounds represented in Compound Group H.

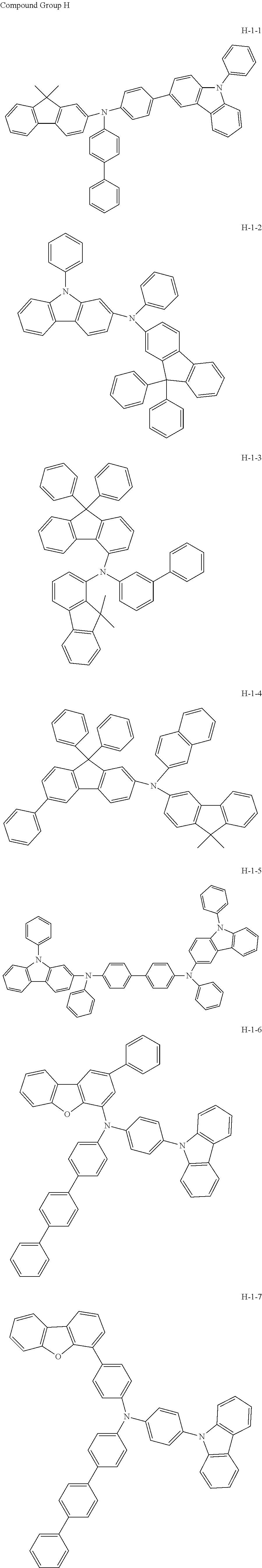

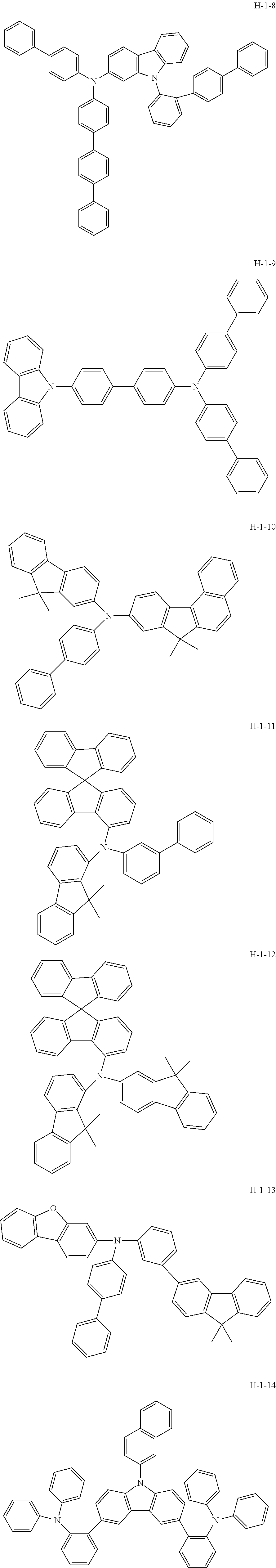

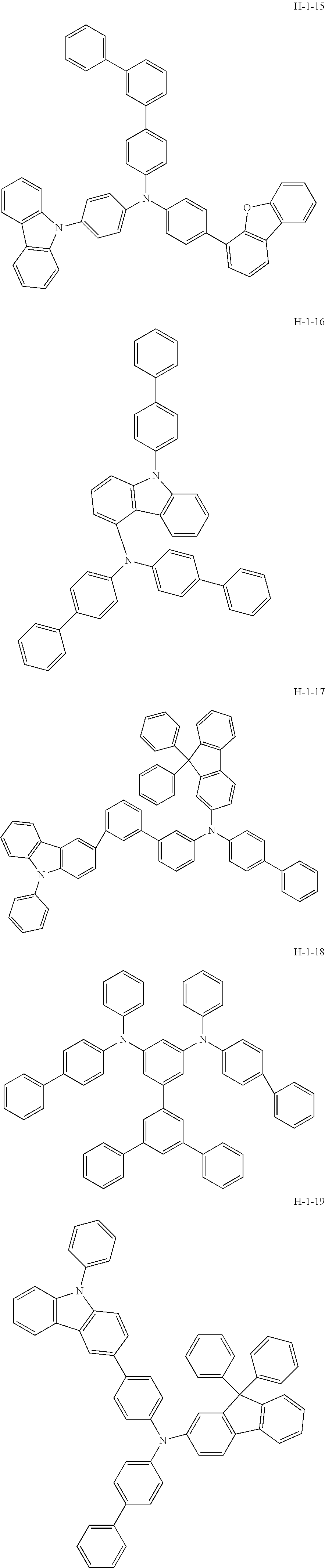

In one or more embodiments, the hole transport regions HTR may include one or more selected from among a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N, N′-diphenyl-benzidine (NPB), triphenylamine-containing polyetherketone (TPAPEK), 4-isopropyl-4′-methyldiphenyliodonium [tetrakis(pentafluorophenyl) borate], and dipyrazino[2,3-f: 2′,3′-h] quinoxaline-2,3,6,7,10,11-hexacarbonitrile (HATCN).

In one or more embodiments, the hole transport region HTR may include one or more selected from among carbazole derivatives such as N-phenylcarbazole and polyvinylcarbazole, fluorene-based derivatives, triphenylamine-based derivatives such as N,N′-bis(3-methylphenyl)-N,N′-diphenyl-[1,1′-biphenyl]-4,4′-diamine (TPD) and 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include one or more selected from among 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include one or more of the compounds of the hole transport region in at least one selected from among the hole injection layer HIL, the hole transport layer HTL, and the electron blocking layer EBL.

A thickness of the hole transport region HTR may be from about 100 Å to about 10,000 Å, for example, from about 100 Å to about 5,000 Å. If (e.g., when) the hole transport region HTR includes a hole injection layer HIL, a thickness of the hole injection region HIL may be, for example, from about 30 Å to about 1,000 Å. If (e.g., when) the hole transport region HTR includes a hole transport layer HTL, a thickness of the hole transport layer HTL may be from about 30 Å to about 1,000 Å. For example, if (e.g., when) the hole transport region HTR includes an electron blocking layer EBL, a thickness of the electron blocking layer EBL may be from about 10 Å to about 1,000 Å. If (e.g., when) the thicknesses of the hole transport region HTR, the hole injection layer HIL, the hole transport layer HTL, and the electron blocking layer EBL satisfy the above-described respective ranges, satisfactory hole transport properties may be achieved without substantial increase of a driving voltage.

In one or more embodiments, the hole transport region HTR may further include a charge generating material in addition to one or more of the above-described materials to improve conductivity. The charge generating material may be dispersed uniformly (e.g., substantially uniformly) or non-uniformly in the hole transport region HTR. The charge generating material may be, for example, a p-dopant. The p-dopant may include at least one selected from among metal halide compounds, quinone derivatives, metal oxides, and cyano group-containing compounds, without limitation. For example, in one or more embodiments, the p-dopant may include at least one selected from metal halide compounds such as CuI and/or RbI, quinone derivatives such as tetracyanoquinodimethane (TCNQ) and 2,3,5,6-tetrafluoro-7,7,8,8-tetracyanoquinodimethane (F4-TCNQ), metal oxides such as tungsten oxide and molybdenum oxide, cyano group-containing compounds such as dipyrazino[2,3-f:2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), without limitation.

As described above, the hole transport region HTR may further include at least one of a buffer layer or an electron blocking layer EBL in addition to the hole injection layer HIL and the hole transport layer HTL. The buffer layer may increase light emission efficiency by compensating for a resonance distance according to the wavelength of light emitted from the emission layer EML. A material that may be included in the hole transport region HTR may be used as a material included in the buffer layer. The electron blocking layer EBL is a layer that inhibits electron injection from the electron transport region ETR to the hole transport region HTR.

The emission layer EML is provided on the hole transport region HTR. The emission layer EML may have a thickness of, for example, about 100 Å to about 1,000 Å, or about 100 Å to about 300 Å. The emission layer EML may have a single layer formed of a single material, a single layer formed of multiple different materials, or a multilayer structure having multiple layers formed of multiple different materials.

In the light emitting element ED of one or more embodiments, the emission layer EML may be to emit blue light. In one or more embodiments, the emission layer EML may be to emit green light or red light.

In the light emitting element ED of one or more embodiments, the emission layer EML may include one or more selected from anthracene derivatives, pyrene derivatives, fluoranthene derivatives, chrysene derivatives, dihydrobenzanthracene derivatives, and triphenylene derivatives. For example, in one or more embodiments, the emission layer EML may include at least one of an anthracene derivative or a pyrene derivative.

In the light emitting elements ED of embodiments, shown in FIGS. 7 to 9, the emission layer EML may include a suitable host and/or dopant, for example, in one or more embodiments, the emission layer EML may include a compound represented by Formula E-1. The compound represented by Formula E-1 may be used as a fluorescence host material.

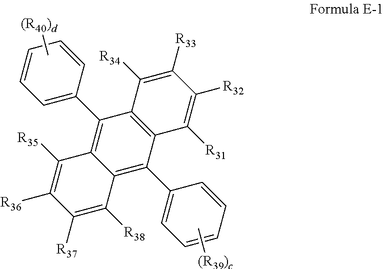

In Formula E-1, R₃₁ to R₄₀ may each independently be hydrogen, deuterium, a halogen, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In one or more embodiments, one or more selected from among R₃₁ to R₄₀ may be each independently combined with an adjacent group to form a saturated hydrocarbon ring, an unsaturated hydrocarbon ring, a saturated heterocycle, or an unsaturated heterocycle.

In Formula E-1, “c” and “d” may each independently be an integer of 0 to 5.

The compound represented by Formula E-1 may be any one selected from among Compound E1 to Compound E19.

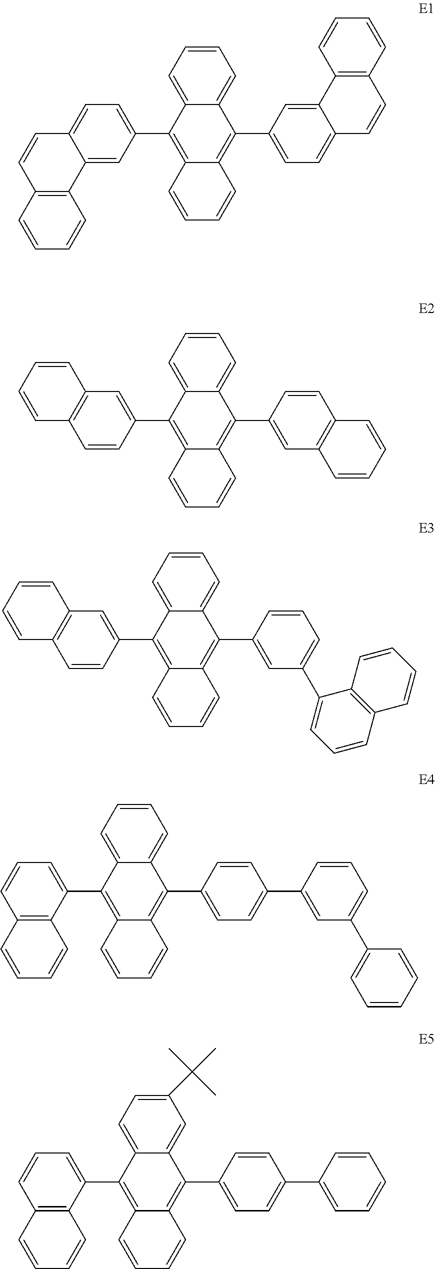

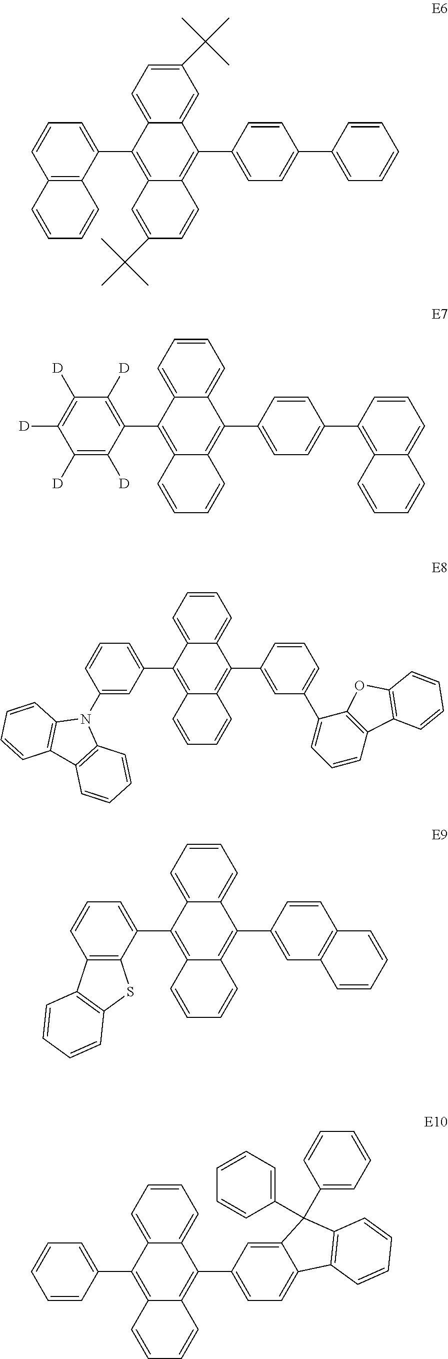

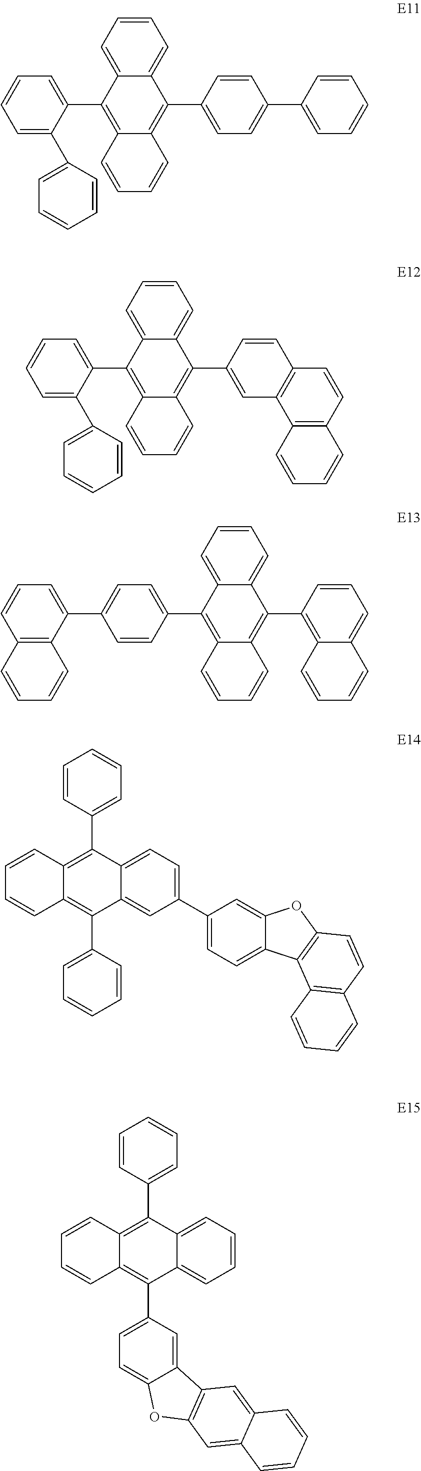

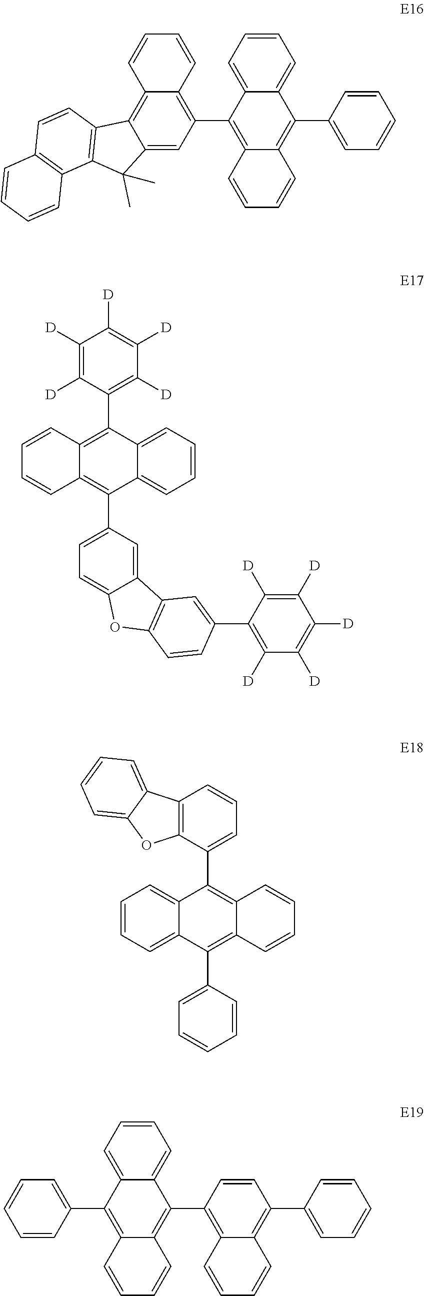

In one or more embodiments, the emission layer EML may include a compound represented by Formula E-2a or Formula E-2b. The compound represented by Formula E-2a or Formula E-2b may be used as a phosphorescence host material.

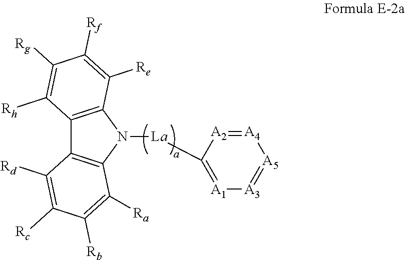

In Formula E-2a, “a” may be an integer of 0 to 10, Lₐ may be a direct linkage, a substituted or unsubstituted arylene group of 6 to 30 ring-forming carbon atoms, or a substituted or unsubstituted heteroarylene group of 2 to 30 ring-forming carbon atoms. In one or more embodiments, if (e.g., when) “a” is an integer of 2 or greater, multiple Lₐ(s) may each independently be a substituted or unsubstituted arylene group of 6 to 30 ring-forming carbon atoms or a substituted or unsubstituted heteroarylene group of 2 to 30 ring-forming carbon atoms.

In addition, in Formula E-2a, A₁ to A₅ may each independently be N or CRᵢ. Rₐ to Rᵢ may each independently be hydrogen, deuterium, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In one or more embodiments, one or more selected from among Rₐ to Rᵢ may be independently combined with an adjacent group to form a hydrocarbon ring or a heterocycle including N, O, S, and/or the like as a ring-forming atom.

In one or more embodiments, in Formula E-2a, two or three selected from among A₁ to A₅ may be N, and the remainder may be CRᵢ.

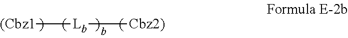

In Formula E-2b, Cbz1 and Cbz2 may each independently be an unsubstituted carbazole group or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” may be an integer of 0 to 10, and if (e.g., when) “b” is an integer of 2 or greater, multiple L_{b}(s) may each independently be a substituted or unsubstituted arylene group of 6 to 30 ring-forming carbon atoms or a substituted or unsubstituted heteroarylene group of 2 to 30 ring-forming carbon atoms.

The compound represented by Formula E-2a or Formula E-2b may be any one selected from among compounds in Compound Group E-2. However, the compounds shown in Compound Group E-2 are mere examples, and the compound represented by Formula E-2a or Formula E-2b is not limited to the compounds represented in Compound Group E-2.

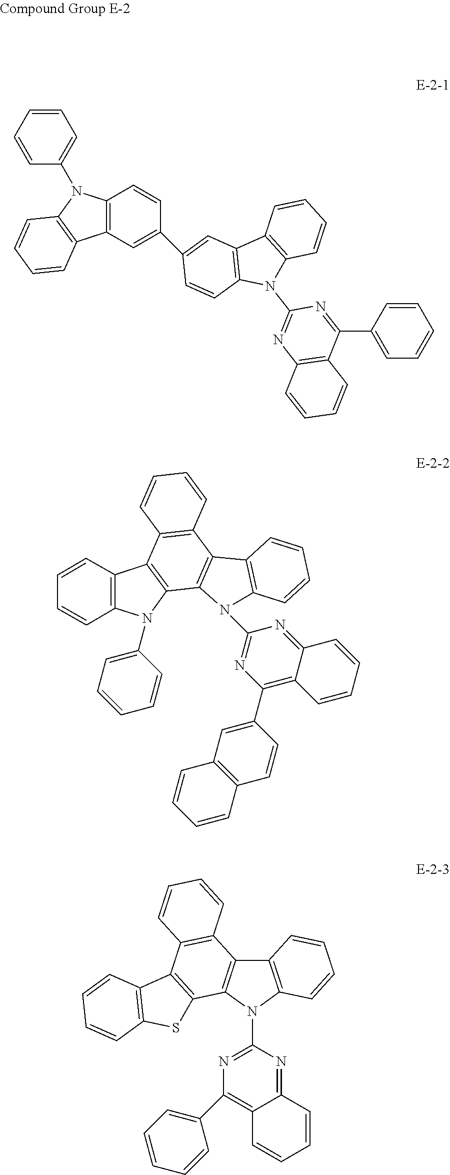 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

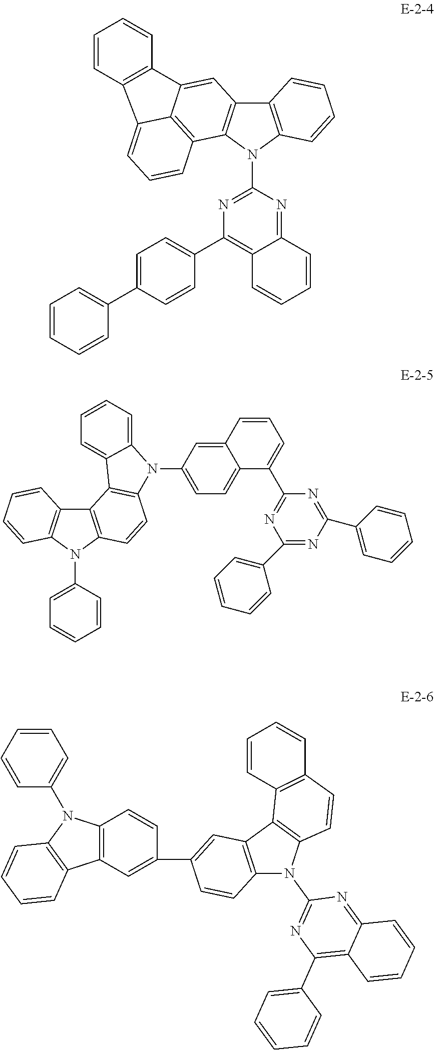 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

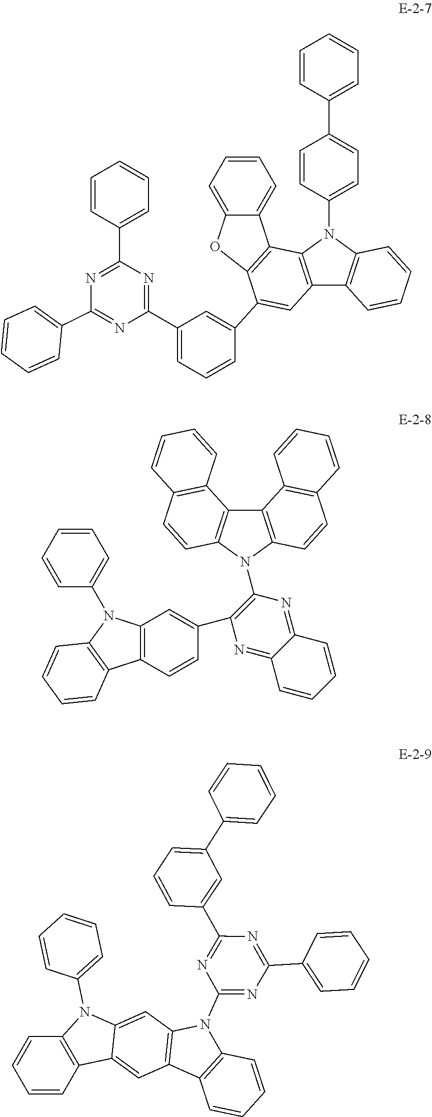 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

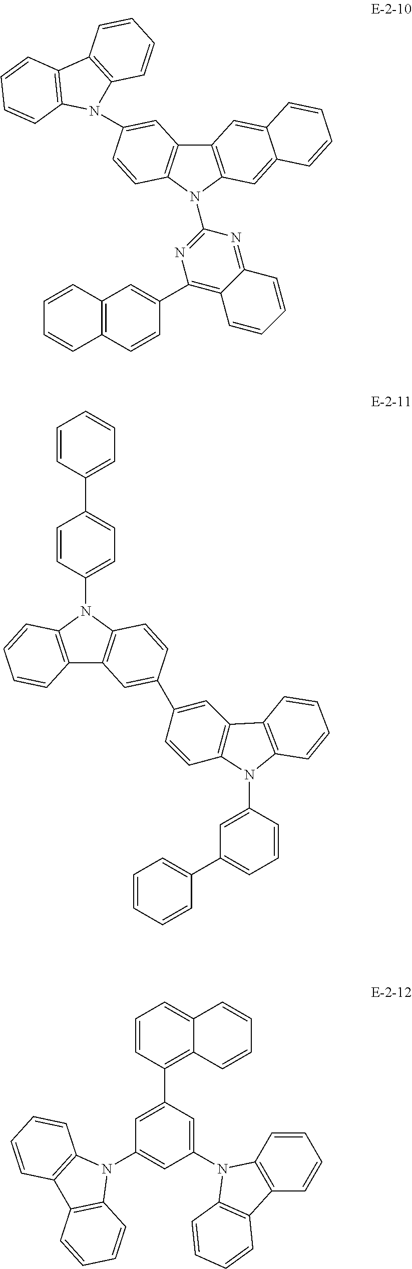 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

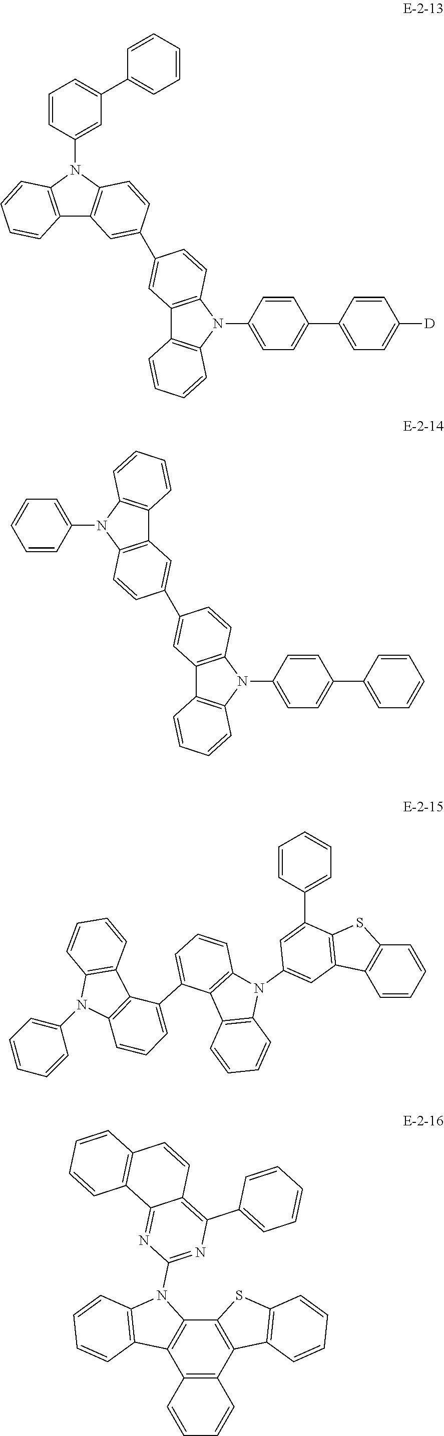 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1]

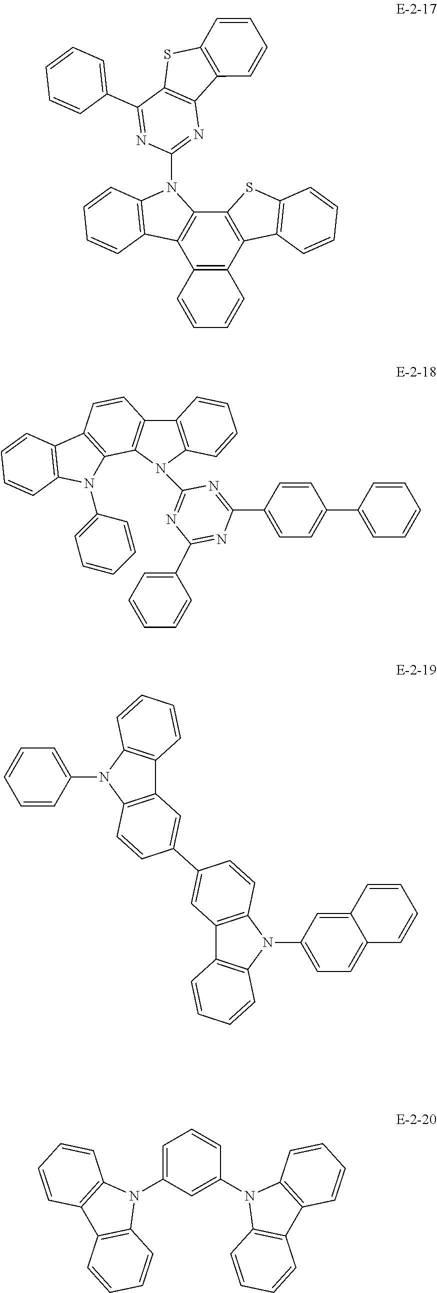 [SMILES: c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

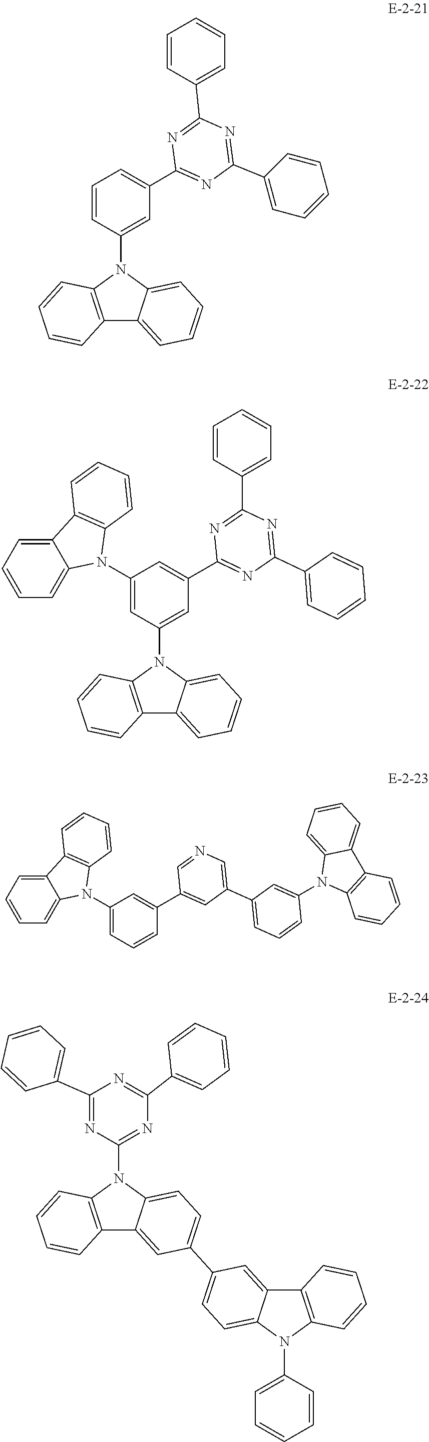 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a general material well-suitable in the art as a host material. For example, the emission layer EML may include, as a host material, at least one of bis (4-(9H-carbazol-9-yl)phenyl) diphenylsilane (BCPDS), (4-(1-(4-(diphenylamino)phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazol-2-yl)benzene (TPBi). However, embodiments of the present disclosure are not limited thereto. For example, tris(8-hydroxyquinolinato)aluminum (Alq₃), 9,10-di(naphthalen-2-yl) anthracene (ADN), 2-tert-butyl-9,10-di(naphth-2-yl) anthracene (TBADN), distyrylarylene (DSA), 4,4′-bis(9-carbazolyl)-2,2′-dimethyl-biphenyl (CDBP), 2-methyl-9,10-bis(naphthalen-2-yl) anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄) and/or the like may be used as the host material.

In one or more embodiments, the emission layer EML may include a compound represented by Formula M-a. The compound represented by Formula M-a may be used as a phosphorescence dopant material.

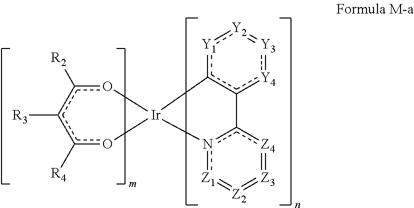

In Formula M-a, Y₁ to Y₄ and Z₁ to Z₄ may each independently be CR₁ or N, and R₁ to R₄ may each independently be hydrogen, deuterium, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In Formula M-a, “m” is 0 or 1, and “n” is 2 or 3. In Formula M-a, if (e.g., when) “m” is 0, “n” is 3, and if (e.g., when) “m” is 1, “n” is 2.

The compound represented by Formula M-a may be used as a phosphorescence dopant.

The compound represented by Formula M-a may be any one selected from among Compounds M-a1 to M-a25. However, Compounds M-a1 to M-a25 are mere examples, and the compound represented by Formula M-a is not limited to the compounds represented by Compounds M-a1 to M-a25.

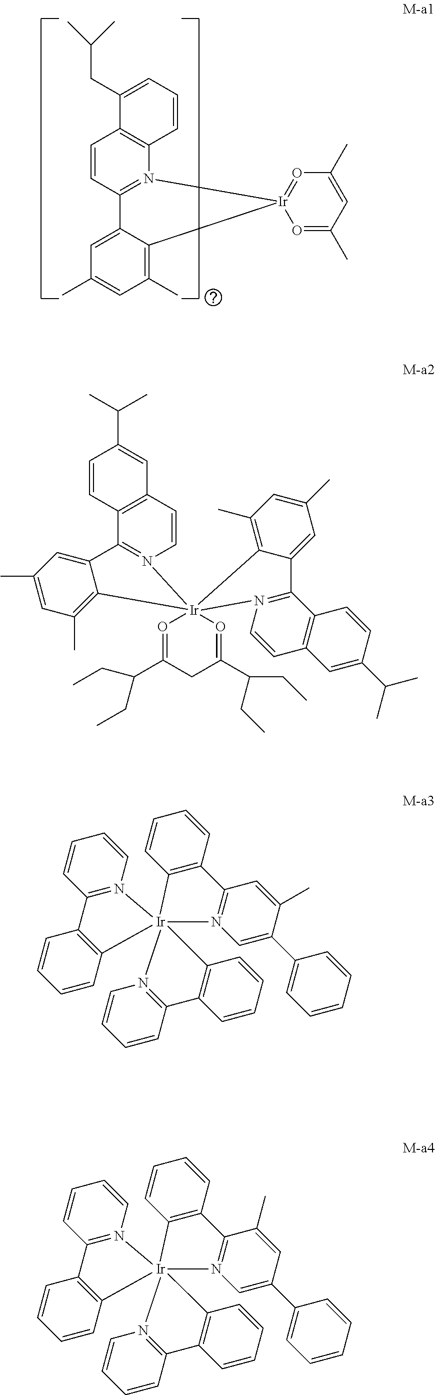

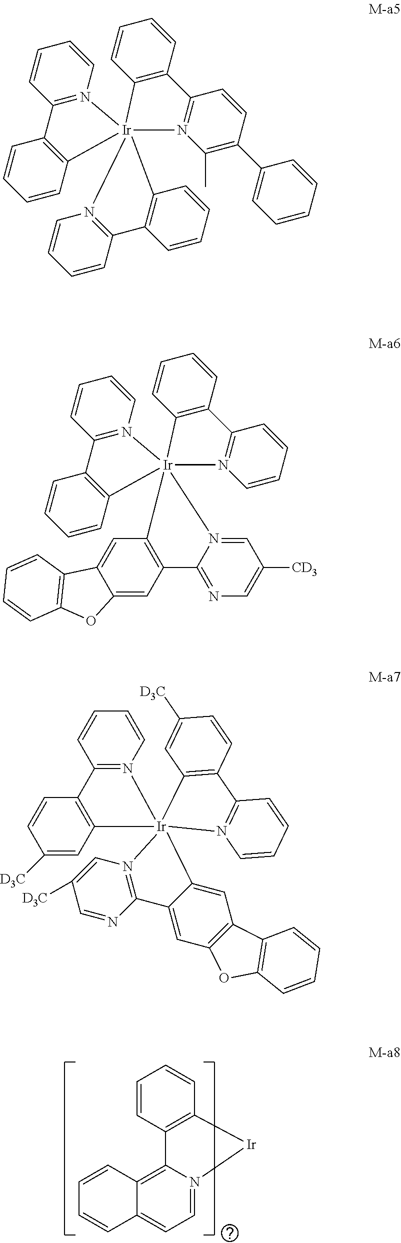

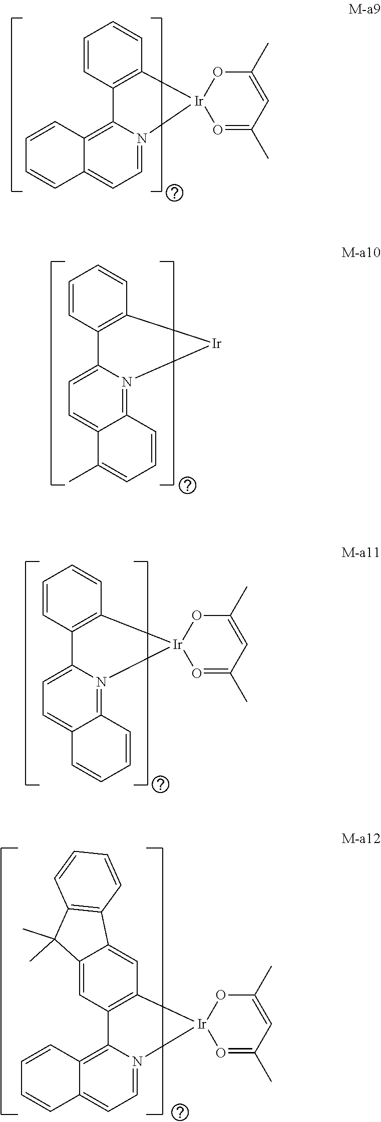

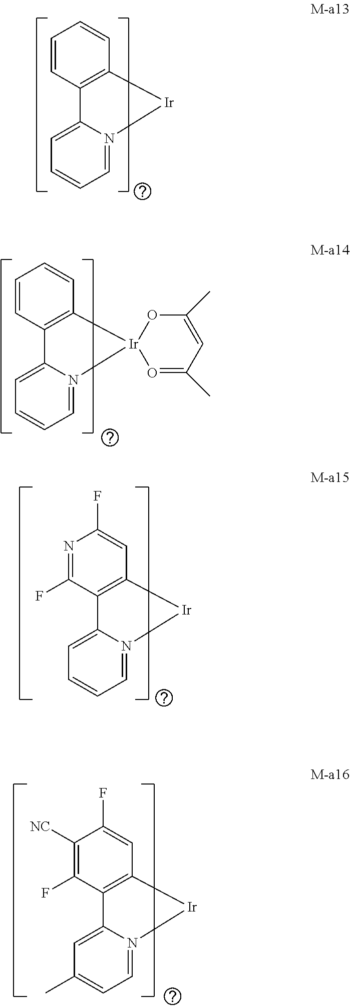

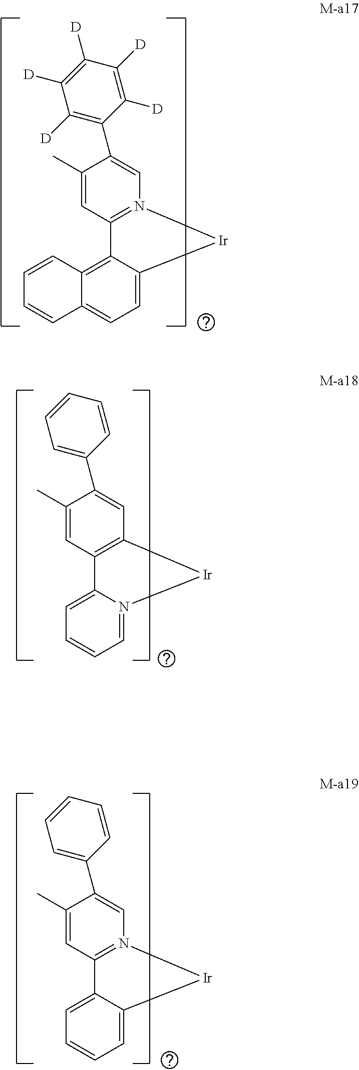

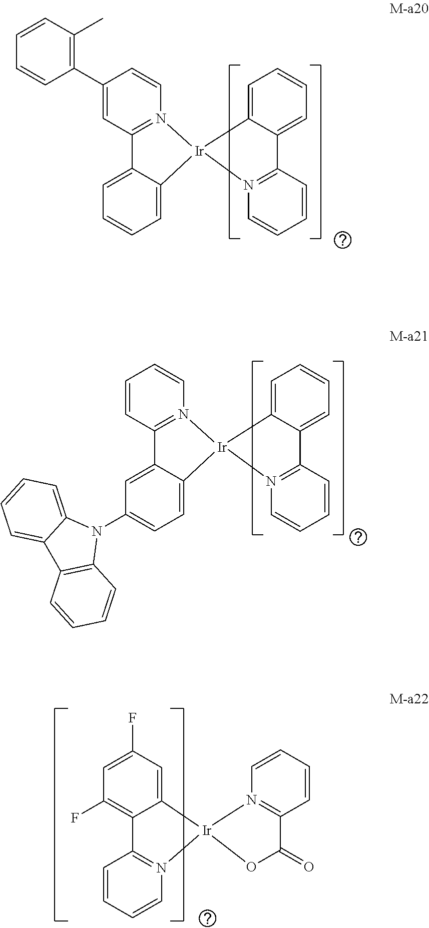

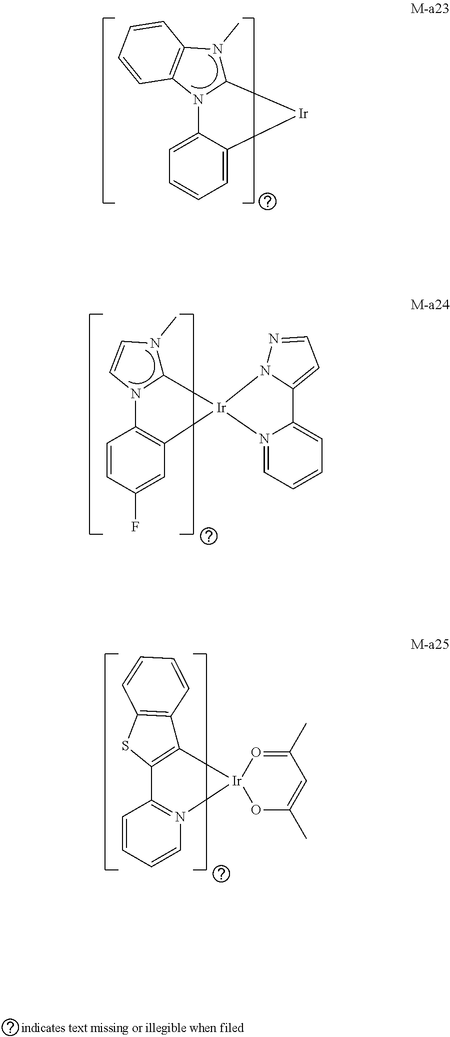

In one or more embodiments, the emission layer EML may include a compound represented by any one selected from among Formula F-a to Formula F-c. The compounds represented by Formula F-a to Formula F-c may be used as fluorescence dopant materials.

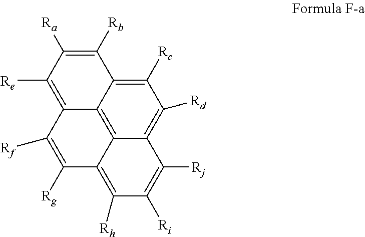

In Formula F-a, two selected from among Rₐ to Rⱼ may each independently be substituted with *—NAr₁Ar₂. The remainder not substituted with *—NAr₁Ar₂ among Rₐ to Rⱼ may each independently be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₁Ar₂, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, in one or more embodiments, at least one selected from among Ar₁ and Ar₂ may be a heteroaryl group including O or S as a ring-forming atom.

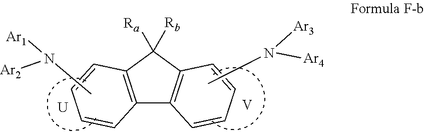

In Formula F-b, Rₐ and R_{b} may each independently be hydrogen, deuterium, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₁ to Ar₄ may each independently be a substituted or unsubstituted aryl group of 6 to 30 ring-forming carbon atoms or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms. In one or more embodiments, at least one selected from among Ar₁ to Ar₄ may be a heteroaryl group including O or S as a ring-forming atom.

In Formula F-b, the number of rings represented by U and V may each independently be 0 or 1. For example, in Formula F-b, if (e.g., when) the number of U or V is 1, one ring forms a part of a fused ring at the designated part by U or V, and if (e.g., when) the number of U or V is 0, a ring is not present at the designated part by U or V. For example, if (e.g., when) the number of U is 0, and the number of V is 1, or if (e.g., when) the number of U is 1, and the number of V is 0, a fused ring having the fluorene core of Formula F-b may be a ring compound with four rings. In one or more embodiments, if (e.g., when) the number of both (e.g., simultaneously) U and V is 0, the fused ring of Formula F-b may be a ring compound with three rings. In one or more embodiments, if (e.g., when) the number of both (e.g., simultaneously) U and V is 1, a fused ring having the fluorene core of Formula F-b may be a ring compound with five rings.

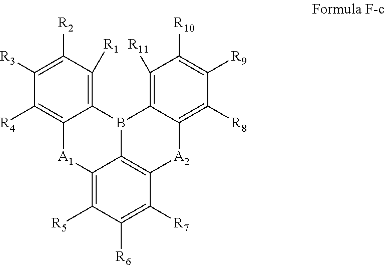

In Formula F-c, A₁ and A₂ may each independently be O, S, Se, or NRₘ, and Rₘ may be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring.

In one or more embodiments, in Formula F-c, A₁ and A₂ may each independently be combined with substituents of an adjacent ring to form a fused ring. For example, if (e.g., when) A₁ and A₂ may each independently be NRₘ, in one or more embodiments, A₁ may be combined with R₄ or R₅ to form a ring. In one or more embodiments, A₂ may be combined with R₇ or R₈ to form a ring.

In one or more embodiments, the emission layer EML may further include, as a suitable dopant material, one or more selected from among styryl derivatives (for example, 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and derivatives thereof (for example, 2,5,8,11-tetra-t-butylperylene (TBP)), pyrene and derivatives thereof (for example, 1,1-dipyrene, 1,4-dipyrenylbenzene, and 1,4-bis(N,N-diphenylamino) pyrene), and/or the like.

In one or more embodiments, the emission layer EML may further include a suitable phosphorescence dopant material. For example, the phosphorescence dopant may include a metal complex including iridium (Ir), platinum (Pt), osmium (Os), gold (Au), titanium (Ti), zirconium (Zr), hafnium (Hf), europium (Eu), terbium (Tb), or thulium (Tm). For example, in one or more embodiments, iridium (III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as the phosphorescence dopant. However, embodiments of the disclosure are not limited thereto.

In one or more embodiments, the emission layer may include a quantum dot.

In the description, the quantum dot refers to the crystal of a semiconductor compound. The quantum dot may be to emit light of one or more suitable light emitting wavelengths according to the size of the crystal of the quantum dot. The quantum dot may be to emit light of one or more suitable wavelengths by controlling an element ratio in the quantum dot compound.

A diameter of the quantum dot may be, for example, about 1 nm to about 10 nm. In the present disclosure, when dot, dots, or dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dot may be synthesized by a chemical bath deposition, a metal organic chemical vapor deposition, a molecular beam epitaxy, or a similar process therewith.

The chemical bath deposition is a method of growing quantum dot particle crystal after mixing an organic solvent and a precursor material of a quantum dot. During the growth of the crystal, the organic solvent naturally plays the role of a dispersant coordinated at the surface of the quantum dot crystal and may control the growth of the crystal. Accordingly, the chemical bath deposition is more favorable than a vapor deposition method such as a metal organic chemical vapor deposition (MOCVD) and a molecular beam epitaxy (MBE), and may control the growth of the quantum dot particle through a low cost process.

The emission layer of one or more embodiments of the present disclosure may include a quantum dot material. In one or more embodiments, the quantum dot may have a core/shell structure. The core of the quantum dot may be selected from among Group II-VI compounds, Group III-V compounds, Group III-VI compounds, Group I-III-VI compounds, Group IV-VI compounds, Group IV elements, Group IV compounds, and/or one or more (e.g., any suitable) combinations thereof.

The Group II-VI compound may be selected from the group consisting of: a binary compound such as CdSe, CdTe, CdS, ZnS, ZnSe, ZnTe, ZnO, HgS, HgSe, HgTe, MgSe, MgS, and mixtures thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. In one or more embodiments, the Group II-VI compound may further include Group I metal(s) and/or Group IV element(s). The Group I-II-VI compound may be selected from among CuSnS and CuZnS, and the Group II-IV-VI compound may be selected from among ZnSnS and/or the like. The Group I-II-IV-VI compound may be selected from among a quaternary compound selected from the group consisting of Cu₂ZnSnS₂, Cu₂ZnSnS₄, Cu₂ZnSnSe₄, Ag₂ZnSnS₂, and mixtures thereof.

The Group III-VI compound may include: a binary compound such as In₂S₃ and/or In₂Se₃; a ternary compound such as InGaS₃ and/or InGaSe₃; or a (e.g., any suitable) combination thereof.

The Group I-III-VI compound may be selected from among: a ternary compound such as AgInS, AgInS₂, CuInS, CuInS₂, AgGaS₂, CuGaS₂ CuGaO₂, AgGaO₂, AgAlO₂, and mixtures thereof; and/or a quaternary compound such as AgInGaS₂ and/or CuInGaS₂.

The Group III-V compound may be selected from the group consisting of: a binary compound such as GaN, GaP, GaAs, GaSb, AlN, AlP, AlAs, AlSb, InN, InP, InAs, InSb, and mixtures thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; and a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In one or more embodiments, the Group III-V compound may further include a Group II metal. For example, InZnP, and/or the like, may be selected as a Group III-II-V compound.

The Group IV-VI compound may be selected from the group consisting of: a binary compound such as SnS, SnSe, SnTe, PbS, PbSe, PbTe, and mixtures thereof; a ternary compound such as SnSeS, SnSeTe, SnSTe, PbSeS, PbSeTe, PbSTe, SnPbS, SnPbSe, SnPbTe, and mixtures thereof; and a quaternary compound such as SnPbSSe, SnPbSeTe, SnPbSTe, and mixtures thereof.

The Group II-IV-V compound may be a ternary compound selected from the group consisting of ZnSnP, ZnSnP₂, ZnSnAs₂, ZnGeP₂, ZnGeAs₂, CdSnP₂, CdGeP₂, and mixtures thereof.

The Group IV element may be selected from the group consisting of Si, Ge and a (e.g., any suitable) mixture thereof. The Group IV compound may be a binary compound selected from the group consisting of SiC, SiGe and a (e.g., any suitable) mixture thereof.

Each element included in a polynary compound such as the binary compound, the ternary compound, or the quaternary compound may be present at substantially uniform concentration or non-uniform concentration in a particle. For example, the afore-mentioned chemical formulae may refer to the types (kinds) of elements included in the compound, and an element ratio in the compound may be different. For example, AgInGaS₂ may refer to AgInₓGa₁₋ₓS₂ (x is a real number of 0 to 1).

In this regard, the binary compound, ternary compound, or quaternary compound may be present in a particle in a substantially uniform concentration or may be present in the same particle in partially different concentration distribution. In addition, the quantum dot may have a core/shell structure in which one quantum dot wraps another quantum dot. In one or more embodiments, the core/shell structure may have a concentration gradient of decreasing concentration of elements present in the shell toward the core.

In one or more embodiments, the quantum dot may have a core-shell structure including a core including the above-described nanocrystal and a shell around (e.g., surrounding) the core. The shell of the quantum dot may play the role of a protection layer for preventing or reducing the chemical deformation of the core to maintain semiconductor properties and/or a charging layer for imparting the quantum dot with electrophoresis characteristics. The shell may be a single layer or a multilayer. Examples of the shell of the quantum dot may include an oxide of a metal or nonmetal, a semiconductor compound, and/or a (e.g., any suitable) combination thereof.

For example, the metal or non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; or a ternary compound such as MgAl₂O₄, CoFe₂O₄, NiFe₂O₄, and/or CoMn₂O₄. However, embodiments of the present disclosure are not limited thereto.

In addition, the semiconductor compound suitable as a shell may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, and/or the like. However, embodiments of the present disclosure are not limited thereto.

The quantum dot may have a full width at half maximum (FWHM) of emission spectrum of about 45 nm or less, about 40 nm or less, or about 30 nm or less. Within these ranges, color purity or color reproducibility of the quantum dot may be improved. In addition, light emitted via such quantum dots is emitted in all directions, and light view angle may be improved.

In addition, the shape of the quantum dot may be a commonly used shape in the art, without specific limitation, for example, the quantum dot may be a spherical nanoparticle, a pyramidal nanoparticle, a multi-arm nanoparticle, a cubic nanoparticle, a nanotube, a nanowire, a nanofiber, a nanoplate particle, and/or the like.

Because an energy band gap of the quantum dot may be controlled or selected by controlling the size of the quantum dot or controlling an element ratio in the quantum dot compound, light of one or more suitable wavelength bands may be obtained from a quantum dot emission layer. Accordingly, by using the quantum dot (by using quantum dots having different sizes or by changing the element ratio in the quantum dot compound), a light emitting element emitting light of one or more suitable wavelengths may be accomplished. For example, the size of the quantum dots and/or the element ratio in the quantum dot compound may be selected to enable the quantum dots to emit red color, green color, and/or blue color light. In addition, the quantum dots may be composed for emitting white light through the combination of light of one or more suitable colors.

In the light emitting elements ED of embodiments, shown in FIGS. 7 to 9, the electron transport region ETR may be provided on the emission layer EML. The electron transport region ETR may include at least one selected from among an electron transport region ETR, a hole blocking layer EBL, an electron transport layer ETL, and an electron injection layer EIL, but embodiments of the disclosure are not limited thereto.

The electron transport region ETR may have a single layer formed of a single material, a single layer formed of multiple different materials, or a multilayer structure having multiple layers formed of multiple different materials.

For example, in one or more embodiments, the electron transport region ETR may have a single layer structure of an electron injection layer EIL or an electron transport layer ETL, or a single layer structure formed of an electron injection material and/or an electron transport material. In one or more embodiments, the electron transport region ETR may have a single layer structure formed of multiple different materials, or a structure stacked from the emission layer EML of electron transport layer ETL/electron injection layer EIL, or hole blocking layer EBL/electron transport layer ETL/electron injection layer EIL, without limitation. A thickness of the electron transport region ETR may be, for example, from about 1,000 Å to about 1,500 Å.

The electron transport region ETR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-2.

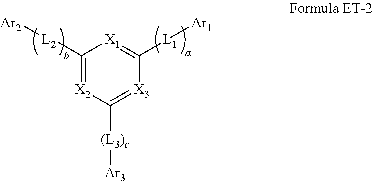

In Formula ET-2, at least one selected from among X₁ to X₃ may be N, and the remainder are CRₐ. Rₐ may be hydrogen, deuterium, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may each independently be an integer of 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. In one or more embodiments, if (e.g., when) “a” to “c” are each an integer of 2 or greater, L₁(s) to L₃(s) may each independently be a substituted or unsubstituted arylene group of 6 to 30 ring-forming carbon atoms or a substituted or unsubstituted heteroarylene group of 2 to 30 ring-forming carbon atoms.

In one or more embodiments, the electron transport region ETR may include an anthracene-based compound. However, embodiments of the disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalen-2-yl)anthracene (ADN), 1,3-bis[3,5-di(pyridin-3-yl)phenyl]benzene (BmPyPhB), 4′-(4-(4-(4,6-diphenyl-1,3,5-triazin-2-yl)phenyl)naphthalen-1-yl)-[1,1′-biphenyl]-4-carbonitrile (CNNPTRZ), and/or a (e.g., any suitable) mixture thereof, without limitation.

In one or more embodiments, the electron transport region ETR may include at least one selected from among Compounds ET1 to ET36.

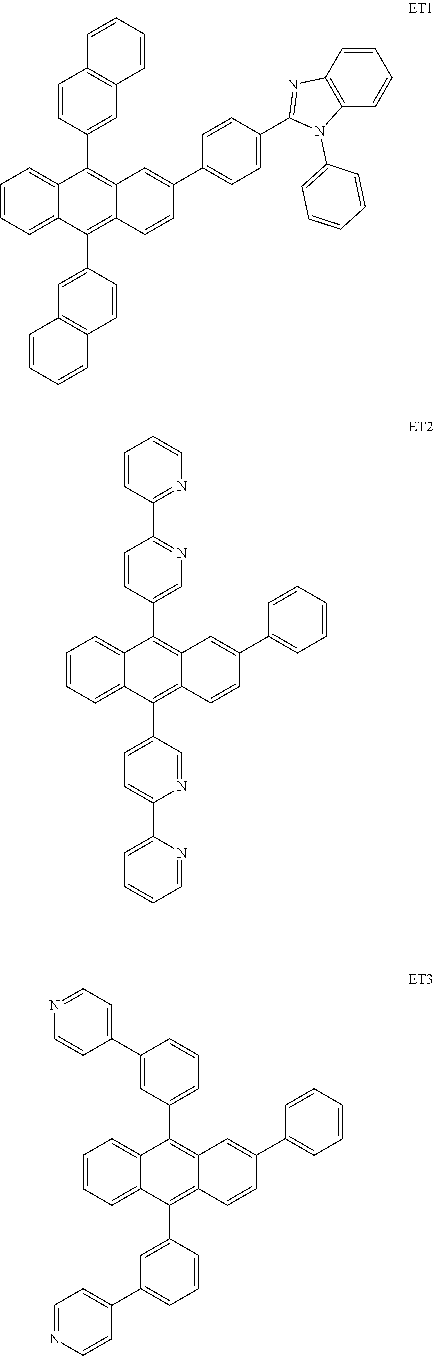 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

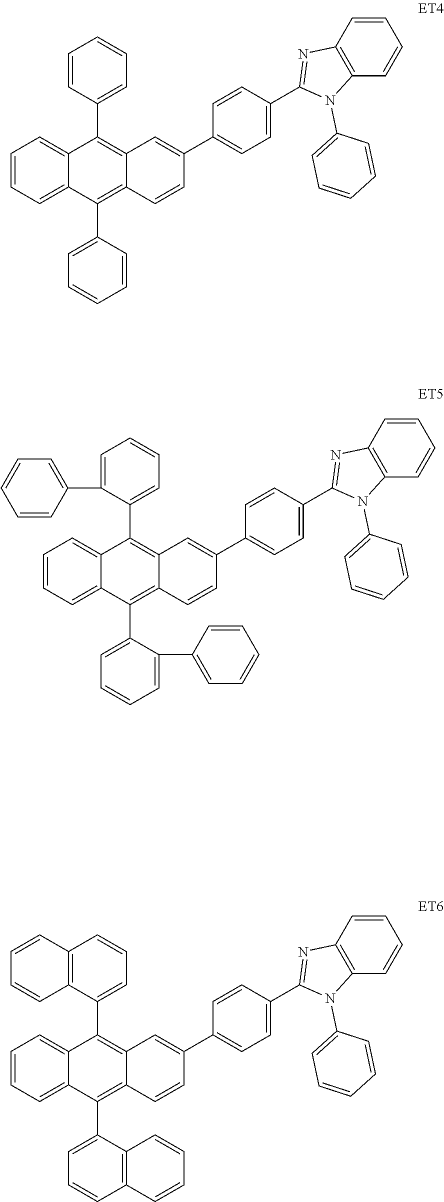 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

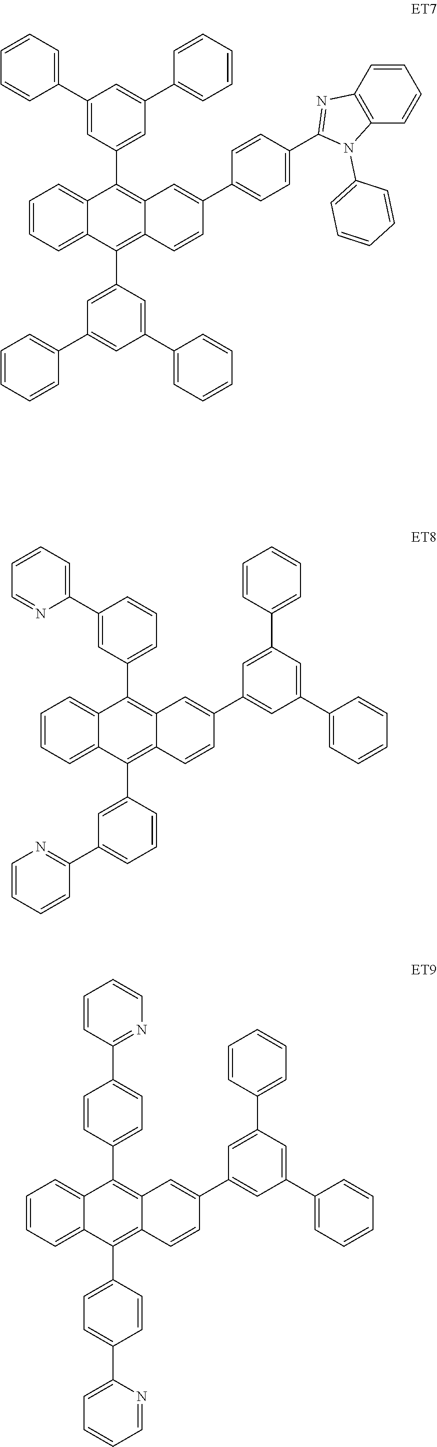 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

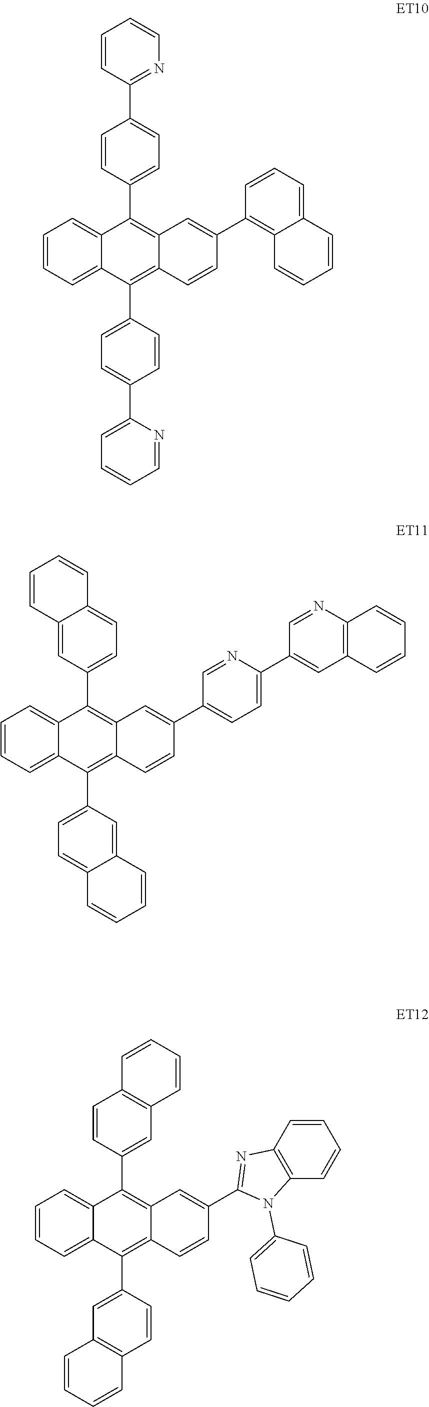 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

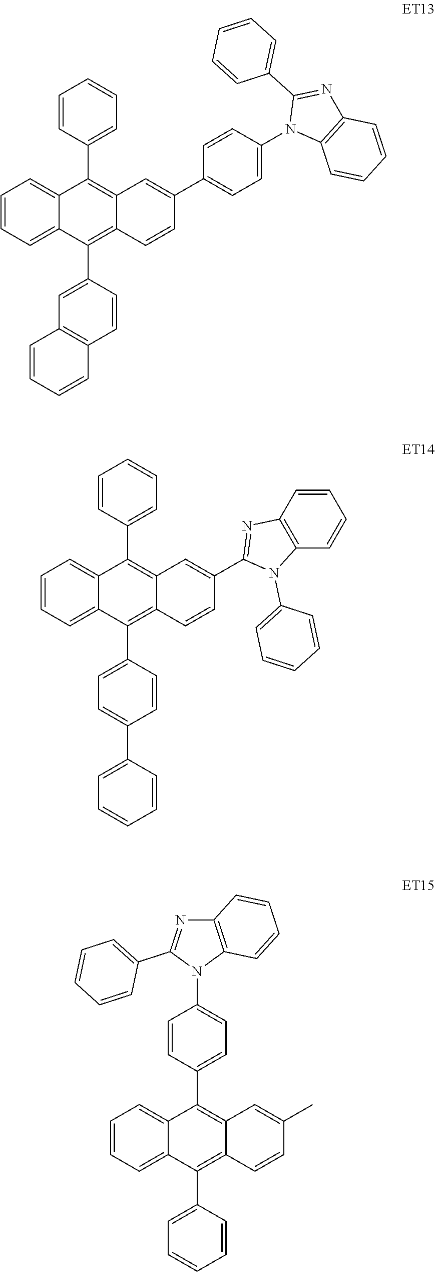 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

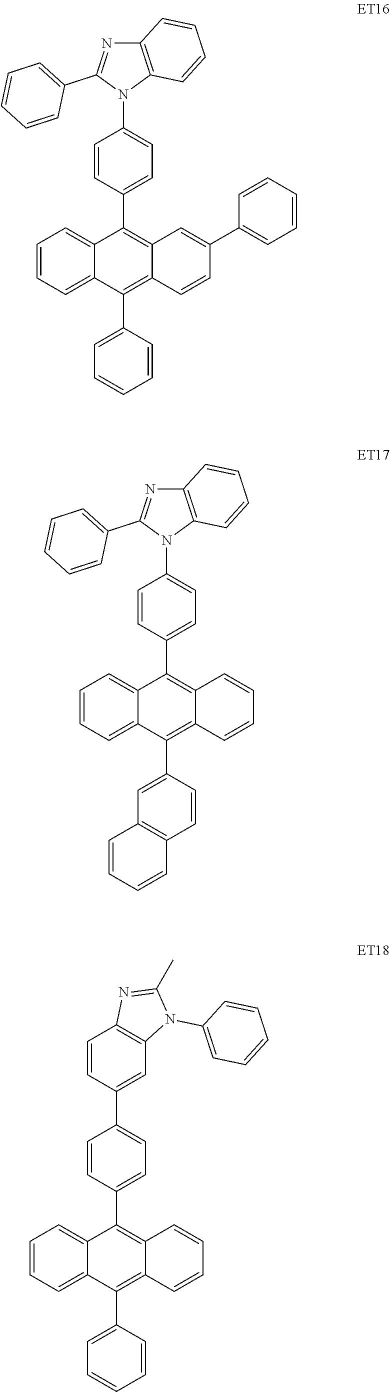 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

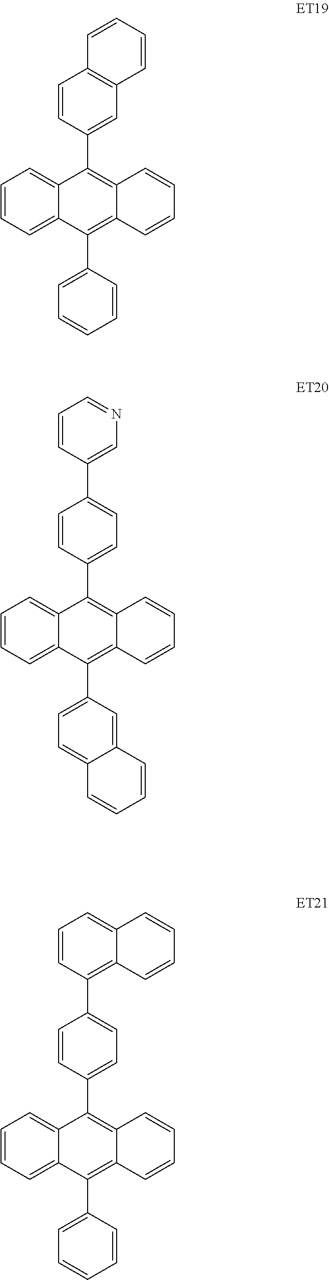

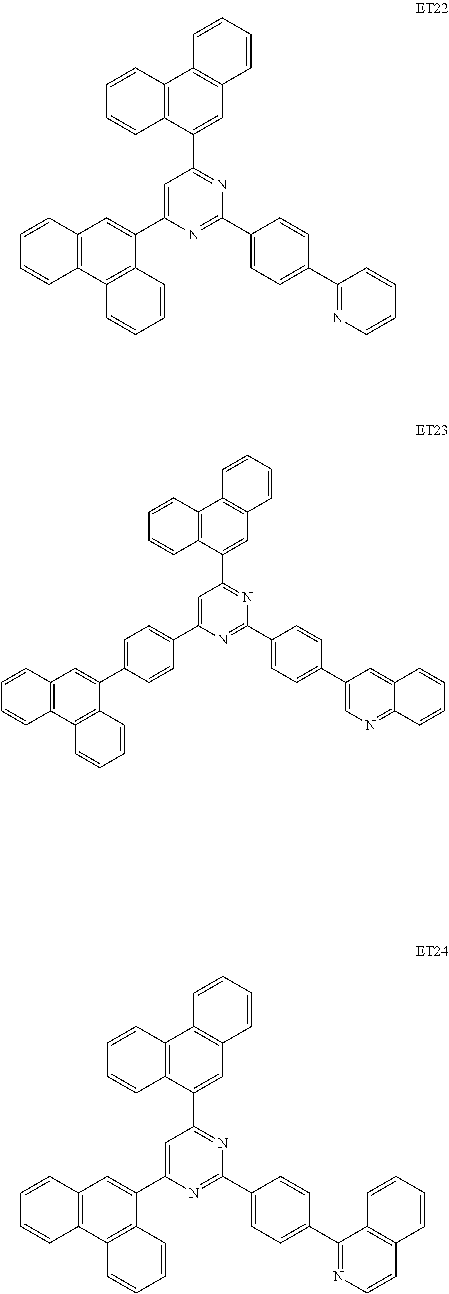 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

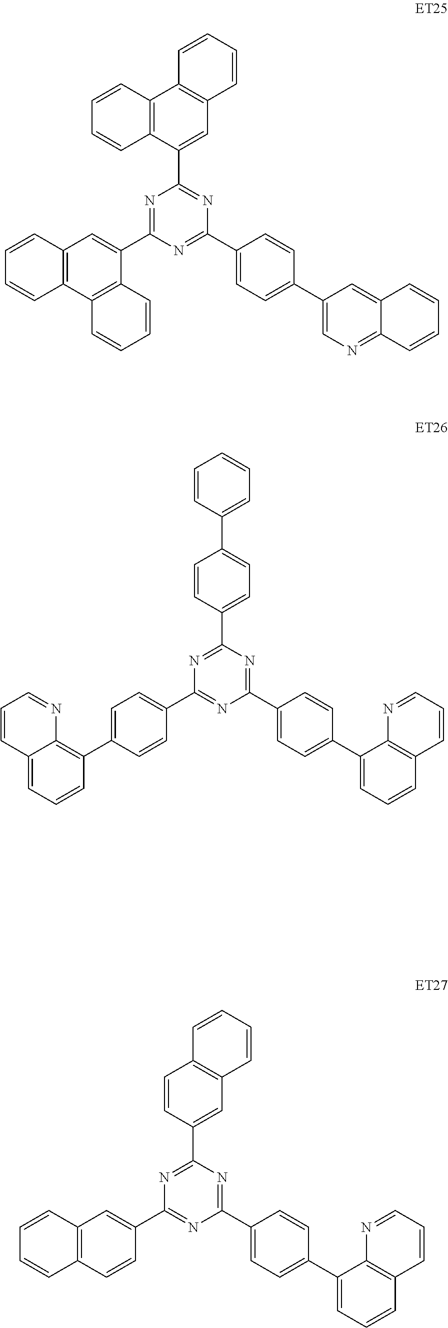 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

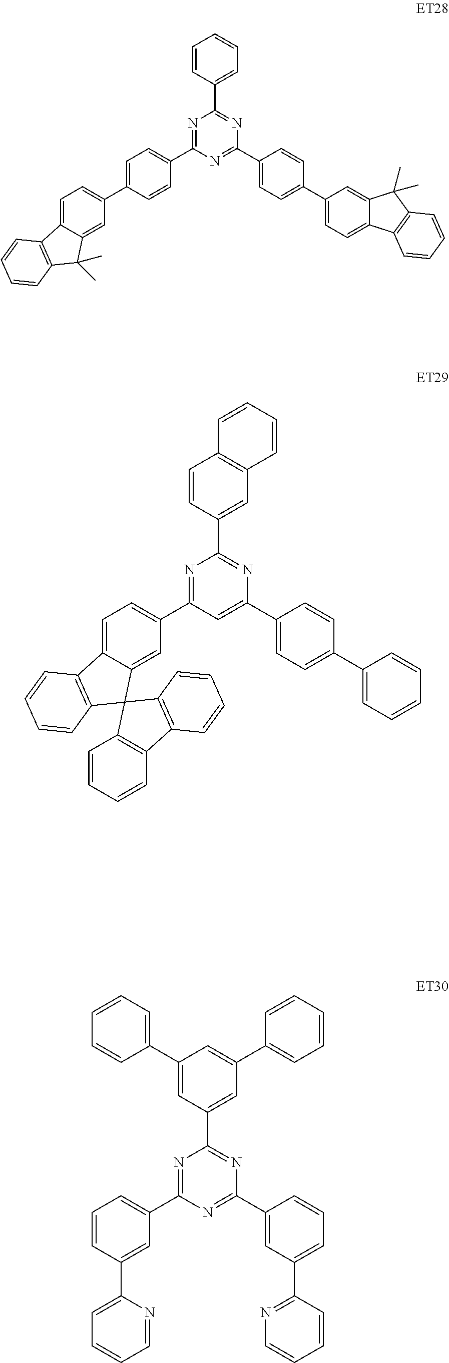 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

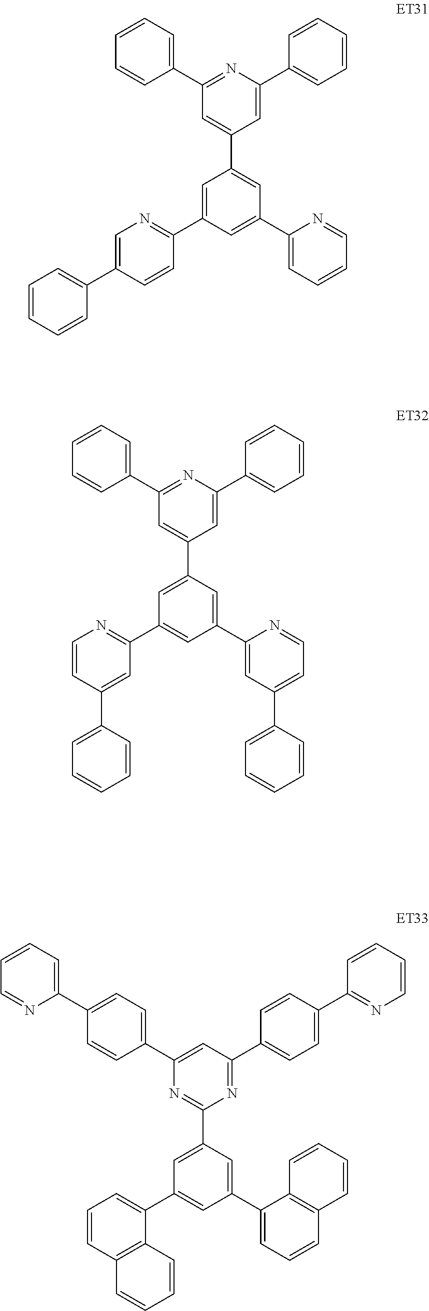 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

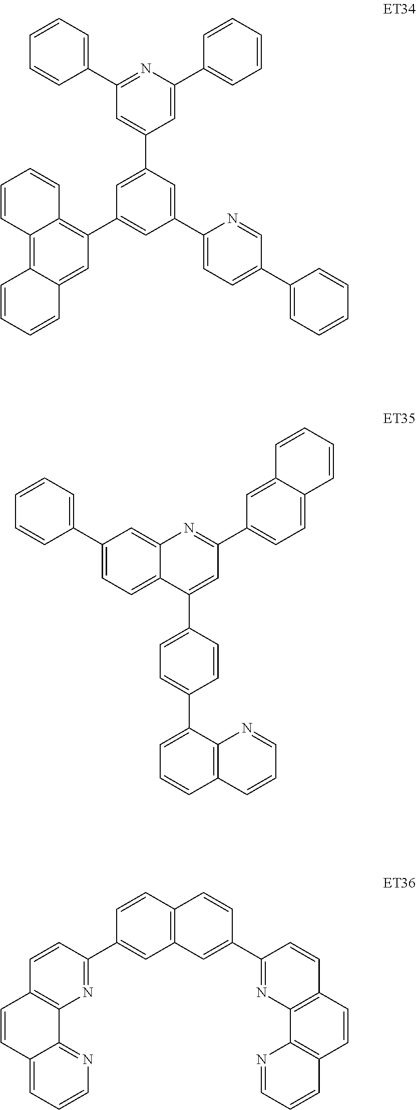 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region ETR may include a metal halide such as LiF, NaCl, CsF, RbCl, RbI, CuI, and/or KI, a lanthanide metal such as Yb, or a co-depositing material of the metal halide and the lanthanide metal. For example, in one or more embodiments, the electron transport region ETR may include KI:Yb, RbI:Yb, LiF:Yb, and/or the like, as the co-depositing material. In one or more embodiments, the electron transport region ETR may include a metal oxide such as Li₂O and/or BaO, or 8-hydroxy-lithium quinolate (Liq). However, embodiments of the present disclosure are not limited thereto. The electron transport region ETR also may be formed of a mixture material of an electron transport material and an insulating organo metal salt. The insulating organo metal salt may be a material having an energy band gap of about 4 eV or more. For example, the organo metal salt may include, for example, one or more of metal acetates, metal benzoates, metal acetoacetates, metal acetylacetonates, or metal stearates.

In one or more embodiments, the electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the aforementioned materials. However, embodiments of the disclosure are not limited thereto.

The electron transport region ETR may include one or more of the compounds of the electron transport region in at least one selected from among an electron injection layer EIL, an electron transport layer ETL, and a hole blocking layer EBL.

If (e.g., when) the electron transport region ETR includes an electron transport layer ETL, a thickness of the electron transport layer ETL may be from about 100 Å to about 1,000 Å, for example, from about 150 Å to about 500 Å. If (e.g., when) the thickness of the electron transport layer ETL satisfies the above-described range, satisfactory electron transport properties may be obtained without substantial increase of a driving voltage. If (e.g., when) the electron transport region ETR includes an electron injection layer EIL, a thickness of the electron injection layer EIL may be from about 1 Å to about 100 Å, for example, from about 3 Å to about 90 Å. If (e.g., when) the thickness of the electron injection layer EIL satisfies the above described range, satisfactory electron injection properties may be obtained without inducing substantial increase of a driving voltage.

In one or more embodiments, a layer closest to the second electrode EL2 in the electron transport region ETR may be described as an “auxiliary layer.” In the light emitting elements ED of embodiments shown in FIG. 8 and FIG. 9, the electron injection layer EIL may be described as an auxiliary layer.

As described above, in one or more embodiments, the electron injection layer EIL may include a lanthanide metal such as ytterbium Yb. If (e.g., when) the electron injection layer EIL includes ytterbium, ytterbium has a relatively low work function, making it easy to inject electrons, thereby reducing a driving voltage, and has low absorption in the visible light range, thereby improving light transmittance. If (e.g., when) the electron injection layer EIL includes ytterbium (Yb), the thickness of the electron injection layer EIL may be about 5 Å to about 505 Å. If (e.g., when) the electron injection layer EIL has a thickness within the above range, light transmittance may be increased while electron mobility may be improved, thereby improving emission efficiency.

The second electrode EL2 may be provided on the electron transport region ETR. In one or more embodiments, the second electrode EL2 may be a common electrode. The second electrode EL2 may be a cathode or an anode, but embodiments of the present disclosure are not limited thereto. For example, if (e.g., when) the first electrode EL1 is an anode, the second cathode EL2 may be a cathode, and if (e.g., when) the first electrode EL1 is a cathode, the second electrode EL2 may be an anode.

In one or more embodiments, the second electrode EL2 includes a silver (Ag)-magnesium (Mg) alloy (i.e., a silver-magnesium alloy). In one or more embodiments, the second electrode EL2 may include a silver (Ag)-magnesium (Mg) alloy in which the silver content (e.g., amount) is greater than the magnesium content (e.g., amount). The silver (Ag)-magnesium (Mg) alloy may be a silver-rich (Ag-rich) alloy in which the silver content (e.g., amount) is greater than the magnesium content (e.g., amount).

Silver (Ag), i.e., silver, is a metal with high electrical conductivity and low light absorption, which may improve electrical and optical properties. Magnesium (Mg), i.e., magnesium, is a metal with low work function, which may improve charge mobility and increase reliability by increasing the strength of an electrode thin film.

In the second electrode EL2, magnesium (Mg) may be included in the content (e.g., amount) of about 30 vol % or less relative to a total content (e.g., amount) of 100 vol % of the silver (Ag)-magnesium (Mg) alloy, and may be included in the content (e.g., amount) of about 0.001 to about 30 vol %. As the second electrode EL2 includes magnesium (Mg) in the above range, the stability of the electrode thin film may be secured while increasing light transmittance and decreasing light absorption, thereby improving efficiency.

In one or more embodiments, magnesium (Mg) may be included in the content (e.g., amount) of about 1 vol % to about 30 vol % on the basis of the total content (e.g., amount) of 100 vol % of the silver (Ag)-magnesium (Mg) alloy. In one or more embodiments, magnesium (Mg) may be included in the content (e.g., amount) of about 5 vol % to about 15 vol % on the basis of the total content (e.g., amount) of 100 vol % of the silver (Ag)-magnesium (Mg) alloy. Accordingly, while forming the second electrode EL2, the silver (Ag)-magnesium (Mg) alloy may be easily formed while improving efficiency.

In one or more embodiments, the second electrode EL2 may further include ytterbium (Yb). Because ytterbium (Yb) has a relatively low work function, electron injection into the electron transport layer ETL from the second electrode EL2 may be easy, a driving voltage may be reduced, and absorption in a visible light range may be low to improve light transmittance. If (e.g., when) the second electrode EL2 further includes ytterbium (Yb), ytterbium may be included in the content (e.g., amount) of about 5 vol % to about 30 vol % relative to the total content (e.g., amount) of 100 vol % of the silver (Ag)-magnesium (Mg) alloy included in the second electrode EL2.

In one or more embodiments, a thickness of the second electrode EL2 may be about 30 Å to about 105 Å. In one or more embodiments, the thickness of the second electrode EL2 may be about 30 Å to about 80 Å. If (e.g., when) the thickness of the second electrode EL2 is less than about 30 Å, sufficient film quality may not be secured if (e.g., when) forming a film of the second electrode EL2 using the silver (Ag)-magnesium (Mg) alloy, and thus the function of the second electrode EL2 may be reduced and deteriorated. If (e.g., when) the thickness of the second electrode EL2 exceeds about 105 Å, the reflectivity of the second electrode EL2 may be excessively (or substantially) increased, and thus the transmittance of the light emitting element ED may be reduced.

In one or more embodiments, the second electrode EL2 may be connected with an auxiliary electrode. If (e.g., when) the second electrode EL2 is connected with the auxiliary electrode, the resistance of the second electrode EL2 may be reduced.

In one or more embodiments, the capping layer CPL may be arranged on the second electrode EL2 of the light emitting element ED of one or more embodiments. The capping layer CPL may include a multilayer or a single layer.

In one or more embodiments, a refractive index of the capping layer CPL may be about 2.2 to about 2.5. For example, for light in a wavelength range of about 460 nm to about 800 nm, the refractive index of the capping layer CPL may be about 2.2 to about 2.5. In one or more embodiments, for light in a wavelength range of about 460 nm to about 800 nm, the refractive index of the capping layer CPL may be about 2.45.

In one or more embodiments, the capping layer CPL may be an organic layer or an inorganic layer. For example, if (e.g., when) the capping layer CPL includes an inorganic material, the inorganic material may include one or more selected from among alkali metal compounds such as LiF, alkaline earth metal compounds such as MgF₂, SiON, SiNₓ, SiO_{y}, zinc oxide, titanium oxide, zirconium oxide, niobium oxide, tantalum oxide, tin oxide, nickel oxide, indium nitride, gallium nitride, and/or the like.

For example, if (e.g., when) the capping layer CPL includes an organic material, the organic material may include at least one selected from among α-NPD, NPB, TPD, m-MTDATA, Alq₃, CuPc, N4,N4,N4′,N4′-tetra (biphenyl-4-yl) biphenyl-4,4′-diamine (TPD15), 4,4′,4″-tris (carbazol-9-yl) triphenylamine (TCTA), poly(3,4-ethylenedioxythiophene) (PEDOT), 4,4′-bis[N-(3-methylphenyl)-N-phenyl amino]biphenyl (TPD), 4,4′,4″-tris[(3-methylphenyl)phenyl amino]triphenylamine (m-MTDATA), 1,3,5-tris[N,N-bis(2-methylphenyl)-amino]-benzene (o-MTDAB), 1,3,5-tris[N,N-bis(3-methylphenyl)-amino]-benzene (m-MTDAB), 1,3,5-tris[N,N-bis(4-methylphenyl)-amino]-benzene (p-MTDAB), 4,4′-bis[N,N-bis(3-methylphenyl)-amino]-diphenylmethane (BPPM), 4,4′-dicarbazolyl-1,1′-biphenyl (CBP), 4,4′,4″-tris(N-carbazole)triphenylamine (TCTA), 2,2′,2″-(1,3,5-benzentolyl)tris-[1-phenyl-1H-benzimidazole] (TPBI), and 3-(4-biphenyl)-4-phenyl-5-t-butylphenyl-1,2,4-triazole (TAZ).

In one or more embodiments, if (e.g., when) the capping layer CPL includes an organic material, the organic material may be represented by Formula 1. The organic material represented by Formula 1 may have a refractive index of about 2.2 to about 2.5 in a wavelength range of about 460 nm to about 800 nm.

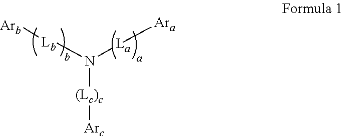

In Formula 1, Arₐ to Ar_{c} may each independently be a substituted or unsubstituted aryl group of 6 to 30 ring-forming carbon atoms or a substituted or unsubstituted heteroaryl group of 2 to 30 ring-forming carbon atoms. For example, in one or more embodiments, at least one selected from among Arₐ to Ar_{c} may be an aryl group of 6 to 30 carbon atoms, substituted with an amine group. In one or more embodiments, one or more (e.g., each) of Arₐ to Ar_{c} may be, for example, substituted with an aryl group, a heteroaryl group, or an amine group, or an unsubstituted phenyl group. In one or more embodiments, one or more (e.g., each) of Arₐ to Ar_{c} may be, for example, a fluorenyl group substituted with an alkyl group, an amine group, or an aryl group, an unsubstituted fluorenyl group, a carbazole group substituted with a phenyl group, or a naphthyl group substituted with an aryl group, a heteroaryl group, or an amine group.

In Formula 1, Lₐ to L_{c} may each independently be a direct linkage, a substituted or unsubstituted arylene group of 6 to 30 ring-forming carbon atoms, or a substituted or unsubstituted heteroarylene group of 2 to 30 ring-forming carbon atoms.

In Formula 1, “a” to “c” may each independently be an integer of 0 to 3. In one or more embodiments, if (e.g., when) “a” to “c” are each an integer of 2 or greater, multiple Lₐ(s) to L_{c}(s) may each independently be a substituted or unsubstituted arylene group of 6 to 30 ring-forming carbon atoms or a substituted or unsubstituted heteroarylene group of 2 to 30 ring-forming carbon atoms.

In one or more embodiments, the organic material represented by Formula 1 may be any one selected from among compounds in Compound Group 1. The capping layer of the light emitting element ED of one or more embodiments may include at least one selected from among the compounds in Compound Group 1.

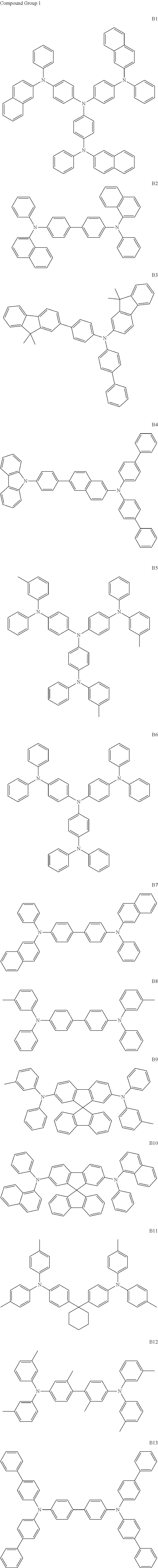

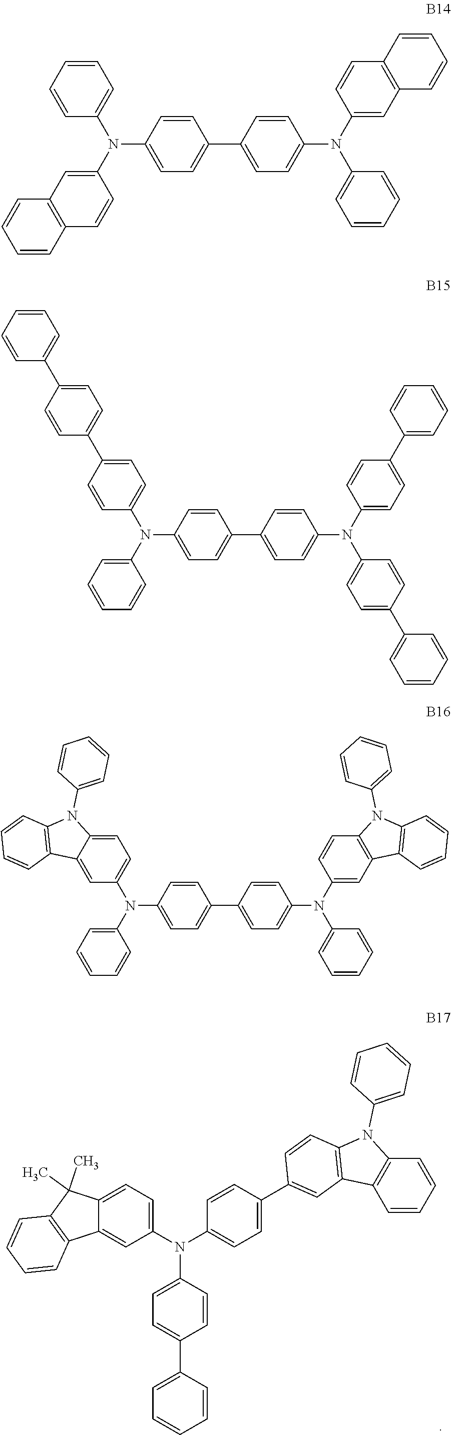 [SMILES: c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A thickness of the capping layer CPL may be about 200 Å to about 500 Å. In one or more embodiments, the thickness of the capping layer CPL may be, for example, about 200 Å to about 300 Å. If (e.g., when) the thickness of the capping layer CPL is less than about 200 Å, the light absorption of the light emitting element ED may increase excessively (or substantially), thereby reducing emission efficiency. If (e.g., when) the thickness of the capping layer CPL exceeds about 500 Å, the reflectivity by the capping layer CPL may increase excessively (or substantially), thereby decreasing emission efficiency, and light efficiency may decrease significantly in a high viewing angle range.

The capping layer CPL may be provided at a constant ratio compared to the thickness of the second electrode EL2. If the thickness of the second electrode EL2 is defined as a first thickness and the thickness of the capping layer CPL is defined as a second thickness, the first thickness may be about 0.15 to about 0.4 compared to the second thickness, i.e., about 0.15 to about 0.4 times the second thickness. By providing the thicknesses of the capping layer CPL and the second electrode EL2 to satisfy the above range, the light emitting element ED may have emission efficiency of a set or predetermined value or more, while having high light efficiency even in a high viewing angle range.

In one or more embodiments, the capping layer CPL may have a light transmittance of about 75% or more at a wavelength of about 550 nm. In one or more embodiments, the capping layer CPL may have a light transmittance of greater than about 65% to about 90% in a visible light range, i.e., a wavelength range of about 450 to about 750 nm. The capping layer CPL may have a light transmittance of greater than about 65% to about 90% in a visible light range, including the thickness and refractive index as described above.

In one or more embodiments, the capping layer CPL may have a light reflectance of about 1% to less than about 30% in a wavelength range of about 450 nm to about 750 nm, and may have a light absorption of about 15% or less in a wavelength range of about 450 nm to about 750 nm. The capping layer CPL may have a light reflectance of about 1% to less than about 30% in a visible light range, and may have a light absorption of about 15% or less, including the thickness and refractive index as described above.

Based on a top of the capping layer CPL, a luminance of the light emitting element ED at a side viewing angle of about 60 degrees may be about 20% or more compared to a luminance at a front viewing angle. The light emitting element ED of one or more embodiments may have a luminance reduction of less than about 80% at a side viewing angle of about 60 degrees based on the top of the capping layer CPL. For example, the light emitting element ED of one or more embodiments may have a luminance reduction of about 40% to about 75% at a side viewing angle of about 60 degrees based on the top of the capping layer CPL. The light emitting element ED of one or more embodiments includes the second electrode EL2 containing the silver (Ag)-magnesium (Mg) alloy and the capping layer CPL containing a high refractive index material as described above, and has a structure in which the thickness of each of the second electrode EL2 and the capping layer CPL is limited to a set or predetermined range. Accordingly, excellent or suitable emission efficiency may be achieved while preventing or reducing the luminance reduction from becoming excessively (or substantially) high in a high viewing angle range. As a result, the emission efficiency of the light emitting element ED may be improved, and the display characteristics in the side viewing angle range of the electronic device DD (FIG. 6) including the light emitting element ED may be improved.

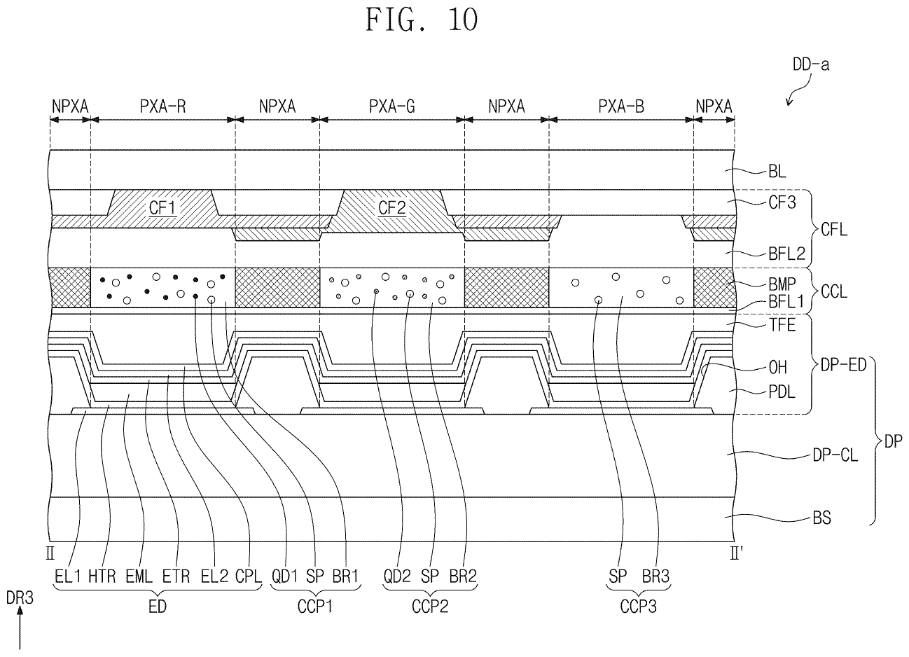

FIGS. 10 to 13 are each a cross-sectional view of a display device according to one or more embodiments of the present disclosure. In the explanation of display devices according to one or more embodiments with reference to FIGS. 10 to 13, the content that overlaps with those explained in FIGS. 1 to 9 will not be explained again for conciseness, and instead only differences will be mainly described.

Referring to FIG. 10, a display device DD-a according to one or more embodiments may include a display panel DP including a display element layer DP-ED, a light control layer CCL arranged on the display panel DP, and a color filter layer CFL. In one or more embodiments as shown in FIG. 10, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR arranged on the first electrode EL1, an emission layer EML arranged on the hole transport region HTR, an electron transport region ETR arranged on the emission layer EML, a second electrode EL2 arranged on the electron transport region ETR, and a capping layer CPL arranged on the second electrode EL2. In one or more embodiments, any of the structures of the light emitting elements of FIGS. 7 to 9 described above may be applied in substantially the same manner to the structure of the light emitting element ED shown in FIG. 10. The description of the materials, thicknesses, refractive indices, and/or the like of the second electrode EL2 and the capping layer CPL of the light emitting elements ED described above in the description of FIGS. 7 to 9 may be applied in substantially the same manner to the second electrode EL2 and the capping layer CPL of the light emitting element ED included in the display device DD-a according to one or more embodiments.

Referring to FIG. 10, the emission layer EML may be arranged within an opening OH defined in a pixel defining layer PDL. For example, the emission layer EML provided corresponding to each of light emitting areas PXA-R, PXA-G, and PXA-B, distinguished by the pixel defining layer PDL, may be to emit light of the same wavelength range. In the display device DD-a of one or more embodiments, the emission layer EML may be to emit blue light. In one or more embodiments, the emission layer EML may be provided as a common layer across all of the light emitting areas PXA-R, PXA-G, and PXA-B.

The light control layer CCL may be arranged on the display panel DP. The light control layer CCL may include a light converter. The light converter may be a quantum dot or a phosphor. The light converter may convert the wavelength of the light provided and then emit the converted light. For example, the light control layer CCL may be a layer including a quantum dot or a layer including a phosphor.

The light control layer CCL may include multiple light control parts CCP1, CCP2, and CCP3. The light control parts CCP1, CCP2, and CCP3 may be spaced and/or apart (e.g., spaced apart or separated) from one another.

Referring to FIG. 10, a division pattern BMP may be arranged between the light control parts CCP1, CCP2, and CCP3 that are spaced and/or apart (e.g., spaced apart or separated) from one another, but embodiments of the present disclosure are not limited thereto. In FIG. 10, the division pattern BMP is illustrated as not overlapping with the light control parts CCP1, CCP2, and CCP3, but, in one or more embodiments, the edges of the light control parts CCP1, CCP2, and CCP3 may at least partially overlap with the division pattern BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 that transmits the first color light. In one or more embodiments, the first light control part CCP1 may provide red light, which is the second color light, and the second light control part CCP2 may provide green light, which is the third color light. The third light control part CCP3 may be to transmit and provide blue light, which is the first color light provided from the light emitting element ED. For example, in one or more embodiments, the first quantum dot QD1 may be a red quantum dot to emit red light, and the second quantum dot QD2 may be a green quantum dot to emit green light. The same content as described above on quantum dots may be applied to quantum dots QD1 and QD2.

In one or more embodiments, the light control layer CCL may further include a scatterer SP. The first light control part CCP1 may include a first quantum dot QD1 and a scatterer SP, the second light control part CCP2 may include a second quantum dot QD2 and a scatterer SP, and the third light control part CCP3 may not include (e.g., may exclude) any quantum dot but include a scatterer SP.

The scatterer SP may be an inorganic particle. For example, the scatterer SP may include at least one of TiO₂, ZnO, Al₂O₃, SiO₂, or hollow silica. In one or more embodiments, the scatterer SP may include any one selected from among TiO₂, ZnO, Al₂O₃, SiO₂, and hollow silica, or may be a mixture of two or more materials selected from among TiO₂, ZnO, Al₂O₃, SiO₂, and hollow silica.

The first light control part CCP1, the second light control part CCP2, and the third light control part CCP3 may include base resins BR1, BR2, and BR3, respectively, in which quantum dots QD1 and QD2 and the scatterer SP are dispersed accordingly. In one or more embodiments, the first light control part CCP1 may include the first quantum dot QD1 and the scatterer SP, dispersed in a first base resin BR1, the second light control part CCP2 may include the second quantum dot QD2 and the scatterer SP, dispersed in a second base resin BR2, and the third light control part CCP3 may include the scatterer SP dispersed in a third base resin BR3.

The base resins BR1, BR2, and BR3 are mediums in which quantum dots QD1 and QD2 and the scatterer SP are dispersed accordingly, and may be composed of one or more suitable resin compositions that may generally be referred to as a binder. For example, the base resins BR1, BR2, and BR3 may each independently be one or more selected from among acrylic resins, urethane resins, silicone resins, epoxy resins, and/or the like. The base resins BR1, BR2, and BR3 may each be a transparent resin. In one or more embodiments, the first base resin BR1, the second base resin BR2, and the third base resin BR3 may be the same as or different from one another.

In one or more embodiments, the light control layer CCL may include a barrier layer BFL1. The barrier layer BFL1 may serve to prevent or reduce the penetration of moisture and/or oxygen (hereinafter referred to as “moisture/oxygen”). The barrier layer BFL1 may block the light control parts CCP1, CCP2, and CCP3 from being exposed to moisture/oxygen. In one or more embodiments, the barrier layer BFL1 may cover the light control parts CCP1, CCP2, and CCP3. In one or more embodiments, a barrier layer BFL2 may also be provided between the light control parts CCP1, CCP2, and CCP3 and the color filter layer CFL.

The barrier layers BFL1 and BFL2 may each include at least one inorganic layer. For example, in one or more embodiments, the barrier layers BFL1 and BFL2 may be each formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide, and/or silicon oxynitride, or a metal thin film having secured light transmittance. In one or more embodiments, the barrier layers BFL1 and BFL2 may each independently further include an organic film. Each of the barrier layers BFL1 and BFL2 may be formed as a single layer or multiple layers.

In the display device DD-a of one or more embodiments, the color filter layer CFL may be arranged on the light control layer CCL. For example, in one or more embodiments, the color filter layer CFL may be arranged directly on the light control layer CCL. In these embodiments, the barrier layer BFL2 may not be provided.

The color filter layer CFL may include first to third filters CF1, CF2, and CF3. The first to third filters CF1, CF2 and CF3 may be arranged to correspond to a red light emitting area PXA-R, a green light emitting area PXA-G, and a blue light emitting area PXA-B, respectively.

In one or more embodiments, the color filter layer CFL may include a first filter CF1 that transmits the second color light, a second filter CF2 that transmits the third color light, and a third filter CF3 that transmits the first color light. For example, in one or more embodiments, the first filter CF1 may be a red filter, the second filter CF2 may be a green filter, and the third filter CF3 may be a blue filter. Each of the filters CF1, CF2 and CF3 may include a polymer photosensitive resin, and a pigment and/or a dye. The first filter CF1 may include a red pigment and/or a red dye, the second filter CF2 may include a green pigment and/or a green dye, and the third filter CF3 may include a blue pigment and/or a blue dye.

In one or more embodiments, the third filter CF3 may not include (e.g., may exclude) any pigment or dye. The third filter CF3 may include a polymer photosensitive resin and may not include (e.g., may exclude) any pigment or dye. The third filter CF3 may be transparent. The third filter CF3 may be formed of a transparent photosensitive resin.

In one or more embodiments, the first filter CF1 and the second filter CF2 may be yellow filters. The first filter CF1 and the second filter CF2 may be provided as one body without being separated from each other.

In one or more embodiments, the color filter layer CFL may further include a light-shielding part. The light-shielding part may be a black matrix. The light-shielding part may be formed by including an organic light-shielding material or an inorganic light-shielding material, including a black pigment and/or a black dye. The light-shielding part may prevent or reduce light leakage and may distinguish boundaries between adjacent filters CF1, CF2, and CF3.

In one or more embodiments, a base substrate BL may be arranged on the color filter layer CFL. The base substrate BL may be a member that provides a base surface on which the color filter layer CFL and the light control layer CCL are arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

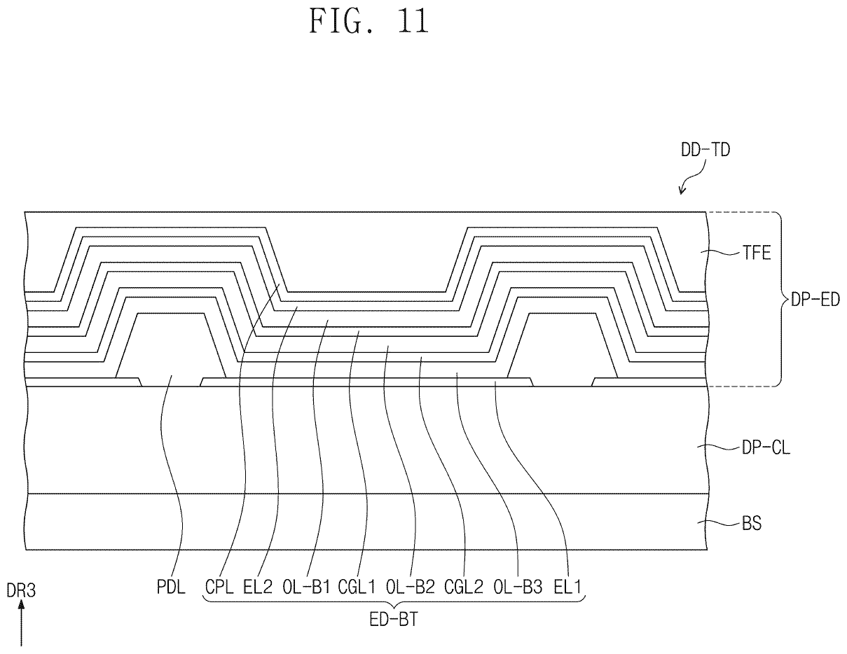

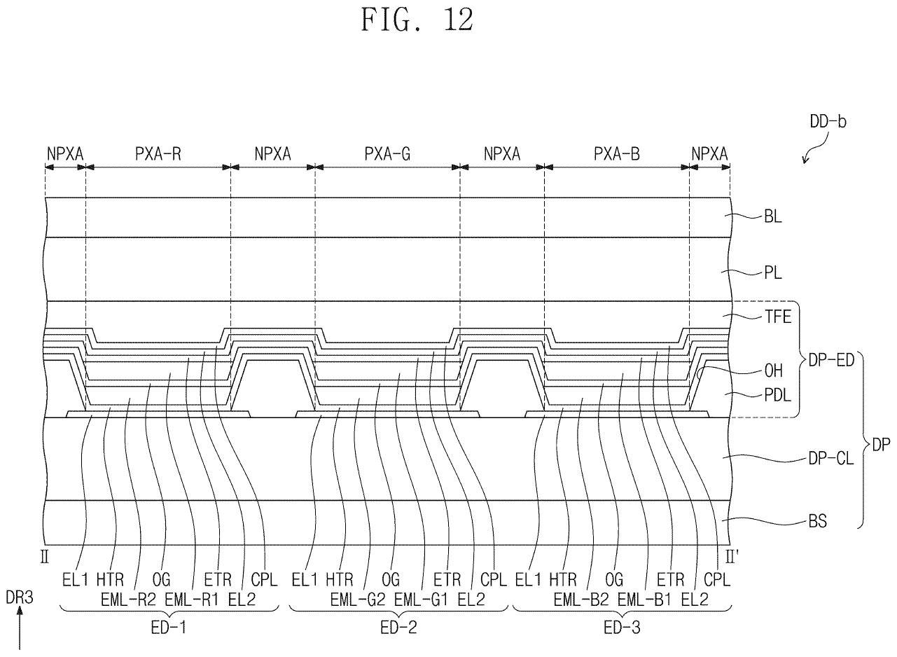

FIG. 11 is a cross-sectional view showing a portion of a display device according to one or more embodiments of the present disclosure. In a display device DD-TD of one or more embodiments, a light emitting element ED-BT may include multiple light emitting structures OL-B1, OL-B2, and OL-B3. The light emitting element ED-BT may include a first electrode EL1 and an oppositely arranged second electrode EL2, and multiple light emitting structures OL-B1, OL-B2, and OL-B3, which are sequentially stacked in a thickness direction between the first electrode EL1 and the second electrode EL2. Each of the light emitting structures OL-B1, OL-B2, and OL-B3 may include an emission layer EML (FIG. 10), and a hole transport region HTR (FIG. 10) and an electron transport region ETR (FIG. 10), arranged with the emission layer EML (FIG. 10) interposed therebetween.

For example, the light emitting element ED-BT included in the display device DD-TD of one or more embodiments may be a light emitting element of a tandem structure including multiple emission layers.

In one or more embodiments shown in FIG. 11, all light emitted from the light emitting structures OL-B1, OL-B2, and OL-B3 may be blue light. However, embodiments of the present disclosure are not limited thereto, and the wavelength ranges of light emitted from the light emitting structures OL-B1, OL-B2, and OL-B3 may be different from one another. For example, in one or more embodiments, the light emitting element ED-BT including multiple light emitting structures OL-B1, OL-B2, and OL-B3 that emit light in different wavelength ranges may be to emit white light (e.g., combined white light).

Charge generating layers CGL1 and CGL2 may be arranged between neighboring light emitting structures OL-B1, OL-B2, and OL-B3. The charge generating layers CGL1 and CGL2 may each include a p-type (kind) charge (e.g., P-charge) generating layer and/or an n-type (kind) charge (e.g., N-charge) generating layer.

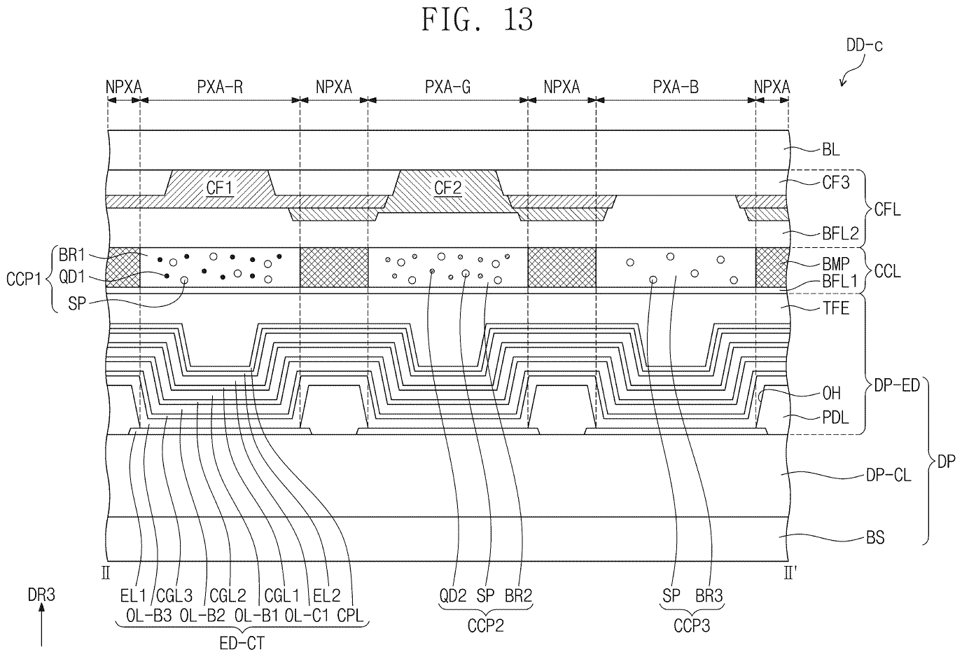

FIG. 12 is a cross-sectional view showing a display device according to one or more embodiments of the present disclosure. FIG. 13 is a cross-sectional view showing a display device according to one or more embodiments of the present disclosure.

Referring to FIG. 12, a display device DD-b according to one or more embodiments may include light emitting elements ED-1, ED-2, and ED-3 in each of which two emission layers are stacked. Compared to the electronic device DD of one or more embodiments illustrated in FIG. 6, the display device DD-b illustrated in FIG. 12 differs in that each of the first to third light emitting elements ED-1, ED-2, and ED-3 includes two emission layers stacked in a thickness direction. The two emission layers in each of the first to third light emitting elements ED-1, ED-2, and ED-3 may be to emit light in substantially the same wavelength range.

In one or more embodiments, the first light emitting element ED-1 may include a first red emission layer EML-R1 and a second red emission layer EML-R2. The second light emitting element ED-2 may include a first green emission layer EML-G1 and a second green emission layer EML-G2. In addition, the third light emitting element ED-3 may include a first blue emission layer EML-B1 and a second blue emission layer EML-B2. An emission auxiliary part OG may be arranged between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or multiple layers. The emission auxiliary part OG may include a charge generating layer. For example, the emission auxiliary part OG may include an electron transport region, a charge generating layer, and a hole transport region, which are sequentially stacked. The emission auxiliary part OG may be provided as a common layer throughout the first to third light emitting elements ED-1, ED-2, and ED-3. However, embodiments of the disclosure are not limited thereto, and the emission auxiliary part OG may be patterned and provided within an opening OH defined in a pixel defining layer PDL.

The first red emission layer EML-R1, the first green emission layer EML-G1, and the first blue emission layer EML-B1 may each be arranged between the emission auxiliary part OG and the electron transport region ETR. The second red emission layer EML-R2, the second green emission layer EML-G2, and the second blue emission layer EML-B2 may be arranged between the hole transport region HTR and the emission auxiliary part OG.

For example, in one or more embodiments, the first light emitting element ED-1 may include a first electrode EL1, a hole transport region HTR, a second red emission layer EML-R2, an emission auxiliary part OG, a first red emission layer EML-R1, an electron transport region ETR, a second electrode EL2, and a capping layer CPL, which are sequentially stacked (e.g., in the stated order). The second light emitting element ED-2 may include a first electrode EL1, a hole transport region HTR, a second green emission layer EML-G2, an emission auxiliary part OG, a first green emission layer EML-G1, an electron transport region ETR, a second electrode EL2, and a capping layer CPL, which are sequentially stacked (e.g., in the stated order). The third light emitting element ED-3 may include a first electrode EL1, a hole transport region HTR, a second blue emission layer EML-B2, an emission auxiliary part OG, a first blue emission layer EML-B1, an electron transport region ETR, a second electrode EL2, and a capping layer CPL, which are sequentially stacked (e.g., in the stated order).

In one or more embodiments, an optical auxiliary layer PL may be arranged on the display element layer DP-ED. The optical auxiliary layer PL may include a polarizing layer. The optical auxiliary layer PL may be arranged on the display panel DP to control light reflected from the display panel DP due to external light. In one or more embodiments, the optical auxiliary layer PL may not be provided in the display device DD-b.

At least one of the second electrode EL2 or the capping layer CPL, included in the display device DD-b of one or more embodiments illustrated in FIG. 12, may include the materials, thicknesses, refractive indexes, and/or the like as described above.

Different from FIG. 11 and FIG. 12, a display device DD-c of FIG. 13 is illustrated to include four light emitting structures OL-B1, OL-B2, OL-B3, and OL-C1. A light emitting element ED-CT may include first to fourth light emitting structures OL-B1, OL-B2, OL-B3, and OL-C1, which are stacked in a thickness direction between a first electrode EL1 and an opposite arranged second electrode EL2. Charge generating layers CGL1, CGL2, and CGL3 may each be separately arranged between the first to fourth light emitting structures OL-B1, OL-B2, OL-B3, and OL-C1. In one or more embodiments, among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit light in different wavelength ranges. The light emitting element ED-CT includes a capping layer CPL arranged on the second electrode EL2.

The charge generating layers CGL1, CGL2, and CGL3 arranged between neighboring light emitting structures OL-B1, OL-B2, OL-B3, and OL-C1 may each independently include a p-type (kind) charge (e.g., P-charge) generating layer and/or an n-type (kind) charge (e.g., N-charge) generating layer.

At least one selected from among the light emitting structures OL-B1, OL-B2, OL-B3, and OL-C1 included in the display device DD-c of one or more embodiments may include the hole transport region described above. For example, in one or more embodiments, at least one selected from among the first to third light emitting structures OL-B1, OL-B2, and OL-B3 may include a first hole transport layer including a first hole transport material, as in the above-described embodiment, and a portion of the first hole transport layer may include a structure doped with a p-dopant.

The light emitting element ED according to one or more embodiments of the present disclosure includes one or more functional layers FL (FIG. 5) arranged between a first electrode EL1 and a second electrode EL2, and includes a capping layer CPL arranged on the second electrode EL2. As described above, the light emitting element ED of one or more embodiments includes a second electrode EL2 including a silver (Ag)-magnesium (Mg) alloy (i.e., a silver-magnesium alloy) and a capping layer CPL including a highly refractive material, and has a structure in which the thicknesses of the second electrode EL2 and the capping layer CPL are limited to set or predetermined ranges, so that the light emitting element ED has excellent or suitable emission efficiency, while preventing or reducing luminance reduction from becoming excessively (or substantially) high in a high viewing angle range. Accordingly, the emission efficiency of the light emitting element ED may be improved, and the display characteristics of the electronic device DD (FIG. 6) including the light emitting element ED may be improved in a side viewing angle range.

In one or more embodiments, an electronic device may include the display device of the present disclosure including multiple light emitting elements, and a control part that controls the display device. The electronic device of one or more embodiments may be a device that is activated according to an electrical signal. The electronic device may include display devices of one or more suitable embodiments. For example, the electronic device may include large-sized display devices such as a television, a monitor, or an external billboard as well as small or medium-sized display devices such as a personal computer, a notebook computer, a personal digital assistant, a vehicle display device, a game console, a portable electronic device, or a camera.

Hereinafter, light emitting elements according to one or more embodiments of the present disclosure will be described in more detail with reference to Examples and Comparative example. In addition, the Examples shown hereinafter are examples to assist the understanding of the present disclosure, and the scope of the disclosure is not limited thereto.

### EXAMPLES

### 1. Manufacture of Light Emitting Elements of Examples and Comparative Example

### Manufacture of Light Emitting Element of Example 1

As an anode, a glass substrate, on which ITO/Ag/ITO with thicknesses of about 70 Å/1,000 Å/70 Å were deposited, was cut into a size of about 50 mm×50 mm×0.4 mm, cleansed using ultrasonic waves with isopropyl alcohol and then with pure water for about 10 minutes each, exposed to UV for about 10 minutes and cleansed by exposing to ozone, and then, the glass substrate (anode) was installed in a vacuum deposition apparatus.

H-1-5 was deposited on the anode to form a hole injection layer with a thickness of about 700 Å, and then Compound H-1-1 was deposited to form a hole transport layer with a thickness of about 800 Å. Thereafter, TCTA and Ir(ppy)₃ were co-deposited at a weight ratio of about 97:3 on the hole transport layer to form an emission layer with a thickness of about 380 Å. Alq₃ was deposited on the emission layer to form an electron transport layer with a thickness of about 360 Å, and then Yb was deposited to have a thickness of about 15 Å on the electron transport layer to form an electron injection layer. Silver (Ag) and magnesium (Mg) were formed at a ratio of about 95:5 (vol %) on the electron injection layer to form a cathode with a thickness of 80 Å. Thereafter, B17 in the above-mentioned Compound Group 1 was deposited on the cathode to have a thickness of about 200 Å to form a capping layer. Each layer was formed by a vacuum deposition method.

The compounds used for the manufacture of light emitting elements in the Examples and Comparative Example are shown below. The materials were commercially available and purified by sublimation and used for the manufacture of light emitting elements.

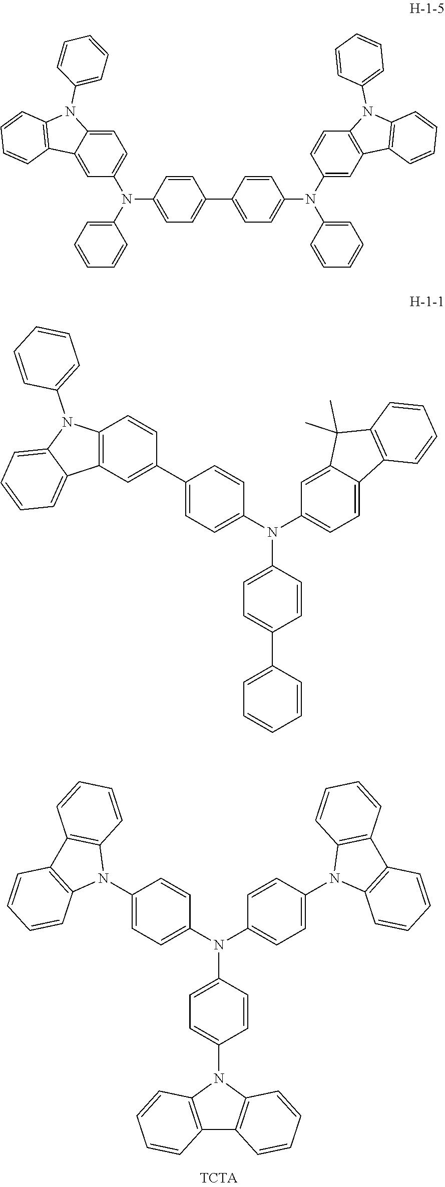 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

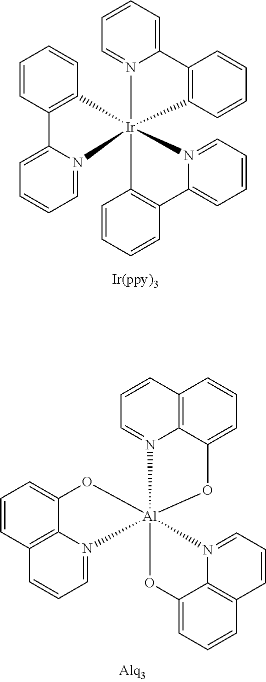

### Manufacture of Light Emitting Element of Example 2

A light emitting element was formed by substantially the same method as in Example 1, except that the capping layer was formed to have a thickness of about 300 Å.

### Manufacture of Light Emitting Element of Example 3

A light emitting element was formed by substantially the same method as in Example 1, except that the capping layer was formed to have a thickness of about 400 Å.

### Manufacture of Light Emitting Element of Example 4

A light emitting element was formed by substantially the same method as in Example 1, except that the capping layer was formed to have a thickness of about 500 Å.

### Manufacture of Light Emitting Element of Comparative Example

A light emitting element was formed by substantially the same method as in Example 1, except that the capping layer was formed to have a thickness of about 600 Å.

### Evaluation

### 1. Transmittance and Reflectance Measurements of Silver (Ag)-Magnesium (Mg) Electrodes and Capping Layer Structures

For each of the light emitting elements of the Examples and Comparative Example formed through the above manufacturing examples, the transmittance and reflectance were measured based on a wavelength of about 550 nm, and are shown in Table 1.

TABLE 1

| | Example | Example | Example | Example | Comparative |
|---|---|---|---|---|---|
| | 1 | 2 | 3 | 4 | Example |
| Transmittance | 88% | 87% | 85% | 70% | 65% |
| Reflectance | 3% | 6% | 13% | 25% | 30% |

Referring to Table 1, in the light emitting elements of the Examples and Comparative Example, it can be confirmed that as the thickness of the capping layer increases, the transmittance decreases and the reflectance increases.

### 2. Measurement of Luminance Change According to Angle in Examples and Comparative Example

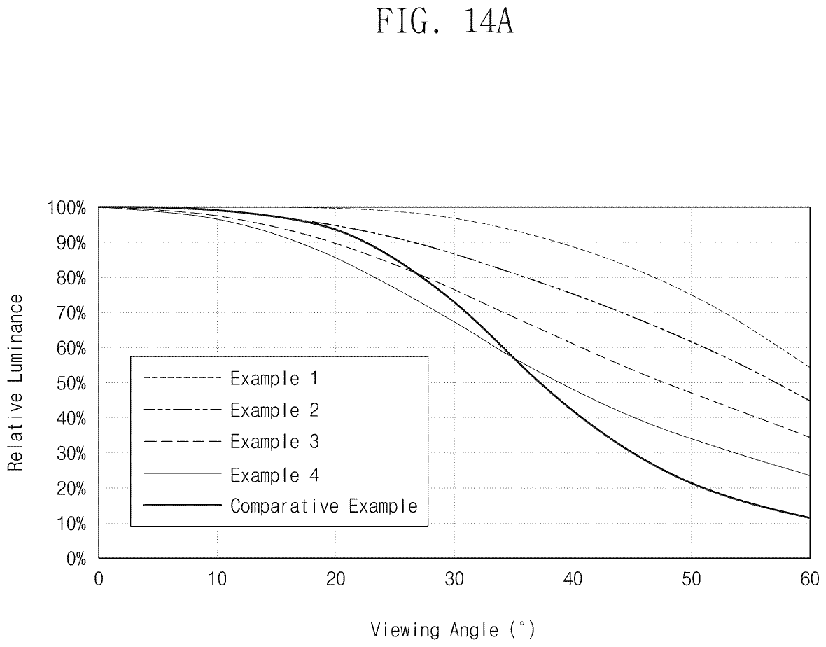

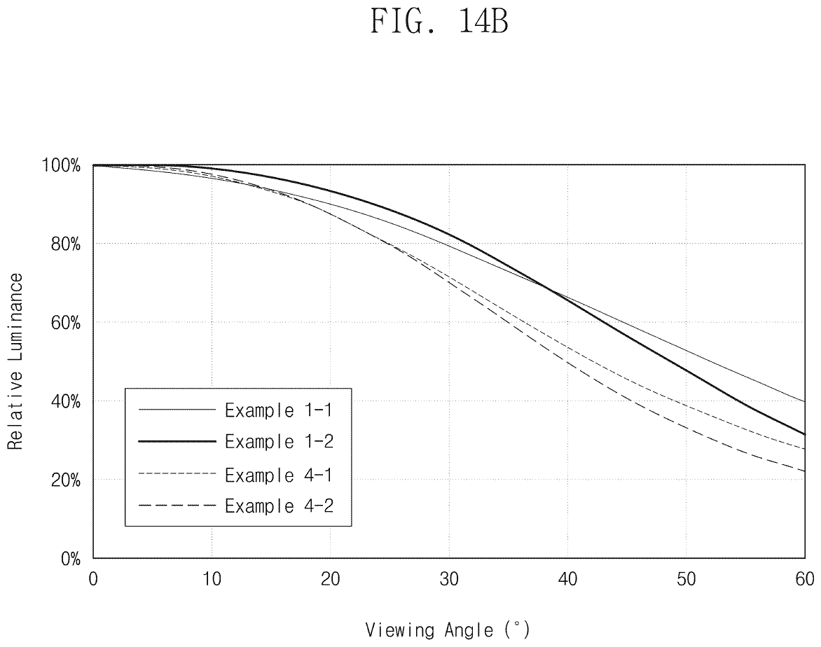

For each of the light emitting elements of the Examples and Comparative Example formed through the above manufacturing examples, a relative luminance according to a viewing angle is shown in FIG. 14A based on a wavelength of about 550 nm. FIG. 14A is a graph showing the relative luminance according to the viewing angle of each of the Examples and Comparative Example. In FIG. 14A, for each of the Examples and Comparative Example, when the viewing angle is 0, the luminance at the front is shown, and if the emission efficiency at the front is set to 100%, a luminance change according to the change in the viewing angle is shown.

Referring to FIG. 14A, it can be confirmed that, compared to the Comparative Example, the luminance reduction at a high viewing angle of the light emitting element of one or more embodiments may be reduced, and the luminance characteristics in the side viewing angle range may be improved. Different from the light emitting elements of the Examples, the light emitting element of the Comparative Example is confirmed to show a relative luminance of about 10% level at a high viewing angle of about 60° as the thickness of the capping layer deviates from the range of the Examples. For example, if the thickness of the capping layer is significantly thicker than the thicknesses of the Examples, the luminance reduction in the high viewing angle range may greatly increase to about 90% level, and the display characteristics in the side viewing angle range of the display device including the light emitting element of the Comparative Example may be significantly reduced. The light emitting element according to one or more embodiments of the present disclosure may secure emission efficiency by limiting the thickness and refractive index of the capping layer to set or predetermined ranges, thereby limiting the transmittance and reflectance to appropriate or suitable ranges as shown in Table 1, while preventing or reducing the luminance reduction from becoming excessively (or substantially) high in the high viewing angle range. Therefore, the display characteristics in the side viewing angle range of the display device including the light emitting element of the present disclosure may be improved.

### 3. Manufacture of Example 1-1, Example 1-2, Example 4-1 and Example 4-2 Manufacture of Example 1-1

Example 1-1 was formed in substantially the same manner as Example 1, except that a cathode was formed with a thickness of about 50 Å. After that, a first encapsulating inorganic layer/organic encapsulating layer/second encapsulating inorganic layer structure was additionally formed on the light emitting element to form an encapsulating layer.

### Manufacture of Example 1-2

Example 1-2 was formed in substantially the same manner as Example 1, except that a cathode was formed with a thickness of about 105 Å. After that, a first encapsulating inorganic layer/organic encapsulating layer/second encapsulating inorganic layer structure was additionally formed on the light emitting element to form an encapsulating layer.

### Manufacture of Example 4-1

Example 4-1 was formed in substantially the same manner as Example 4, except that a cathode was formed with a thickness of about 50 Å. After that, a first encapsulating inorganic layer/organic encapsulating layer/second encapsulating inorganic layer structure was additionally formed on the light emitting element to form an encapsulating layer.

### Manufacture of Example 4-2

Example 4-2 was formed a light emitting element in substantially the same manner as Example 4, except that a cathode was formed with a thickness of about 105 Å. After that, a first encapsulating inorganic layer/organic encapsulating layer/second encapsulating inorganic layer structure was additionally formed on the light emitting element to form an encapsulating layer.

### 4. Measurement of Luminance Change by Angle in Examples

For each of the light emitting elements of Examples 1-1, 1-2, 4-1 and 4-2 formed through the above-mentioned manufacturing examples, a relative luminance according to a viewing angle is shown in FIG. 14B based on a wavelength of about 550 nm. FIG. 14B is a graph showing a relative emission efficiency according to the viewing angle of each example. In FIG. 14B, for each of the Examples, if the viewing angle is 0, the emission efficiency at the front is shown, and if the emission efficiency at the front is set to 100%, a luminance change according to the change in the viewing angle is shown.

Referring to FIG. 14A and FIG. 14B together, it can be confirmed that the light emitting elements of the Examples each exhibit a similar level of relative luminance in a viewing angle range of about 0° to about 60° even when the thickness range of the silver (Ag)-magnesium (Mg) cathode is changed within the range of the Examples. For example, it can be confirmed that Example 1-1 and Example 1-2 exhibit a similar level of relative luminance for each viewing angle, and Example 4-1 and Example 4-2 exhibit a similar level of relative luminance for each viewing angle.

The stacked structure of the silver (Ag)-magnesium (Mg) electrode and the capping layer, applied to the light emitting element of one or more embodiments, is formed with thicknesses adjusted to set or predetermined ranges, and the transmittance and reflectance may be limited to set or predetermined ranges, thereby ensuring the emission efficiency of the light emitting element when applied to the light emitting element while preventing or reducing the luminance reduction from becoming excessively (or substantially) high in a high viewing angle range.

The light emitting element of one or more embodiments may have excellent or suitable emission efficiency and low luminance reduction in a high viewing angle range.

The display device of one or more embodiments may have improved display characteristics in a side viewing angle range by including the light emitting element.

For example, the stacked structure of the silver (Ag)-magnesium (Mg) electrode and the capping layer, applied to the light-emitting element of one or more embodiments, is designed with thicknesses adjusted to set ranges. This adjustment ensures that the transmittance and reflectance are limited to suitable ranges, thereby maintaining the emission efficiency of the light-emitting element. By controlling these parameters, the luminance reduction in high viewing angle ranges is prevented from becoming excessively high. This enhancement is for achieving excellent emission efficiency and low luminance reduction, even at high viewing angles. Consequently, the display device incorporating the light-emitting element of one or more embodiments exhibits significantly improved display characteristics in the side viewing angle range. This enhancement ensures that the display maintains high-quality visuals and consistent luminance across a wide range of viewing angles, making it ideal for applications where viewing from different angles is common. The precise control over the capping layer's thickness and refractive index, as well as the careful selection of materials, contribute to the overall performance and reliability of the light-emitting element, ensuring that it meets the requirements of modern display technologies and electronic devices.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display device, the electronic device/apparatus, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

Although one or more embodiments of the present disclosure have been described, it is understood that the present disclosure should not be limited to these embodiments, but one or more suitable changes and modifications can be made by one ordinary skilled in the art within the spirit and scope of the present disclosure as hereinafter claimed.

Accordingly, the technical scope of the disclosure is not intended to be limited to the contents set forth in the detailed description of the disclosure, but is intended to be defined by the appended claims and equivalents thereof.

What is claimed is:

1. A light emitting element comprising:
a first electrode;
a hole transport region on the first electrode;
an emission layer on the hole transport region;
an electron transport region on the emission layer;
a second electrode on the electron transport region; and
a capping layer on the second electrode,
wherein
the second electrode comprises a silver-magnesium alloy having a higher silver content than a magnesium content,
a thickness of the second electrode is about 30 Å to about 105 Å,
the capping layer has a refractive index of about 2.2 to about 2.5, and
a thickness of the capping layer is about 200 Å to about 500 Å.

2. The light emitting element of claim 1, wherein the magnesium content is about 5 vol % to about 15 vol % based on a total content of 100 vol % of the silver-magnesium alloy.

3. The light emitting element of claim 1, wherein the electron transport region comprises an auxiliary layer that is adjacent to the second electrode and comprises ytterbium.

4. The light emitting element of claim 3, wherein the second electrode is directly on the auxiliary layer.

5. The light emitting element of claim 1, wherein the capping layer has a light transmittance of greater than about 65% to about 90% in a wavelength range of about 450 nm to about 750 nm.

6. The light emitting element of claim 1, wherein the capping layer has a light reflectance of about 1% to less than about 30% in a wavelength range of about 450 nm to about 750 nm.

7. The light emitting element of claim 1, wherein the capping layer is directly on the second electrode.

8. The light emitting element of claim 1, wherein the hole transport region comprises:
a hole injection layer on the first electrode; and
a hole transport layer on the hole injection layer.

9. The light emitting element of claim 1, wherein the second electrode is a cathode.

10. The light emitting element of claim 1, wherein the first electrode comprises at least one selected from among at least one metal selected from among Ag, Mg, Cu, Al, Pt, Pd, Au, Ni, Nd, Ir, Cr, Li, Ca, Mo, Ti, W, In, Sn, and Zn, a compound of two or more selected from among the metals, LiF, indium tin oxide, indium zinc oxide, zinc oxide, and indium tin zinc oxide.

11. The light emitting element of claim 1, wherein, based on a top of the capping layer, a luminance at a side viewing angle of about 60 degrees is about 20% or more relative to a luminance at a front viewing angle.

12. The light emitting element of claim 1, wherein, the thickness of the second electrode is about 0.15 to about 0.4 of the thickness of the capping layer.

13. The light emitting element of claim 1, wherein the capping layer comprises a compound represented by Formula 1: 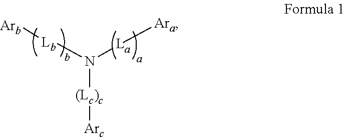
in Formula 1,
Arₐ to Ar_{c} being each independently a substituted or unsubstituted aryl group of 6 to 30 ring-forming carbon atoms or a substituted or unsubstituted heteroaryl group of 2 to 30 ring-forming carbon atoms,
Lₐ to L_{c} being each independently a direct linkage, a substituted or unsubstituted arylene group of 6 to 30 ring-forming carbon atoms, or a substituted or unsubstituted heteroarylene group of 2 to 30 ring-forming carbon atoms, and
“a” to “c” being each independently an integer of 0 to 3, where when “a” to “c” are each an integer of 2 or greater, then multiple Lₐ(s) to L_{c}(s) are each independently a substituted or unsubstituted arylene group of 6 to 30 ring-forming carbon atoms or a substituted or unsubstituted heteroarylene group of 2 to 30 ring-forming carbon atoms.

14. The light emitting element of claim 1, wherein the capping layer comprises at least one selected from among compounds in Compound Group 1:

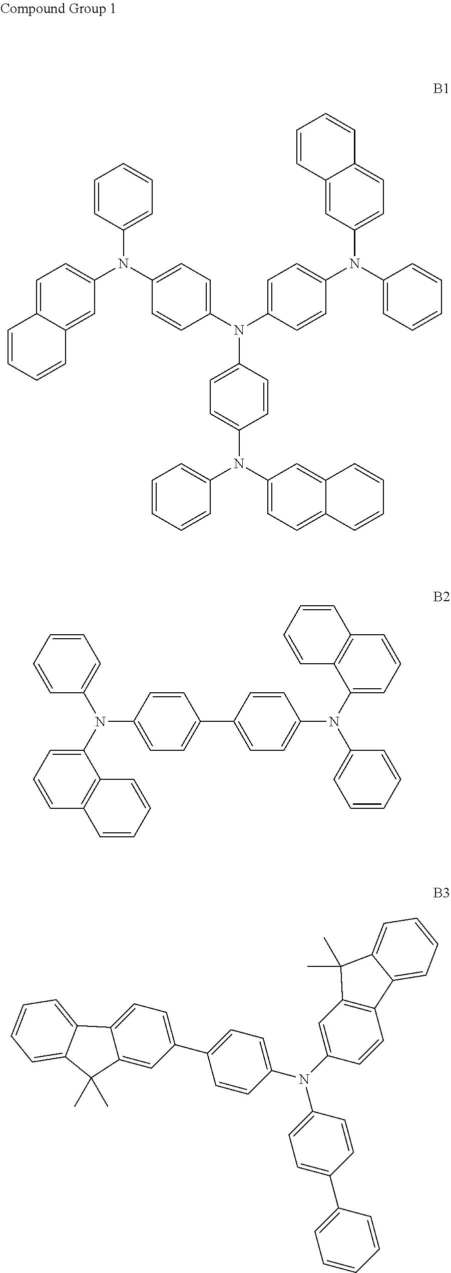 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; CC1(C)c2ccccc2-c2ccc(-c3ccc(N(c4ccc(-c5ccccc5)cc4)c4ccc5c(c4)C(C)(C)c4ccccc4-5)cc3)cc21]

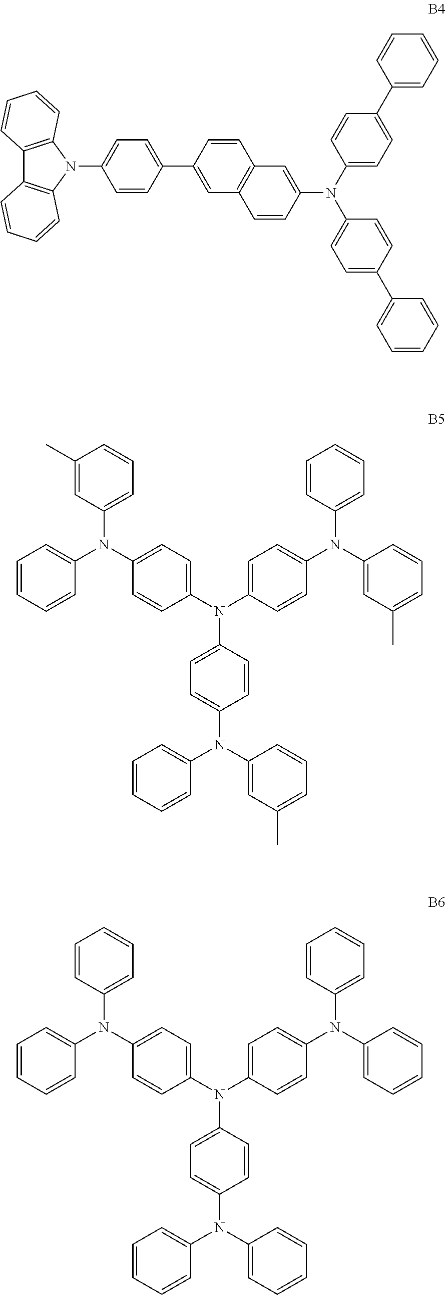 [SMILES: c1ccc(-c2ccc(N(c3ccc(-c4ccccc4)cc3)c3ccc4cc(-c5ccc(-n6c7ccccc7c7ccccc76)cc5)ccc4c3)cc2)cc1 ; Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc(N(c2ccccc2)c2ccc(N(c3ccc(N(c4ccccc4)c4ccccc4)cc3)c3ccc(N(c4ccccc4)c4ccccc4)cc3)cc2)cc1]

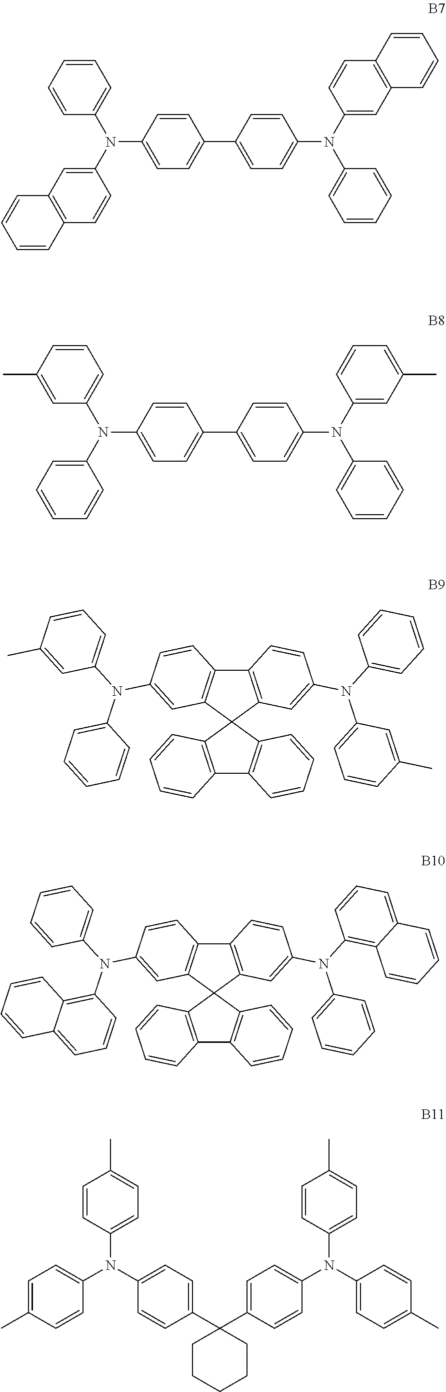

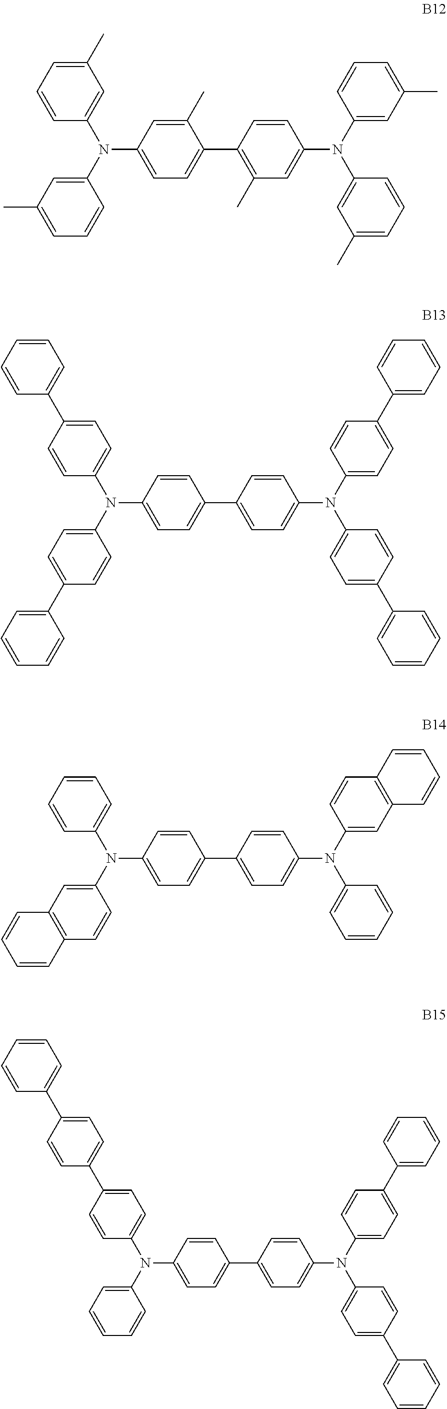

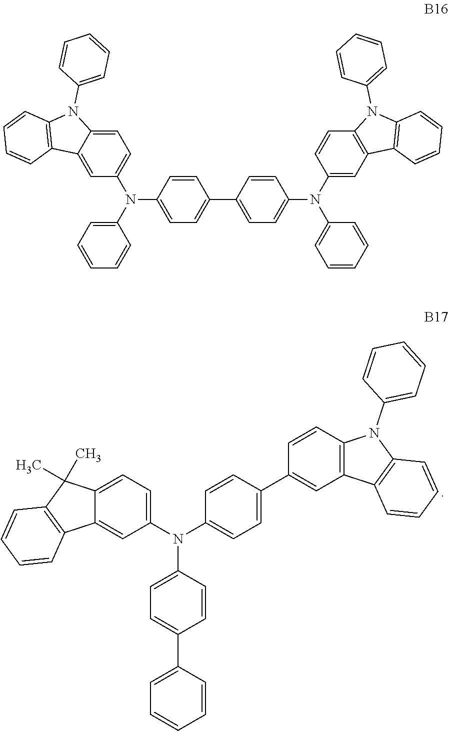 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

15. A light emitting element comprising:
a first electrode;
a hole transport region on the first electrode;
an emission layer on the hole transport region;
an electron transport region on the emission layer;
a second electrode on the electron transport region; and
a capping layer on the second electrode,
wherein
the second electrode comprises a silver-magnesium alloy having a higher silver content than a magnesium content,
the capping layer has a refractive index of about 2.2 to about 2.5,
a thickness of the second electrode is about 0.15 to about 0.4 of a thickness of the capping layer, and
based on a top of the capping layer, the capping layer has a luminance at a side viewing angle of about 60 degrees of about 20% or more relative to a luminance at a front viewing angle.

16. An electronic device comprising:
a base layer comprising multiple light emitting areas and a non-light emitting area adjacent to the multiple light emitting areas;
a circuit layer on the base layer; and
a display element layer on the circuit layer and comprising multiple light emitting elements respectively corresponding to the multiple light emitting areas,
wherein
at least a portion of the multiple light emitting elements comprises:
a first electrode on the circuit layer;
a hole transport region on the first electrode;
an emission layer on the hole transport region;
an electron transport region on the emission layer;
a second electrode on the electron transport region; and
a capping layer on the second electrode, and
wherein
the second electrode comprises a silver-magnesium alloy having a higher silver content than a magnesium content,
a thickness of the second electrode is about 30 Å to about 105 Å,
the capping layer has a refractive index of about 2.2 to about 2.5, and
a thickness of the capping layer is about 200 Å to about 500 Å.

17. The electronic device of claim 16, further comprising an encapsulating layer on the display element layer and comprising a first encapsulating inorganic layer, the first encapsulating inorganic layer being directly on the capping layer.

18. The electronic device of claim 16, further comprising a color filter layer on the display element layer and comprising multiple color filters.

19. The electronic device of claim 16, wherein the magnesium content is about 5 vol % to about 15 vol % based on a total content of 100 vol % of the silver-magnesium alloy.

20. The electronic device of claim 16, wherein the capping layer is directly on the second electrode.
